(19) United States
(12) Patent Application Publication
(10) Pub. No.: US 2016/0064586 A1
(43) Pub. Date: Mar. 3, 2016

(54) SOLAR CELL BACK SHEET, AND SOLAR CELL MODULE

(71) Applicant: FUJIFILM CORPORATION, Tokyo (JP)

(72) Inventors: Hideki TOMIZAWA, Shizuoka (JP); Naohiro MATSUNAGA, Shizuoka (JP); Naoki KOITO, Shizuoka (JP)

(73) Assignee: FUJIFILM CORPORATION, Tokyo (JP)

(21) Appl. No.: 14/938,856

(22) Filed: Nov. 12, 2015

Related U.S. Application Data
(63) Continuation of application No. PCT/JP2014/064031, filed on May 27, 2014.

(30) Foreign Application Priority Data
May 31, 2013 (JP) 2013-116439
Aug. 16, 2013 (JP) 2013-169243
May 26, 2014 (JP) 2014-108183

(51) Int. Cl. H01L 31/049; H01L 31/048

(52) U.S. Cl. CPC H01L 31/049; H01L 31/0481

(57) ABSTRACT

To provide a solar cell back sheet having excellent weather resistance and durability in which high adhesiveness to a sealing material for sealing a solar cell element is maintained for a long period of time even under harsh conditions of a high temperature and a high humidity and a solar cell module including the same.

The solar cell back sheet including a supporter; and a coating layer (B) including a polymer having a yield point; and a coating layer (C) on at least one surface side of the supporter in this order, in which the coating layer (C) is in direct contact with a sealing material for a solar cell module to which the solar cell back sheet is applied and a solar cell module including the same.

### CROSS-REFERENCE TO RELATED APPLICATION

This application is a Continuation of PCT International Application No. PCT/JP2014/064031, filed May 27, 2014, which claims priority under 35 U.S.C. §119(a) to Japanese Patent Application Nos. 2013-116439 filed May 31, 2013, 2013-169243 filed Aug. 16, 2013, and 2014-108183 filed May 26, 2014. Each of the above applications is hereby expressly incorporated by reference, in its entirety, into the present application.

### BACKGROUND OF THE INVENTION

1. Field of the Invention

The present invention relates to a solar cell back sheet and a solar cell module.

2. Description of the Related Art

A solar cell is a power generation method which does not emit carbon dioxide during power generation and causes a small environmental load and has been widely distributed in recent years. A solar cell module has a structure in which a solar cell, in which a solar cell element is sealed with a sealing material, is sandwiched between a front base material disposed on the front surface side on which, generally, sunlight is incident and a so-called back sheet disposed on the side (rear surface side) opposite to the front surface side on which sunlight is incident, and a space between the front base material and the solar cell and a space between the solar cell and the back sheet are respectively sealed with a sealing material such as an ethylene vinyl acetate (EVA) copolymer resin or the like.

Since a solar cell module is generally used in an environment in which the solar cell module is exposed to wind and rain at all times such as outdoors, durability of a solar cell back sheet is an important problem to be solved.

Regarding the above-described durability of a solar cell back sheet in a hot and humid environment, in a case in which a sealing material adjacent to the solar cell back sheet and the solar cell back sheet are peeled off from each other or the solar cell back sheet has a laminate structure, it is important to prevent the occurrence of peeling between individual layers in the solar cell back sheet and the consequent intrusion of moisture into a solar cell-side substrate.

In recent years, there has been a demand for additional thickness reduction of a back sheet in a solar cell module, and particularly, there has been a demand for reducing the thickness of a coating layer adhering a back sheet and a sealing material.

However, a solar cell module is used outdoors for a long period of time under harsh conditions such as direct sunlight and a high temperature and moisture, and thus there has been a problem in that the thickness reduction of the coating layer degrades adhesiveness between a backlight and a sealing material more than before.

As a solar cell back sheet having excellent durability, there has been a proposal of a back sheet with a three-layer structure in which cured layers of a curable composition including a vinyl-based monomer and the like are provided on both surfaces of a base material film (for example, refer to JP2012-227382A) or a solar cell back sheet in which a urethane resin obtained from a reaction between an acryl polyol having specific properties and an isocyanate compound is used as an adhesive layer (for example, refer to JP2012-142349A).

### SUMMARY OF THE INVENTION

According to an aspect of the present invention, a solar cell back sheet with excellent weather resistance and durability including a supporter; and a coating layer (B) including a polymer having a yield point; and a coating layer (C) on at least one surface side of the supporter in this order, in which the coating layer (C) is in direct contact with a sealing material for a solar cell module to which the solar cell back sheet is applied, and high adhesiveness to the sealing material is maintained for a long period of time even under harsh conditions of a high temperature and a high humidity, and a solar cell module including the same are provided.

However, in the solar cell back sheets of JP2012-227382A and JP2012-142349A, while the weather resistance is excellent, and peeling in the appearance of the back sheet after a certain period of time elapses is suppressed to a certain extent, according to the present inventors' studies, the back sheets are not capable of sufficiently suppressing peeling occurring in an interface between the back sheet and a sealing material in a case in which the solar cell back sheet is bent, the adhering force measured in a peeling test between the sealing material and the back sheet is not sufficient, and currently, additional improvement is required.

An object of the present invention made in consideration of the problems of the related art is to provide a solar cell back sheet with excellent durability in which, even when a coating layer for adhesion is a thin layer, excellent adhesiveness to a sealing material for sealing a solar cell element is maintained for a long period of time, particularly, even in a harsh environment at a high temperature and a high humidity and a solar cell module including the same.

Specific means for achieving the above-described object is as described below.

<1> A solar cell back sheet including: a supporter, a coating layer (B), which includes a polymer having a yield point, on at least one surface side of the supporter, and a coating layer (C), in this order, in which the coating layer (C) is in direct contact with a sealing material for a solar cell module to which the solar cell back sheet is applied.

<2> The solar cell back sheet according to <1>, in which the film thickness of the coating layer (B) is greater than the film thickness of the coating layer (C).

<3> The solar cell back sheet according to <1> or <2>, in which the film thickness of the coating layer (B) is in a range of 0.3 μm to 5 μm.

<4> The solar cell back sheet according to any one of <1> to <3>, in which the coating layer (B) further includes inorganic particles.

<5> The solar cell back sheet according to <4>, in which the percentage content of the inorganic particles in the coating layer (B) is in a range of 10% by volume to 35% by volume.

<6> The solar cell back sheet according to <4> or <5>, in which the average particle diameter of the inorganic particles included in the coating layer (B) is equal to or smaller than the film thickness of the coating layer (B).

7> The solar cell back sheet according to any one of <4> to <6>, in which the average particle diameter of the inorganic particles included in the coating layer (B) is equal to or smaller than half of the film thickness of the coating layer (B).

<8> The solar cell back sheet according to any one of <4> to <7>, in which the average particle diameter of the inorganic particles included in the coating layer (B) is 1.0 μm or smaller.

<9> The solar cell back sheet according to any one of <4> to <8>, in which inorganic particles included in the coating layer (B) are at least one kind of particles selected from colloidal silica, titanium oxide, aluminum oxide, and zirconium oxide.

<10> The solar cell back sheet according to any one of <4> to <9>, in which the inorganic particles included in the coating layer (B) contain at least a black pigment.

<11> The solar cell back sheet according to <10>, in which the black pigment contains at least carbon black.

<12> The solar cell back sheet according to any one of <1> to <11>, in which the coating layer (C) further includes an antistatic agent, and the coating layer (B) further includes a component of a crosslinking agent that crosslinks with the polymer in the coating layer (B).

<13> The solar cell back sheet according to <12>, in which the crosslinking agent is an oxazoline-based crosslinking agent.

<14> The solar cell back sheet according to <12> or <13>, further including: a coating layer (D) including a silicone resin or a fluorine-based polymer and inorganic particles on a surface of the supporter opposite to the coating layer (B).

<15> The solar cell back sheet according to <14> formed by further including a black pigment and a nonionic surfactant in the coating layer (D).

<16> The solar cell back sheet according to <14> or <15, further including: a coating layer (E) including a silicone resin or a fluorine-based polymer and inorganic particles on a surface of the coating layer (D) opposite to the supporter.

<17> The solar cell back sheet according to <16>, further including: a nonionic surfactant; and a component of a crosslinking agent that crosslinks with the silicone resin or the fluorine-based polymer in the coating layer (E).

<18> A solar cell module including: a transparent base material on which sunlight is incident; an element structure portion which is provided on the base material and has a solar cell element and a sealing material that seals the solar cell element; and the solar cell back sheet according to any one of <1> to <17> disposed on a side opposite to a side on which the base material of the element structure portion is located.

According to the present invention, it is possible to provide a solar cell back sheet with excellent durability in which, even when a coating layer for adhesion is a thin layer, excellent adhesiveness to a sealing material for sealing a solar cell element is maintained for a long period of time, particularly, even in a harsh environment at a high temperature and a high humidity and a solar cell module including the same.

### BRIEF DESCRIPTION OF THE DRAWINGS

FIG. 1(A) is a plan view illustrating an example of a solar cell module formed by disposing a crystalline solar cell on a solar cell back sheet of the present invention and is a view illustrating an aspect in which the exposed area of the solar cell back sheet is 39%.

FIG. 1(B) is a plan view illustrating an example of a solar cell module formed by disposing a crystalline solar cell on the solar cell back sheet of the present invention and is a view illustrating an aspect in which the exposed area of the solar cell back sheet is 25%.

FIG. 1(C) is a plan view illustrating an example of a solar cell module formed by disposing a crystalline solar cell on the solar cell back sheet of the present invention and is a view illustrating an aspect in which the exposed area of the solar cell back sheet is 5%.

### DESCRIPTION OF THE PREFERRED EMBODIMENTS

Hereinafter, a solar cell back sheet and a solar cell module of the present invention will be described in detail. Meanwhile, in the present specification, numerical ranges expressed using “to” refer to ranges including the numerical values before and after the “to” as the upper limit value and the lower limit value.

In addition, “including a coating layer (B) and a coating layer (C) in this order on at least one surface side of a supporter” means that the coating layer (B) and the coating layer (C) are provided on at least one surface side of the supporter in this order from the supporter side and does not deny the presence of other layers arbitrarily provided. That is, for example, an undercoat layer may be provided between the supporter and the coating layer (B) or an interlayer may be provided between the coating layer (B) and the coating layer (C). In addition, on a rear surface of the supporter on which the (B) layer and the like are not provided, a weather-resistant layer, a gas-barrier layer, and the like may be provided.

[Solar Cell Back Sheet]

The solar cell back sheet (hereinafter, appropriately referred to as “back sheet”) of the present invention includes a supporter, and a coating layer (B) including a polymer having a yield point (hereinafter, appropriately referred to as “(B) layer”); and a coating layer (C) (hereinafter, appropriately referred to as “(C) layer”) on at least one surface side of the supporter in this order, in which the coating layer (C) is provided at a location at which the coating layer (C) is in direct contact with a sealing material for a solar cell module to which the solar cell back sheet is applied.

While the action of the present invention is not clear, it is considered that, when the back sheet of the present invention includes the (B) layer including a polymer having a yield point between the (C) layer, which is an easy-adhesion layer in direct contact with the sealing material, and the supporter, a film formed of the polymer having a yield point, which is a main component of the (B) layer, has an excellent strength and dimensional stability at a high temperature and a high humidity, and consequently, even when a coating layer including at least two layers of the (B) layer and the (C) layer is a thin layer, adhesiveness between the back sheet and the sealing material is maintained at a favorable level under harsh conditions, and the degradation of adhesiveness is suppressed for a long period of time.

Hereinafter, the configuration of the back sheet of the present invention will be described.

In an embodiment of the solar cell back sheet, a coating layer formed by including an acid-denatured polyolefin water dispersion body (hereinafter, appropriately referred to as “inline coating layer”), the (B) layer including a polymer having a yield point, and the (C) layer, which is an easy-adhesion layer having excellent adhesiveness to the sealing material, are provided.

On the side of the supporter on which the (B) layer is not provided (hereinafter, in some cases, referred to as rear surface side), a weather-resistant layer, a gas-barrier layer, or the like may be provided as necessary. In an example described below in detail, a (D) layer including inorganic particles and a silicone resin, which is a weather-resistant layer, and an (E) layer including a fluorine-containing resin are provided in this order on the rear surface side of the supporter.

The inline coating layer, the (D) layer, and the (E) layer are all arbitrary layers that are provided on the back sheet as desired.

Hereinafter, the back sheet of the present invention will be described in detail.

The back sheet of the present invention includes the supporter and the (B) layer and the (C) layer on at least one surface of the supporter. The (C) layer is an outermost layer of the back sheet and a layer functioning as an easy adhesive layer.

The back sheet of the present invention may additionally include well-known functional layers such as a colored layer, a weather-resistant layer, an ultraviolet-absorbing layer, and a gas-barrier layer as necessary. In addition, an inline coating layer or an interlayer may be provided between the supporter and the (B) layer. These arbitrary layers may be provided on any of the surface side of the supporter provided with the (B) layer and the surface side (rear surface side) opposite to the above-described surface. In addition, an undercoat layer may be provided between the supporter and the (B) layer or a functional layer provided so as to be adjacent to the supporter. Meanwhile, the (B) layer may be a layer also serving as a functional layer such as a colored layer.

Hereinafter, first, the supporter and the respective layers laminated on the supporter, which are used in the back sheet of the present invention, will be described in detail.

(Supporter)

The supporter includes a resin (hereinafter, referred to as “raw material resin”).

—Raw Material Resin—

Examples of the raw material resin include polyesters, polystyrenes, polyphenylene ethers, polyphenylene sulfides, and the like, and polyesters are preferred from the viewpoint of cost, mechanical stability, or durability.

Examples of the polyesters include linear saturated polyesters synthesized from an aromatic dibasic acid or an ester-forming derivative thereof and a diol or an ester-forming derivative thereof. Specific examples of the linear saturated polyesters include polyethylene terephthalate, polyethylene isophthalate, polybutylene terephthalate, poly(1,4-cyclohexylene dimethylene terephthalate), polyethylene-2,6-naphthalate, and the like. Among these, polyethylene terephthalate, polyethylene-2,6-naphthalate, and poly(1,4-cyclohexylene dimethylene terephthalate) are particularly preferred in terms of the balance between mechanical properties and cost.

The polyester may be a homopolymer or a copolymer. Furthermore, a polyester obtained by blending a small amount of a different kind of resin, for example, a polyimide or the like into the polyester may be used.

The kind of the polyester is not limited to the above-described polyesters, and a well-known polyester may be used. As the well-known polyester, a polyester may be synthesized using a dicarboxylic acid component and a diol component, or a commercially-available polyester may be used.

In a case in which a polyester is synthesized, the polyester can be obtained by, for example, causing at least one of an esterification reaction and an ester exchange reaction between the dicarboxylic acid component (a) and the diol component (b) using a well-known method.

Examples of the dicarboxylic acid component (a) include dicarboxylic acids and ester derivatives thereof such as aliphatic dicarboxylic acids such as malonic acid, succinic acid, glutaric acid, adipic acid, suberic acid, sebacic acid, dodecanedioic acid, dimer acids, eicosanedioic acid, pimelic acid, azelaic acid, methylmalonic acid, and ethylmalonic acid; alicyclic dicarboxylic acids such as adamantanedicarboxylic acid, norbornene dicarboxylic acid, cyclohexane dicarboxylic acid, and decalin dicarboxylic acid; aromatic dicarboxylic acids such as terephthalic acid, isophthalic acid, phthalic acid, 1,4-naphthalenedicarboxylic acid, 1,5-naphthalenedicarboxylic acid, 2,6-naphthalenedicarboxylic acid, 1,8-naphthalenedicarboxylic acid, 4,4′-diphenyldicarboxylic acid, 4,4′-diphenylether dicarboxylic acid, sodium 5-sulfoisophthalic acid, phenylindane dicarboxylic acid, anthracenedicarboxylic acid, phenanthrene dicarboxylic acid, and 9,9′-bis(4-carboxyphenyl) fluorenic acid.

Examples of the diol component (b) include diol compounds such as aliphatic diols such as ethylene glycol, 1,2-propanediol, 1,3-propanediol, 1,4-butanediol, 1,2-butanediol, and 1,3-butanediol; alicyclic diols such as cyclohexanedimethanol, spiroglycol, and isosorbide; and aromatic diols such as bisphenol A, 1,3-benzenedimethanol, 1,4-benzenedimethanol, and 9,9′-bis(4-hydroxyphenyl)fluorene.

As the dicarboxylic acid component (a), at least one aromatic dicarboxylic acid is preferably used. More preferably, the polyester contains, in the dicarboxylic acid component, an aromatic dicarboxylic acid as a main component. Meanwhile, the “main component” means that the fraction of the aromatic dicarboxylic acid in the dicarboxylic acid component is 80% by mass or greater. The polyester may include a dicarboxylic acid component other than the aromatic dicarboxylic acid. Examples of the above-described dicarboxylic acid component include ester derivatives such as aromatic dicarboxylic acids and the like.

As the diol component (b), at least one of aliphatic diols is preferably used. As the aliphatic diol, ethylene glycol can be included and, preferably, ethylene glycol may be included as a main component. Meanwhile, the main component means that the fraction of ethylene glycol in the diol component is 80% by mass or greater.

The amount of the aliphatic diol (for example, ethylene glycol) used is preferably in a range of 1.015 mol to 1.50 mol in relation to 1 mol of the aromatic dicarboxylic acid (for example, terephthalic acid) and, as necessary, an ester derivative thereof. The amount of the aliphatic diol (for example, ethylene glycol) used is more preferably in a range of 1.02 mol to 1.30 mol, and still more preferably in a range of 1.025 mol to 1.10 mol. When the amount of the aliphatic diol used is in a range of 1.015 mol or greater, the esterification reaction favorably proceeds, and when the amount of the aliphatic diol used is in a range of 1.50 mol or less, for example, the generation of diethylene glycol as a byproduct due to the dimerization of ethylene glycol is suppressed, and it is possible to favorably maintain a number of characteristics such as melting point, glass transition temperature, crystallinity, heat resistance, hydrolysis resistance, and weather resistance.

In the esterification reaction or the ester exchange reaction, it has been possible so far to use a well-known reaction catalyst. Examples of the reaction catalyst include alkali metal compounds, alkaline-earth metal compounds, zinc compounds, lead compounds, manganese compounds, cobalt compounds, aluminum compounds, antimony compounds, titanium compounds, and phosphorous compounds. Generally, it is preferable to add an antimony compound, a germanium compound, or a titanium compound as a polymerization catalyst in an arbitrary phase ahead of the completion of the method for manufacturing the polyester. As the method for adding the above-described compound, when a germanium compound is used as an example, germanium compound powder is preferably added as it is.

For example, in the esterification reaction, the aromatic dicarboxylic acid and the aliphatic diol are polymerized in the presence of a catalyst containing a titanium compound. In this esterification reaction, it is preferable to use, as the titanium compound which serves as the catalyst, an organic chelate titanium complex having an organic acid as a ligand and to provide a process for adding at least the organic chelate titanium complex, a magnesium compound, and a pentavalent phosphoric acid ester not having an aromatic ring as a substituent in this order in the step.

Specifically, in the esterification reaction step, first, in the beginning, the aromatic dicarboxylic acid and the aliphatic diol are mixed with a catalyst containing the organic chelate titanium complex, which is a titanium compound, ahead of the addition of the magnesium compound and the phosphorous compound. The titanium compound such as the organic chelate titanium complex has a strong catalytic activity for the esterification reaction and is thus capable of causing the esterification reaction to favorably proceed. At this time, the titanium compound may be added during the mixing of the aromatic dicarboxylic acid component and the aliphatic diol component, or the aromatic dicarboxylic acid component (or the aliphatic diol component) and the titanium compound may be mixed together, and then the aliphatic diol component (or the aromatic dicarboxylic acid component) may be mixed with the mixture. In addition, the aromatic dicarboxylic acid component, the aliphatic diol component, and the titanium compound may be mixed together at the same time. There is no particular limitation regarding the mixing, and the components can be mixed together using a well-known method of the related art.

Here, during the polymerization of the polyester, the following compound is preferably added.

As a pentavalent phosphorous compound, at least one pentavalent phosphoric acid ester not having an aromatic ring as a substituent is used. Examples thereof include phosphoric acid esters [(OR)₃—P═O; R=an alkyl group having 1 or 2 carbon atoms]having a lower alkyl group having 2 or less carbon atoms as a substituent. Specifically, trimethyl phosphate and triethyl phosphate are particularly preferred.

The amount of the phosphorous compound added is preferably in a range of 50 ppm to 90 ppm in terms of the P element-equivalent value. The amount of the phosphorous compound is more preferably in a range of 60 ppm to 80 ppm, and still more preferably in a range of 60 ppm to 75 ppm.

When the polyester includes a magnesium compound, the electrostatic application property of the polyester improves.

Examples of the magnesium compound include magnesium salts such as magnesium oxide, magnesium hydroxide, magnesium alkoxides, magnesium acetate, and magnesium carbonate. Among these, magnesium acetate is most preferred from the viewpoint of the solubility in ethylene glycol.

In order to impart a high electrostatic application property, the amount of the magnesium compound added is preferably 50 ppm and more preferably in a range of 50 ppm to 100 ppm in terms of the Mg element-equivalent value. The amount of the magnesium compound added is preferably in a range of 60 ppm to 90 ppm and more preferably in a range of 70 ppm to 80 ppm in terms of imparting the electrostatic application property.

In the esterification reaction step, it is particularly preferable to add, melt, and polymerize the titanium compound, which is a catalyst component, and the magnesium compound and the phosphorous compound, which are additives, so that a value Z computed from the following expression (i) satisfies the following relational expression (ii). Here, the content of P refers to the amount of phosphorus derived from all phosphorous compounds including the pentavalent phosphoric acid ester not having an aromatic ring, and the content of Ti refers to the amount of titanium derived from all Ti compounds including the organic chelate titanium complex. As described above, when the joint use of the magnesium compound and the phosphorous compound in a catalyst system including a titanium compound is selected, and the addition timings and addition fractions thereof are controlled, it is possible to obtain a hue with a slight yellow color tone while appropriately maintaining the catalytic activity of the titanium compound at a high level, and to impart heat resistance so that yellow coloration does not easily occur even when the polyester is exposed to a high temperature during a polymerization reaction, the formation of a film (melting), and the like.

Z=5×(the content of P [ppm]/the atomic weight of P)−2×(the content of Mg [ppm]/the atomic weight of Mg)−4×(the content of Ti [ppm]/the atomic weight of Ti) (i)

0≦Z≦5.0 (ii)

The phosphorous compound does not only act on titanium but also interacts with the magnesium compound, and thus the above-described expressions serve as indexes for quantitatively expressing the balance among these three components.

Expression (i) expresses the amount of phosphorus capable of acting on titanium by subtracting the amount of phosphorus acting on magnesium from the amount of all phosphorus capable of reacting with magnesium and titanium. It can be said that, in a case in which the Z value is a positive value, the amount of phosphorus hindering titanium is excessive, and, conversely, in a case in which the Z value is a negative value, the amount of phosphorus necessary to hinder titanium is not sufficient. In the reaction, since a Ti atom, an Mg atom, and a P atom do not have equal valences, weighting is carried out by multiplying the molar numbers of the respective atoms by the valences thereof.

Meanwhile, special synthesis or the like is not required for the synthesis of the polyester, and it is possible to obtain a polyester having a reaction activity required for the reaction and having a color tone and coloration resistance to heat using a titanium compound which is inexpensive and can be easily procured, and the phosphorous compound and the magnesium compound which are described above.

In Expression (ii), from the viewpoint of further improving the color tone and the coloration resistance to heat in a state of maintaining the polymerization reactivity, it is preferable to satisfy 1.0≦Z≦4.0 and it is more preferable to satisfy 1.5≦Z≦3.0.

As a preferred aspect of the esterification reaction step, 1 ppm to 30 ppm of a chelate titanium complex having citric acid or citrate as a ligand is preferably added to the aromatic dicarboxylic acid and the aliphatic diol before the end of the esterification reaction. After that, it is preferable to add 60 ppm to 90 ppm (more preferably 70 ppm to 80 ppm) of a weakly acidic magnesium salt in the presence of the chelate titanium complex and furthermore, after the above-described addition, add 60 ppm to 80 ppm (more preferably 65 ppm to 75 ppm) of the pentavalent phosphoric acid ester not having an aromatic ring as a substituent.

The esterification reaction step can be carried out while removing water or alcohols generated from the reaction outside of the system using a multistage apparatus including at least two reactors coupled in series under a condition in which ethylene glycol is refluxed.

The esterification reaction step may be carried out in a single stage or may be carried out in multiple separated stages.

In a case in which the esterification reaction step is carried out in a single stage, the esterification reaction temperature is preferably in a range of 230° C. to 260° C. and more preferably in a range of 240° C. to 250° C.

In a case in which the esterification reaction step is carried out in multiple separated stages, the temperature of the esterification reaction in a first reactor is preferably in a range of 230° C. to 260° C. and more preferably in a range of 240° C. to 250° C., and the pressure is preferably in a range of 1.0 kg/cm² to 5.0 kg/cm², and more preferably in a range of 2.0 kg/cm² to 3.0 kg/cm². The temperature of the esterification reaction in a second reactor is preferably in a range of 230° C. to 260° C. and more preferably in a range of 245° C. to 255° C., and the pressure is preferably in a range of 0.5 kg/cm² to 5.0 kg/cm², and more preferably in a range of 1.0 kg/cm² to 3.0 kg/cm². Futhermore, in a case in which the esterification reaction step is carried out in three or more separated stages, as the conditions for the esterification reaction in the intermediate stage, the reaction temperature and the pressure are preferably set to conditions between those in the first reactor and those in the final reactor.

Meanwhile, a polycondensation reaction of an esterification reaction product generated from the esterification reaction is caused so as to generate a polycondensate. The polycondensation reaction may be caused in a single stage or may be caused in multiple separated stages.

The esterification reaction product such as an oligomer generated from the esterification reaction is subsequently subjected to a polycondensation reaction. This polycondensation reaction can be preferably caused by supplying the esterification reaction product to a multistage polycondensation reactor.

For example, regarding the conditions for the polycondensation reaction caused in three-stage reactors, in the first reactor, the reaction temperature is in a range of 255° C. to 280° C. and more preferably in a range of 265° C. to 275° C., and the pressure is in a range of 100 Torr to 10 Torr (13.3×10−3 MPa to 1.3×10⁻³ MPa), and more preferably in a range of 50 Torr to 20 Torr (6.67×10⁻³ MPa to 2.67×10⁻³ MPa); in the second reactor, the reaction temperature is in a range of 265° C. to 285° C. and more preferably in a range of 270° C. to 280° C., and the pressure is in a range of 20 Torr to 1 Torr (2.67×10⁻³MPa to 1.33×10⁻⁴ MPa), and more preferably in a range of 10 Torr to 3 Torr (1.33×10⁻³ MPa to 4.0×10⁻⁴ MPa); and in the third reactor in the final reactor, the reaction temperature is in a range of 270° C. to 290° C. and more preferably in a range of 275° C. to 285° C., and the pressure is in a range of 10 Torr to 0.1 Torr (1.33×10⁻³ MPa to 1.33×10⁻⁵ MPa), and more preferably in a range of 5 Torr to 0.5 Torr (6.67×10⁻⁴ MPa to 6.67×10⁻⁵ MPa).

To the polyester synthesized as described above, additives such as a photostabilizing agent, an antioxidant, an ultraviolet absorber, a flame retardant, a lubricant (fine particles), a nucleating agent (crystallization agent), and a crystallization inhibitor may be further added.

In addition, from the viewpoint of designability and reflectivity, the polyester preferably includes inorganic particles of barium sulfate, calcium phosphate, silica particles, titanium oxide, or the like and organic particles of polymethylpentene or the like. Among these, white particles of silica particles, titanium oxide, or the like are preferred, and titanium oxide is particularly preferably used. As the titanium oxide, titanium oxide having an average primary particle diameter in a range of 0.1 μm to 1.0 μm is preferably used, and the average primary particle diameter is most preferably in a range of, particularly, 0.1 μm to 0.3 μm. The average primary particle diameter refers to a value measured using a MICROTRACK FRA manufactured by Honeywell Inc.

Among these, the inorganic particles are preferred, and, from the viewpoint of light resistance and dispersibility, inorganic particles which have been subjected to an alumina treatment, a silica treatment, a ZrO₂ treatment, or the like are preferred, and inorganic particles which have been subjected to only an alumina treatment are most preferred in consideration of the influence of polyethylene terephthalate (PET) on hydrolysis resistance. In addition, from the viewpoint of dispersibility, inorganic particles which have been subjected to an organic surface treatment using a polyol, an organic polysiloxane, or the like are preferred. Examples of surface-treated titanium oxide include PF-739 (inorganic particles subjected to a polyol treatment after an alumina treatment as a surface treatment) manufactured by Ishihara Sangyo Kaisha, Ltd. and the like.

In a case in which the polyester includes titanium oxide, the amount of titanium oxide added is preferably in a range of 0.5% by mass to 10% by mass of the polyester, and, from the viewpoint of hydrolysis resistance and transition probability, the amount thereof is preferably in a range of 0.5% by mass to 5% by mass.

In the synthesis of the polyester, it is preferable to carry out solid-phase polymerization after the polymerization using the esterification reaction. When solid-phase polymerization is carried out, it is possible to control the moisture content of the polyester, the degree of crystallization, the acid value of the polyester, that is, the concentration of a terminal carboxyl group of the polyester, and the intrinsic viscosity.

Particularly, when the solid-phase polymerization is carried out, the concentration of ethylene glycol (EG) gas at the initiation of the solid-phase polymerization is set to be higher than the concentration of the EG gas at the end of the solid-phase polymerization preferably in a range of 200 ppm to 1000 ppm, more preferably in a range of 250 ppm to 800 ppm, and still more preferably in a range of 300 ppm to 700 ppm. At this time, AV (the concentration of terminal COOH) can be controlled by adding EG of the average EG gas concentration (the average of the gas concentrations at the initiation and at the end of the solid-phase polymerization). That is, EG is added and is thus reacted with the terminal COOH, whereby AV can be reduced. The amount of EG added is preferably in a range of 100 ppm to 500 ppm, more preferably in a range of 150 ppm to 450 ppm, and still more preferably in a range of 200 ppm to 400 ppm.

In addition, the temperature of the solid-phase polymerization is preferably in a range of 180° C. to 230° C., more preferably in a range of 190° C. to 215° C., and still more preferably in a range of 195° C. to 209° C.

In addition, the solid-phase polymerization time is preferably in a range of 10 hours to 40 hours, more preferably in a range of 14 hours to 35 hours, and still more preferably in a range of 18 hours to 30 hours.

Here, the polyester preferably has strong hydrolysis resistance. Therefore, the content of a carboxyl group in the polyester is preferably 50 equivalents/t (here, ‘t’ represents ton, and ton is equal to 1000 kg) or less, more preferably 35 equivalents/t or less, and still more preferably 20 equivalents/t or less. When the content of the carboxyl group is 50 equivalents/t or less, it is possible to maintain the hydrolysis resistance and to suppress a decrease in strength to a small extent when the polyester is aged in a hot and humid environment. The lower limit of the content of the carboxyl group is desirably 2 equivalents/t, more preferably 3 equivalents/t, and still more preferably 3 equivalents/t in terms of maintaining the adhesiveness to a layer (for example, a colored layer) formed in the polyester.

The content of the carboxyl group in the polyester can be adjusted using the kind of polymerization catalyst, film-forming conditions (film-forming temperature or time), solid-phase polymerization, and additives (a terminal-sealing agent and the like).

—Carbodiimide Compound, Ketenimine Compound, and Iminoether Compound—

In a case in which the raw material resin is the polyester, the supporter may include at least one of a carbodiimide compound, a ketenimine compound, and an iminoether compound. The carbodiimide compound, the ketenimine compound, and the iminoether compound may be used singly respectively or two or more thereof may be jointly used. The inclusion of the carbodiimide compound, the ketenimine compound, and the iminoether compound is effective in suppressing the deterioration of the polyester after a thermal treatment and maintaining strong insulating properties even after a thermal treatment.

The content of the carbodiimide compound, the ketenimine compound, or the iminoether compound is preferably in a range of 0.1% by mass to 10% by mass, more preferably in a range of 0.1% by mass to 4% by mass, and still more preferably in a range of 0.1% by mass to 2% by mass of the polyester. When the content of the carbodiimide compound, the ketenimine compound, or the iminoether compound is set in the above-described range, the adhesiveness between the supporter and an adjacent layer can be enhanced. In addition, the heat resistance of the supporter can be enhanced.

Meanwhile, in a case in which two or more of the carbodiimide compound, the ketenimine compound, and the iminoether compound are jointly used, the total percentage content of the two compounds is preferably in the above-described range.

The carbodiimide compound will be described.

Examples of the carbodiimide compound include compounds having one or more carbodiimide groups in the molecule (including polycarbodiimide compounds), and specifically include, as monocarbodiimide compounds, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphtylcarbodiimide, and N,N′-di-2,6-diisopropylphenyl carbodiimide. As the polycarbodiimide compound, a polycarbodiimide compound having a degree of polymerization having a lower limit of generally 2 or greater and preferably 4 or greater and an upper limit of generally 40 or less and preferably 30 or less is used, and examples thereof include polycarbodiimide compounds manufactured using the methods described in the specification of U.S. Pat. No. 2,941,956A, JP1972-33279B (JP-S47-33279B), J. Org. Chem. Vol. 28, pp. 2069 to 2075 (1963), Chemical Review 1981, Vol. 81, Issue 4, pp. 619 to 621, and the like.

Examples of an organic diisocyanate, which is a raw material for manufacturing the polycarbodiimide compound, include aromatic diisocyanates, aliphatic diisocyanates, alicyclic diisocyanates, and mixtures thereof, and specifically include 1,5-naphthalene diisocyanate, 4,4′-diphenylmethane diisocyanate, 4,4′-diphenyldimethylmethane diisocyanate, 1,3-phenylene diisocyanate, 1,4-phenylene diisocyanate, 2,4-tolylene diisocyanate, 2,6-tolylene diisocyanate, mixtures of 2,4-tolylene diisocyanate and 2,6-tolylene diisocyanate, hexamethylene diisocyanate, cyclohexane-1,4-diisocyanate, xylylene diisocyanate, isophorone diisocyanate, 4,4′-dicyclohexylmethane diisocyanate, methylcyclohexane diisocyanate, tetramethylxylylene diisocyanate, 2,6-diisopropylphenyl isocyanate, and 1,3,5-triisopropylbenzene-2,4-diisocyanate.

Specific examples of the polycarbodiimide compounds that can be industrially procured include CARBODILITE HMV-8CA (manufactured by Nisshinbo Holdings Inc.), CARBODILITE La.-1 (manufactured by Nisshinbo Holdings Inc.), STABAXOL P (manufactured by Rhein Chemie Corporation), STABAXOL P100 (manufactured by Rhein Chemie Corporation), STABAXOL P400 (manufactured by Rhein Chemie Corporation), STABILIZER 9000 (manufactured by Rhein Chemie Corporation), and the like.

The carbodiimide compound can be used singly, but a mixture of a plurality of the compounds can also be used.

Here, a cyclic carbodiimide compound which includes one carbodiimide group in a cyclic skeleton and has at least one ring structure in which a first nitrogen atom and a second nitrogen atom are bonded together through a bonding group in the molecule functions as a cyclic sealing agent.

The cyclic carbodiimide compound can be prepared using the method described in WO2011/093478A.

The cyclic carbodiimide compound has a ring structure. The cyclic carbodiimide compound may have a plurality of ring structures. The ring structure has one carbodiimide group (—N═C═CN—), and the first nitrogen atom and the second nitrogen atom are bonded together through a bonding group. In a single ring structure, there is only one carbodiimide group; however, for example, in the case of a spirocycle or the like having a plurality of ring structures in the molecule, the compound may have a plurality of carbodiimide groups as long as individual ring structures bonded to spiro atoms have one carbodiimide group. The number of atoms in the ring structure is preferably in a range of 8 to 50, more preferably in a range of 10 to 30, still more preferably in a range of 10 to 20, and particularly preferably in a range of 10 to 15.

Here, the number of atoms in the ring structure refers to the number of atoms directly constituting the ring structure, and, for example, the number of atoms of an 8-membered ring is 8, and the number of atoms of a 50-membered ring is 50. The reasons for setting the number of atoms in the ring structure in the above-described ranges are as described below. When the number of atoms in the ring structure is smaller than 8, the stability of the cyclic carbodiimide compound degrades, and thus it becomes difficult to store and use the cyclic carbodiimide compound. In addition, there is no particular limitation regarding the upper limit value of the number of ring members from the viewpoint of reactivity, but the synthesis of a cyclic carbodiimide compound having more than 50 atoms is difficult, and there are cases in which the cost significantly increases. On the basis of the above-described viewpoints, the number of atoms in the ring structure is preferably in a range of 10 to 30, more preferably in a range of 10 to 20, and particularly in a range of 10 to 15.

As the cyclic carbodiimide compound, a cyclic carbodiimide compound represented by General Formula (O-A) or General Formula (O-B) shown below is preferably used. Hereinafter, a preferred structure of the cyclic carbodiimide compound of the present invention will be described in the order of General Formula (O-A) and General Formula (O-B) shown below.

First, the cyclic carbodiimide compound represented by General Formula (O-A) will be described.

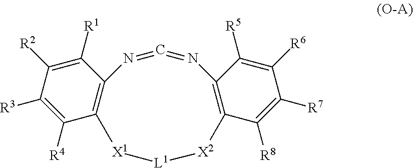

In General Formula (O-A), each of R¹ and R⁵ independently represents an alkyl group, an aryl group, or an alkoxy group. Each of R² to R⁴ and R⁶ to R⁸ independently represents a hydrogen atom, an alkyl group, an aryl group, or an alkoxy group. R¹ to R⁸ may be bonded to each other so as to form a ring. Each of X¹ and X² independently represents a single bond, —O—, —CO—, —S—, —SO₂−, —NH—, or —CH₂−. L¹ represents a divalent linking group.

In General Formula (O-A), each of R¹ and R⁵ independently represents an alkyl group, an aryl group, or an alkoxy group, preferably represents an alkyl group or an aryl group, more preferably represents a secondary or tertiary alkyl group or aryl group from the viewpoint of suppressing a reaction between isocyanate linked to the terminal of the polyester and the hydroxyl group terminal of the polyester and suppressing an increase in the viscosity, and particularly preferably represents a secondary alkyl group.

In General Formula (O-A), the alkyl group represented by R¹ and R⁵ is preferably an alkyl group having 1 to 20 carbon atoms, more preferably an alkyl group having 1 to 12 carbon atoms, and particularly preferably an alkyl group having 2 to 6 carbon atoms. The alkyl group represented by R¹ and R⁵ may be a straight chain, a branched chain, or a cyclic chain, but is preferably a branched chain or a cyclic chain from the viewpoint of suppressing a reaction between isocyanate linked to the terminal of the polyester and the hydroxyl group terminal of the polyester and suppressing an increase in the viscosity, and particularly preferably represents a secondary alkyl group. The alkyl group represented by R¹ and R⁵ is preferably a secondary or tertiary alkyl group and more preferably a secondary alkyl group. Examples of the alkyl group represented by R¹ and R⁵ include a methyl group, an ethyl group, an n-propyl group, a sec-propyl group, an iso-propyl group, an n-butyl group, a tert-butyl group, a sec-butyl group, an iso-butyl group, an n-pentyl group, a sec-pentyl group, an iso-pentyl group, an n-hexyl group, a sec-hexyl group, an iso-hexyl group, and a cyclohexyl group. Among these, an iso-propyl group, a tert-butyl group, an iso-butyl group, an iso-pentyl group, an iso-hexyl group, and a cyclohexyl group are preferred, and an iso-propyl group, a cyclohexyl group, and a tert-butyl group are more preferred, and an iso-propyl group and a cyclohexyl group are particularly preferred.

In General Formula (O-A), the alkyl group represented by R¹ and R⁵ may further have a substituent, and the substituent is not particularly limited. However, the alkyl group represented by R¹ and R⁵ preferably does not have any further substituents from the viewpoint of the reactivity with a carboxylic acid.

In General Formula (O-A), the aryl group represented by R¹ and R⁵ is preferably an aryl group having 6 to 20 carbon atoms, more preferably an aryl group having 6 to 12 carbon atoms, and particularly preferably an aryl group having 6 carbon atoms. The aryl group represented by R¹ and R⁵ may be an aryl group formed through the condensation of R¹ and R² or the condensation of R⁵ and R⁶, but R¹ and R⁵ preferably do not respectively condense with R² and R⁶ so as to form a ring. Examples of the aryl group represented by R¹ and R⁵ include a phenyl group, a naphthyl group, and the like, and, among these, a naphthyl group is more preferred.

In General Formula (O-A), the aryl group represented by R¹ and R⁵ may further have a substituent, and the substituent is not particularly limited. However, the aryl group represented by R¹ and R⁵ preferably does not have any further substituents from the viewpoint of the reactivity with a carboxylic acid.

In General Formula (O-A), the alkoxy group represented by R¹ and R⁵ is preferably an alkoxy group having 1 to 20 carbon atoms, more preferably an alkoxy group having 1 to 12 carbon atoms, and particularly preferably an alkoxy group having 2 to 6 carbon atoms. The alkoxy group represented by R¹ and R⁵ may be a straight chain, a branched chain, or a cyclic chain, but is preferably a branched chain or a cyclic chain from the viewpoint of suppressing a reaction between isocyanate linked to the terminal of the polyester and the hydroxyl group terminal of the polyester and suppressing an increase in the viscosity. A preferred example of the alkoxy group represented by R¹ and R⁵ is a group in which —O— is linked to the terminal of the alkyl group represented by R¹ and R⁵, and the preferred range thereof is also, similarly, a group in which —O— is linked to the terminal of the alkyl group represented by R¹ and R⁵.

In General Formula (O-A), the alkoxy group represented by R¹ and R⁵ may further have a substituent, and the substituent is not particularly limited. However, the alkoxy group represented by R¹ and R⁵ preferably does not have any further substituents from the viewpoint of the reactivity with a carboxylic acid.

In General Formula (O-A), R¹ and R⁵ may be identical to or different from each other, but are preferably identical to each other from the viewpoint of cost.

In General Formula (O-A), each of R² to R⁴ and R⁶ to R⁸ independently represents a hydrogen atom, an alkyl group, an aryl group, or an alkoxy group, is preferably a hydrogen atom, an alkyl group having 1 to 20 carbon atoms, or an alkoxy group having 1 to 20 carbon atoms, more preferably a hydrogen atom or an alkyl group having 1 to 6 carbon atoms, and particularly preferably a hydrogen atom.

In General Formula (O-A), the alkyl group, the aryl group, or the alkoxy group represented by R² to R⁴ and R⁶ to R⁸ may further have a substituent, and the substituent is not particularly limited.

In General Formula (O-A), both R² and R⁶ are preferably hydrogen atoms from the viewpoint of ease of introducing a bulky substituent into R¹ and R⁵. Here, in WO2010/071211A, compounds obtained by substituting portions (meta positions with respect to the carbodiimide group) corresponding to R² and R⁶ in General Formula (O-A) with an alkyl group or an aryl group are exemplified, but these compounds are not capable of suppressing the reaction between isocyanate linked to the terminal of the polyester and the hydroxyl group terminal of the polyester, and thus it is difficult to introduce substituents into the portions (ortho positions with respect to the carbodiimide group) corresponding to R² and R⁶ in General Formula (O-A).

In General Formula (O-A), R¹ to R⁸ may be bonded to each other so as to form a ring.

There is no particular limitation regarding a ring formed at this time, but an aromatic ring is preferred. For example, two or more of R¹ to R⁴ may be bonded to each other so as to form a fused ring or R¹ to R⁴ may form an arylene group or a heteroarylene group having 10 or more carbon atoms together with a benzene ring substituted with R¹ to R⁴. Examples of the arylene group having 10 or more carbon atoms formed at this time include aromatic groups having 10 to 15 carbon atoms such as a naphthalenediyl group.

In General Formula (O-A), similarly, for example, two or more of R⁵ to R⁸ may be bonded to each other so as to form a fused ring or R⁵ to R⁸ may form an arylene group or a heteroarylene group having 10 or more carbon atoms together with a benzene ring substituted with R⁵ to R⁸. The preferred range at this time is identical to the preferred range when R¹ to R⁴ form an arylene group or a heteroarylene group having 10 or more carbon atoms together with a benzene ring substituted with R¹ to R⁴.

However, in General Formula (O-A), it is preferable that R¹ to R⁸ are not bonded to each other and thus do not form a ring.

In General Formula (O-A), each of X¹ and X² independently represents at least one selected from a single bond, —O—, —CO—, —S—, —SO₂—, —NH—, or —CH₂—. Among these, each of X¹ and X² is preferably —O—, —CO—, —S—, —SO₂—, or —NH—, and more preferably —O— or —S— from the viewpoint of easy synthesis.

In General Formula (O-A), L¹ represents a divalent linking group and may respectively include a hetero atom and a substituent. L¹ is preferably a divalent aliphatic group having 1 to 20 carbon atoms, a divalent alicyclic group having 3 to 20 carbon atoms, a divalent aromatic group having 5 to 15 carbon atoms, or a combination thereof and more preferably a divalent aliphatic group having 1 to 20 carbon atoms.

In General Formula (O-A), examples of the divalent aliphatic group represented by L¹ include alkylene groups having 1 to 20 carbon atoms. Examples of the alkylene groups having 1 to 20 carbon atoms include a methylene group, an ethylene group, a propylene group, a butylene group, a pentylene group, a hexylene group, a heptylene group, an octylene group, a nonylene group, a decylene group, a dodecylene group, and a hexadecylene group, and a methylene group, an ethylene group, and a propylene group are preferred, and an ethylene group is particularly preferred. These aliphatic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-A), examples of the divalent alicyclic group represented by L¹ include cycloalkylene groups having 3 to 20 carbon atoms. Examples of the cycloalkylene groups having 3 to 20 carbon atoms include a cyclopropylene group, a cyclobutylene group, a cyclopentylene group, a cyclohexylene group, a cycloheptylene group, a cyclooctylene group, a cyclononylene group, a cyclodecylene group, a cyclododecylene group, and a cyclohexadecylene group. These alicyclic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-A), examples of the divalent aromatic group represented by L¹ include arylene groups having 5 to 15 carbon atoms which may include a hetero atom and thus have a heteroring structure. Examples of the arylene groups having 5 to 15 carbon atoms include a phenylene group and a naphthalenediyl group. These aromatic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

The number of atoms in the ring structure including the carbodiimide group in General Formula (O-A) is preferably in a range of 8 to 50, more preferably in a range of 10 to 30, still more preferably in a range of 10 to 20, and particularly preferably in a range of 10 to 15.

Here, the number of atoms in the ring structure including the carbodiimide group refers to the number of atoms directly constituting the ring structure including the carbodiimide group, and, for example, the number of atoms of an 8-membered ring is 8, and the number of atoms of a 50-membered ring is 50. When the number of atoms in the ring structure is smaller than 8, the stability of the cyclic carbodiimide compound degrades, and thus there are cases in which the storage and use of the cyclic carbodiimide compound becomes difficult.

In addition, there is no particular limitation regarding the upper limit value of the number of ring members from the viewpoint of reactivity, but the synthesis of a cyclic carbodiimide compound having more than 50 atoms is difficult, and there are cases in which the cost significantly increases. On the basis of the above-described viewpoints, in General Formula (O-A), the number of atoms in the ring structure is preferably in a range of 10 to 30, more preferably in a range of 10 to 20, and particularly in a range of 10 to 15.

Next, the cyclic carbodiimide compound represented by General Formula (O-B) shown below will be described.

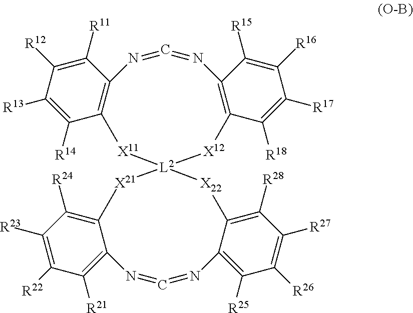

In General Formula (O-B), each of R¹¹, R¹⁵, R²¹, and R²⁵ independently represents an alkyl group, an aryl group, or an alkoxy group. Each of R¹² to R¹⁴, R¹⁶ to R¹⁸, R²² to R²⁴, and R²⁶ to R²⁸ independently represents a hydrogen atom, an alkyl group, an aryl group, or an alkoxy group. R¹¹ to R²⁸ may be bonded to each other so as to form a ring. Each of X¹¹, X¹², X²¹, and X²² independently represents a single bond, —O—, —CO—, —S—, —SO₂—, —NH—, or —CH₂—. L² represents a tetravalent linking group.

In General Formula (O-B), the preferred ranges of R¹¹, R¹⁵, R²¹, and R²⁵ are identical to the preferred ranges of R¹ and R⁵ in General Formula (O-A).

The aryl group represented by R¹¹, R¹⁵, R²¹, and R²⁵ may be an aryl group formed through the condensation of R¹¹ and R¹², the condensation of R¹⁵ and R¹⁶, the condensation of R²¹ and R²² or the condensation of R²⁵ and R²⁶, but it is preferable that R¹¹, R¹⁵, R²¹, and R²⁵ do not respectively condense with R¹², R¹⁶, R²², and R²⁶ and thus do not form a ring.

R¹¹, R¹⁵, R²¹, and R²⁵ may be identical to or different from each other, but are preferably identical to each other from the viewpoint of the cost.

In General Formula (O-B), the preferred ranges of R¹² to R¹⁴, R^{I6} to R¹⁸, R²² to R²⁴, and R²⁶ to R²⁸ are identical to the preferred ranges of R² to R⁴ and R⁶ to R⁸ in General Formula (O-A).

Among R¹² to R¹⁴, R¹⁶ to R¹⁸, R²² to R²⁴, and R²⁶ to R²⁸, R¹², R¹⁶, R²², and R²⁶ are preferably all hydrogen atoms from the viewpoint of ease of introducing a bulky substituent into R¹¹, R¹⁵, R²¹, and R²⁵.

Here, when a bulky group such as an alkyl group, an aryl group, or an alkoxy group is introduced in the vicinity of the carbodiimide group as described above, the cyclic carbodiimide compound represented by General Formula (O-B) is capable of suppressing a reaction between an isocyanate group, which is generated after the reaction between the carbodiimide group and the terminal carboxylic acid of the polyester, and a terminal hydroxyl group of the polyester. As a result, it is possible to suppress an increase in the molecular weight of the polyester and to suppress the generation of chips caused by the above-described increase in the viscosity of the polyester.

In General Formula (O-B), R¹¹ to R²⁸ may be bonded to each other so as to form a ring, and a range of a preferred ring is identical to a range of a preferred ring formed by the mutual bonding of R¹ to R⁸ in General Formula (O-A).

In General Formula (O-B), the preferred ranges of X¹¹, X¹², X²¹, and X²² are identical to the preferred ranges of X¹ and X² in General Formula (O-A).

In General Formula (O-B), L² represents a tetravalent linking group and may respectively include a hetero atom and a substituent. L² is preferably a tetravalent aliphatic group having 1 to 20 carbon atoms, a tetravalent alicyclic group having 3 to 20 carbon atoms, a tetravalent aromatic group having 5 to 15 carbon atoms, or a combination thereof and more preferably a tetravalent aliphatic group having 1 to 20 carbon atoms.

In General Formula (O-B), examples of the tetravalent aliphatic group represented by L² include alkanetetrayl groups having 1 to 20 carbon atoms and the like. Examples of the alkanetetrayl groups having 1 to 20 carbon atoms include a methanetetrayl group, an ethanetetrayl group, a propanetetrayl group, a butanetetrayl group, a pentanetetrayl group, a hexanetetrayl group, a heptanetetrayl group, an octanetetrayl group, a nonanetetrayl group, a decanetetrayl group, a dodecanetetrayl group, and a hexadecanetetrayl group, a methanetetrayl group, an ethanetetrayl group, and a propanetetrayl group are more preferred, and an ethanetetrayl group is particularly preferred. These aliphatic groups may include a substituent. Examples of the substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-B), examples of the tetravalent alicyclic group represented by L² include cycloalkanetetrayl groups having 3 to 20 carbon atoms. Examples of the cycloalkanetetrayl groups having 3 to 20 carbon atoms include a cyclopropanetetrayl group, a cyclobutanetetrayl group, a cyclopentanetetrayl group, a cyclohexanetetrayl group, a cycloheptanetetrayl group, a cyclooctanetetrayl group, a cyclononanetetrayl group, a cyclodecanetetrayl group, a cyclododecanetetrayl group, and a cyclohexadecanetetrayl group.

These alicyclic groups may include a substituent. Examples of the substituent include an alkyl group having 1 to 20 carbon atoms, an arylene group having 6 to 15 carbon atoms, a halogen atom, a nitro group, an amide group, a hydroxyl group, an ester group, an ether group, and an aldehyde group.

In General Formula (O-B), examples of the tetravalent aromatic group represented by L² include arenetetrayl groups having 5 to 15 carbon atoms which may include a hetero atom and thus have a heteroring structure. Examples of the (tetravalent) arenetetrayl groups having 5 to 15 carbon atoms include a benzenetetrayl group and a naphthalenetetrayl group. These aromatic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-B), two ring structures including the carbodiimide group are included through L² which is a tetravalent linking group.

The preferred ranges of the numbers of atoms in the respective ring structures including the carbodiimide group in General Formula (O-B) are respectively identical to the preferred range of the number of atoms in the ring structure including the carbodiimide group in General Formula (O-A).

Here, the cyclic carbodiimide compound is preferably an aromatic carbodiimide not having a ring structure in which the first nitrogen atom and the second nitrogen atom of two or more carbodiimide groups in the molecule are bonded to each other through linking groups, that is, the cyclic carbodiimide compound is preferably a single ring and is represented by General Formula (O-A) from the viewpoint of the viscosity being hardly increased.

However, from the viewpoint of being capable of suppressing sublimation and the generation of isocyanate gas during manufacturing, the cyclic carbodiimide compound of the present invention also preferably has a plurality of ring structures and is represented by General Formula (O-B).

The molecular weight of the cyclic carbodiimide compound is preferably in a range of 400 to 1500 in terms of the weight-average molecular weight. When the molecular weight of the cyclic carbodiimide compound is 400 or higher, sublimation properties are weak, and the generation of isocyanate gas during manufacturing can be suppressed, which is preferable. In addition, there is no particular limitation regarding the upper limit of the molecular weight of the cyclic carbodiimide compound, but the molecular weight thereof is preferably 1500 or lower from the viewpoint of reactivity with a carboxylic acid.

The molecular weight of the cyclic carbodiimide compound is more preferably in a range of 500 to 1200.

Specific examples of the cyclic carbodiimide compound represented by General Formula (O-A) or General Formula (O-B) include the following compounds. However, the present invention is not limited to the following specific examples.

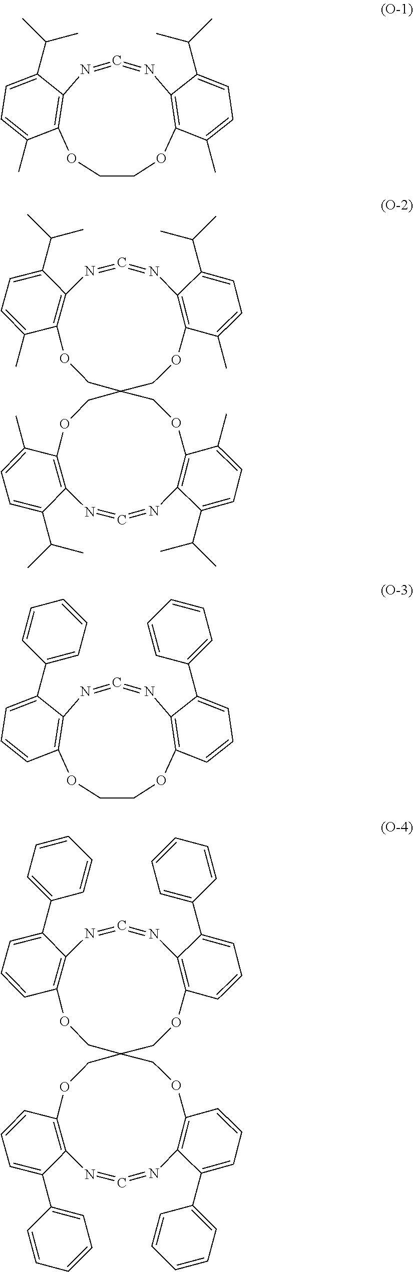

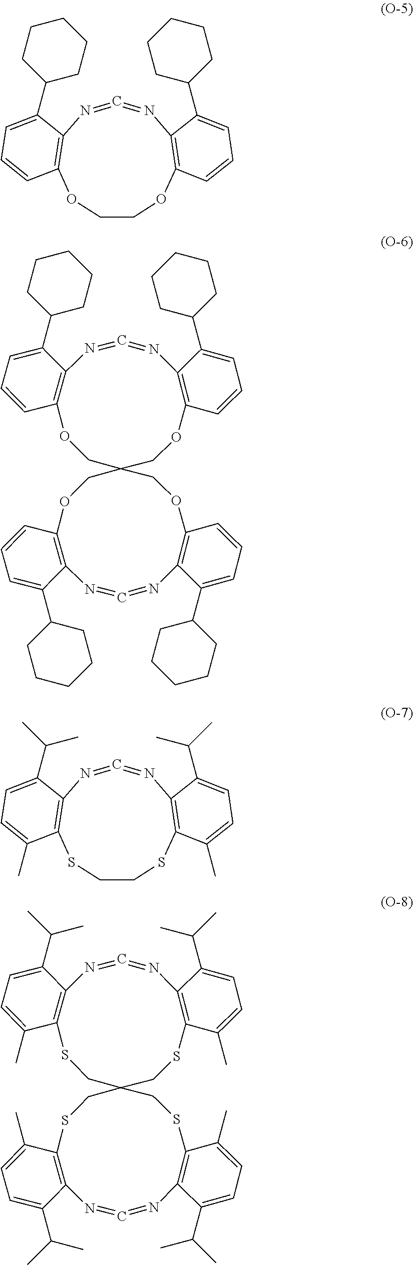

The cyclic carbodiimide compound is preferably a compound having at least one structure represented by —N═C═N— (carbodiimide group) adjacent to an aromatic ring and can be manufactured by, for example, heating an organic isocyanate in the presence of an appropriate catalyst and causing a decarboxylation reaction. In addition, the cyclic carbodiimide compound of the present invention can be synthesized with reference to the method described in JP2011-256337A.

In the synthesis of the cyclic carbodiimide compound, there is no particular limitation regarding the method for introducing a specific bulky substituent into the ortho position of an arylene group adjacent to the first nitrogen atom and the second nitrogen atom of the carbodiimide group, and nitrobenzene substituted with an alkyl group can be synthesized by nitrating an alkylbenzene using, for example, a known method, and a cyclic carbodiimide can be synthesized using the method described in WO2011/158958A on the basis of the nitrobenzene.

The ketenimine compound will be described.

As the ketenimine compound, a ketenimine compound represented by General Formula (K-A) shown below is preferably used.

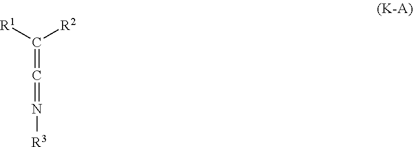

In General Formula (K-A), each of R¹ and R² independently represents an alkyl group, an aryl group, an alkoxy group, an alkoxycarbonyl group, an aminocarbonyl group, an aryloxy group, an acyl group, or an aryloxycarbonyl group, and R³ represents an alkyl group or an aryl group.

Here, the molecular weight of a portion excluding the nitrogen atom and the substituent bonded to the nitrogen atom in the ketenimine compound is preferably 320 or more. That is, in General Formula (K-A), the molecular weight of a R¹—C(═C)—R² group is preferably 320 or more. The molecular weight of the portion excluding the nitrogen atom and the substituent bonded to the nitrogen atom in the ketenimine compound is preferably 320 or more, more preferably in a range of 500 to 1500, and still more preferably in a range of 600 to 1000. As described above, when the molecular weight of the portion excluding the nitrogen atom and the substituent bonded to the nitrogen atom in the ketenimine compound is in the above-described range, it is possible to enhance the adhesiveness between the supporter and a layer in contact with the supporter. This is because, when the portion excluding the nitrogen atom and the substituent bonded to the nitrogen atom in the ketenimine compound has a certain range of molecular weight, the polyester terminal which is bulky to a certain extent diffuses into the layer in contact with the supporter, and an anchorage effect is exhibited.

In General Formula (K-A), the alkyl group represented by R¹ and R² is preferably an alkyl group having 1 to 20 carbon atoms and more preferably an alkyl group having 1 to 12 carbon atoms. The alkyl group represented by R¹ and R² may be a straight chain, a branched chain, or a cyclic chain. Examples of the alkyl group represented by R¹ and R² include a methyl group, an ethyl group, an n-propyl group, an iso-propyl group, an n-butyl group, a tert-butyl group, a sec-butyl group, an iso-butyl group, an n-pentyl group, a sec-pentyl group, an iso-pentyl group, an n-hexyl group, a sec-hexyl group, an iso-hexyl group, and a cyclohexyl group. Among these, a methyl group, an ethyl group, an n-propyl group, an iso-propyl group, an iso-butyl group, and a cyclohexyl group are more preferred.

In General Formula (K-A), the alkyl group represented by R¹ and R² may further have a substituent. The substituent is not particularly limited as long as the reactivity between a ketenimine group and a carboxyl group is not degraded, and examples thereof include an alkyl group having 1 to 20 carbon atoms, an aryl group having 6 to 15 carbon atoms, a halogen atom, a nitro group, an amide group, a hydroxyl group, an ester group, an ether group, and an aldehyde group. Meanwhile, the number of carbon atoms in the alkyl group represented by R¹ and R² represents the number of carbon atoms not including the substituent.

In General Formula (K-A), the aryl group represented by R¹ and R² is preferably an aryl group having 6 to 20 carbon atoms and more preferably an aryl group having 6 to 12 carbon atoms. Examples of the aryl group represented by R¹ and R² include a phenyl group and a naphthyl group, and, among these, a phenyl group is particularly preferred.

In General Formula (K-A), the aryl group represented by R¹ and R² includes a heteroaryl group. The heteroaryl group refers to a 5-membered, 6-membered, or 7-membered ring, which exhibits aromaticity, or a fused ring thereof in which at least one ring-constituting atom is substituted with a hetero atom. Examples of the heteroaryl group include an imidazolyl group, a pyridyl group, a quinolyl group, a furyl group, a thienyl group, a benzoxazolyl group, an indolyl group, a benzimidazolyl group, a benzothiazolyl group, a carbazolyl group, and an azepinyl group. The hetero atom included in the heteroaryl group is preferably an oxygen atom, a sulfur atom, or a nitrogen atom, and, among these, an oxygen atom or a nitrogen atom is preferred.

In General Formula (K-A), the aryl group represented by R¹ and R² or the heteroaryl group may further have a substituent, and the substituent is not particularly limited as long as the reactivity between the ketenimine group and the carboxyl group is not degraded. Meanwhile, the number of carbon atoms in the aryl group represented by R¹ and R² or the heteroaryl group represents the number of carbon atoms not including the substituent.

In General Formula (K-A), the alkoxy group represented by R¹ and R² is preferably an alkoxy group having 1 to 20 carbon atoms, more preferably an alkoxy group having 1 to 12 carbon atoms, and particularly preferably an alkoxy group having 2 to 6 carbon atoms. The alkoxy group represented by R¹ and R² may be a straight chain, a branched chain, or a cyclic chain. A preferred example of the alkoxy group represented by R¹ and R² is a group in which —O— is linked to the terminal of the alkyl group represented by R¹ and R². The alkoxy group represented by R¹ and R² may further have a substituent, and the substituent is not particularly limited as long as the reactivity between the ketenimine group and the carboxyl group is not degraded. Examples of the substituent include the same substituents as for the alkyl group. Meanwhile, the number of carbon atoms in the alkoxy group represented by R¹ and R² represents the number of carbon atoms not including the substituent.

In General Formula (K-A), the alkoxycarbonyl group represented by R¹ and R² is preferably an alkoxycarbonyl group having 2 to 20 carbon atoms, more preferably an alkoxycarbonyl group having 2 to 12 carbon atoms, and particularly preferably an alkoxycarbonyl group having 2 to 6 carbon atoms. Examples of an alkoxy portion of the alkoxycarbonyl group represented by R¹ and R² include the above-described examples of the alkoxy group.

In General Formula (K-A), the aminocarbonyl group represented by R¹ and R² is preferably an alkylaminocarbonyl group having 1 to 20 carbon atoms or an arylaminocarbonyl group having 6 to 20 carbon atoms. A preferred example of the alkylamine portion in the alkylaminocarbonyl group is a group in which —NH— is linked to the terminal of the alkyl group represented by R¹ and R². The alkylaminocarbonyl group represented by R¹ and R² may further have a substituent, and the substituent is not particularly limited as long as the reactivity between the ketenimine group and the carboxyl group is not degraded. Examples of the substituent include the same substituents as for the alkyl group. A preferred example of the arylamine portion in the arylaminocarbonyl group having 6 to 20 carbon atoms is a group in which —NH— is linked to the terminal of the aryl group represented by R¹ and R².

The arylaminocarbonyl group represented by R¹ and R² may further have a substituent, and the substituent is not particularly limited as long as the reactivity between the ketenimine group and the carboxyl group is not degraded. Examples of the substituent include the same substituents as for the alkyl group. Meanwhile, the number of carbon atoms in the alkylaminocarbonyl group represented by R¹ and R² represents the number of carbon atoms not including the substituent.

In General Formula (K-A), the aryloxy group represented by R¹ and R² is preferably an aryloxy group having 6 to 20 carbon atoms and more preferably an aryloxy group having 6 to 12 carbon atoms. Examples of the aryl portion in the aryloxy group represented by R¹ and R² include the above-described examples of the aryl group.

In General Formula (K-A), the acyl group represented by R¹ and R² is preferably an acyl group having 2 to 20 carbon atoms, more preferably an acyl group having 2 to 12 carbon atoms, and particularly preferably an acyl group having 2 to 6 carbon atoms. The acyl group represented by R¹ and R² may further have a substituent, and the substituent is not particularly limited as long as the reactivity between the ketenimine group and the carboxyl group is not degraded. Examples thereof include the same substituents as for the alkyl group. Meanwhile, the number of carbon atoms in the acyl group represented by R¹ and R² represents the number of carbon atoms not including the substituent.

In General Formula (K-A), the aryloxycarbonyl group represented by R¹ and R² is preferably an aryloxycarbonyl group having 7 to 20 carbon atoms and more preferably an aryloxycarbonyl group having 7 to 12 carbon atoms, and examples of the aryl portion in the aryloxycarbonyl group represented by R¹ and R² include the above-described examples of the aryl group.

In General Formula (K-A), R³ represents an alkyl group or an aryl group. The alkyl group is preferably an alkyl group having 1 to 20 carbon atoms and more preferably an alkyl group having 1 to 12 carbon atoms. The alkyl group represented by R³ may be a straight chain, a branched chain, or a cyclic chain. Examples of the alkyl group represented by R³ include a methyl group, an ethyl group, an n-propyl group, an iso-propyl group, an n-butyl group, a tert-butyl group, a sec-butyl group, an iso-butyl group, an n-pentyl group, a sec-pentyl group, an iso-pentyl group, an n-hexyl group, a sec-hexyl group, an iso-hexyl group, and a cyclohexyl group. Among these, a methyl group, an ethyl group, an n-propyl group, an iso-propyl group, an n-butyl group, an iso-butyl group, and a cyclohexyl group are more preferred.

In General Formula (K-A), the alkyl group represented by R³ may further have a substituent. The substituent is not particularly limited as long as the reactivity between the ketenimine group and the carboxyl group is not degraded. Examples of the substituent include the same substituents as for the alkyl group.

In General Formula (K-A), the aryl group represented by R³ is preferably an aryl group having 6 to 20 carbon atoms and more preferably an aryl group having 6 to 12 carbon atoms.

Examples of the aryl group represented by R³ include a phenyl group and a naphthyl group, and, among these, a phenyl group is more preferred.

In General Formula (K-A), the aryl group represented by R³ includes a heteroaryl group. The heteroaryl group refers to a 5-membered, 6-membered, or 7-membered ring, which exhibits aromaticity, or a fused ring thereof in which at least one ring-constituting atom is substituted with a hetero atom. Examples of the heteroaryl group include an imidazolyl group, a pyridyl group, a quinolyl group, a furyl group, a thienyl group, a benzoxazolyl group, an indolyl group, a benzimidazolyl group, a benzothiazolyl group, a carbazolyl group, and an azepinyl group. The hetero atom included in the heteroaryl group is preferably an oxygen atom, a sulfur atom, or a nitrogen atom, and, among these, an oxygen atom or a nitrogen atom is preferred.

In General Formula (K-A), the aryl group represented by R³ or the heteroaryl group may further have a substituent, and the substituent is not particularly limited as long as the reactivity between the ketenimine group and the carboxyl group is not degraded. Examples of the substituent include the same substituents as for the alkyl group.

Meanwhile, General Formula (K-A) may include a repeating unit. In this case, at least one of R¹ and R³ is the repeating unit, and the repeating unit preferably includes a ketenimine portion.

As the ketenimine compound, a ketenimine compound represented by General Formula (K-B) shown below is also preferably used.

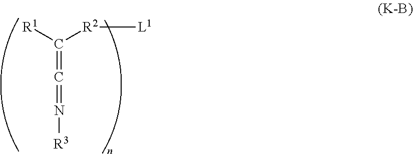

In General Formula (K-B), R¹ represents an alkyl group, an aryl group, an alkoxy group, an alkoxycarbonyl group, an aminocarbonyl group, an aryloxy group, an acyl group, or an aryloxycarbonyl group. R² represents an alkyl group, an aryl group, an alkoxy group, an alkoxycarbonyl group, an aminocarbonyl group, an aryloxy group, an acyl group, or an aryloxycarbonyl group which has L₁ as a substituent. R³ represents an alkyl group or an aryl group. n represents an integer from 1 to 4, and L¹ represents a n-valent linking group. The molecular weight of a (R¹—C(═C)—R²—)ₙ—L¹ group is preferably 320 or more.

In General Formula (K-B), R¹ is the same as R¹ in General Formula (K-A) and also has the same preferred range.

In General Formula (K-B), R² represents an alkyl group, an aryl group, an alkoxy group, an alkoxycarbonyl group, an aminocarbonyl group, an aryloxy group, an acyl group, or an aryloxycarbonyl group which has L¹ that is an n-valent linking group. The alkyl group, the aryl group, the alkoxy group, the alkoxycarbonyl group, the aminocarbonyl group, the aryloxy group, the acyl group, or the aryloxycarbonyl group are the same as those in General Formula (K-A) and also have the same preferred ranges.

In General Formula (K-B), R³ is the same as R³ in General Formula (K-A) and also has the same preferred range.

In General Formula (K-B), L¹ is an n-valent linking group, and, here, n represents an integer from 1 to 4. Particularly, n is preferably an integer from 2 to 4.

In General Formula (K-B), specific examples of a divalent linking group represented by L¹ include, for example, groups represented by —NR⁸— (R⁸ represents a hydrogen atom, an alkyl group which may have a substituent, or an aryl group which may have a substituent and is preferably a hydrogen atom), —SO₂—, —CO—, a substituted or unsubstituted alkylene group, a substituted or unsubstituted alkenylene group, an alkynylene group, a substituted or unsubstituted phenylene group, a substituted or unsubstituted biphenylene group, a substituted or unsubstituted naphthalene group, —O—, —S—, —SO—, and groups obtained by combining two or more thereof. Examples of the substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (K-B), specific examples of a trivalent linking group represented by L¹ include, for example, groups obtained by removing one hydrogen atom from a linking group having a substituent out of the linking groups exemplified as the divalent linking group.

In General formula (K-B), specific examples of a tetravalent linking group represented by L¹ include, for example, groups obtained by removing two hydrogen atoms from a linking group having a substituent out of the linking groups exemplified as the divalent linking group.

In General Formula (K-B), when a divalent to tetravalent linking group is used as the linking group represented by L¹, it is possible to produce a compound having two or more ketenimine portions in the molecule and to exhibit a superior terminal-sealing effect. In addition, when a compound having two or more ketenimine portions in the molecule is used, it is possible to decrease the molecular weight per ketenimine group and to cause the ketenimine compound and the terminal carboxyl group in the polyester to effectively react with each other. Furthermore, when two or more ketenimine portions are included, it is possible to suppress the sublimation of the ketenimine compound or a ketene compound.

In General Formula (K-B), n is more preferably 3 or 4. When n is set to 3 or 4, it is possible to produce a compound including three or four ketenimine portions in one molecule and to exhibit a superior terminal-sealing effect. In addition, when n is set to 3 or 4, it is possible to suppress the sublimation of the ketenimine compound even in a case in which the molar molecular weight of the substituent of R¹ or R² in General Formula (K-B) is set to be small.

As the ketenimine compound, a ketenimine compound represented by General Formula (K-C) shown below is also preferably used.

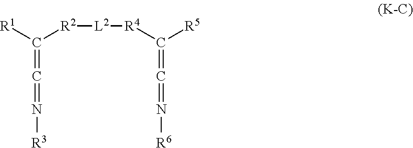

In General Formula (K-C), R¹ and R⁵ represent alkyl groups, aryl groups, alkoxy groups, alkoxycarbonyl groups, aminocarbonyl groups, aryloxy groups, acyl groups, or aryloxycarbonyl groups. R² and R⁴ represent alkyl groups, aryl groups, alkoxy groups, alkoxycarbonyl groups, aminocarbonyl groups, aryloxy groups, acyl groups, or aryloxycarbonyl groups which have L² as a substituent. R³ and R⁶ represent alkyl groups or aryl groups. L² represents a single bond or a divalent linking group. The molecular weight of a R¹—C(═C)—R²-L²-R⁴—C(═C)—R⁵ group is preferably 320 or more.

In General Formula (K-C), R¹ is the same as R¹ in General Formula (K-A) and also has the same preferred range. In addition, R⁵ is the same as R¹ in General Formula (K-A) and also has the same preferred range.

In General Formula (K-C), R² is the same as R² in General Formula (K-B) and also has the same preferred range. In addition, R⁴ is the same as R² in General Formula (K-B) and also has the same preferred range.

In General Formula (K-C), R³ is the same as R³ in General Formula (K-A) and also has the same preferred range. In addition, R⁶ is the same as R³ in General Formula (K-A) and also has the same preferred range.

In General Formula (K-C), L² represents a single bond or a divalent linking group. Specific examples of the divalent linking group include the linking groups exemplified as L¹ in General Formula (K-B).

Here, the molecular weight of a portion excluding the nitrogen atom and the substituent bonded to the nitrogen atom in the ketenimine compound is preferably 320 or more. The molecular weight of the portion excluding the nitrogen atom and the substituent bonded to the nitrogen atom in the ketenimine compound may be 320 or more, preferably 400 or more, and more preferably 500 or more. In addition, the molar molecular weight of the ketenimine compound with respect to the number of the ketenimine portions in one molecule (the molar molecular weight/the number of the ketenimine portions) is preferably 1000 or less, more preferably 500 or less, and still more preferably 400 or less. When the molecular weight of the substituent on carbon in the ketenimine portion of the ketenimine compound and the molar molecular weight of the ketenimine compound with respect to the number of the ketenimine portions are set in the above-described ranges, the sublimation of the ketenimine compound is suppressed, the sublimation of the ketene compound occurring when the terminal carboxyl group of the polyester is sealed is suppressed, and furthermore, it is possible to seal the terminal carboxyl group of the polyester with a small amount of the ketenimine compound added.

The ketenimine compound having at least one ketenimine group can be synthesized with reference to the method described in, for example, J. Am. Chem. Soc., 1953, 75(3), pp. 657 to 660.

Hereinafter, specific preferred examples of the ketenimine compounds represented by General Formulae (K-A) to (K-C) will be illustrated, but the present invention is not limited thereto.

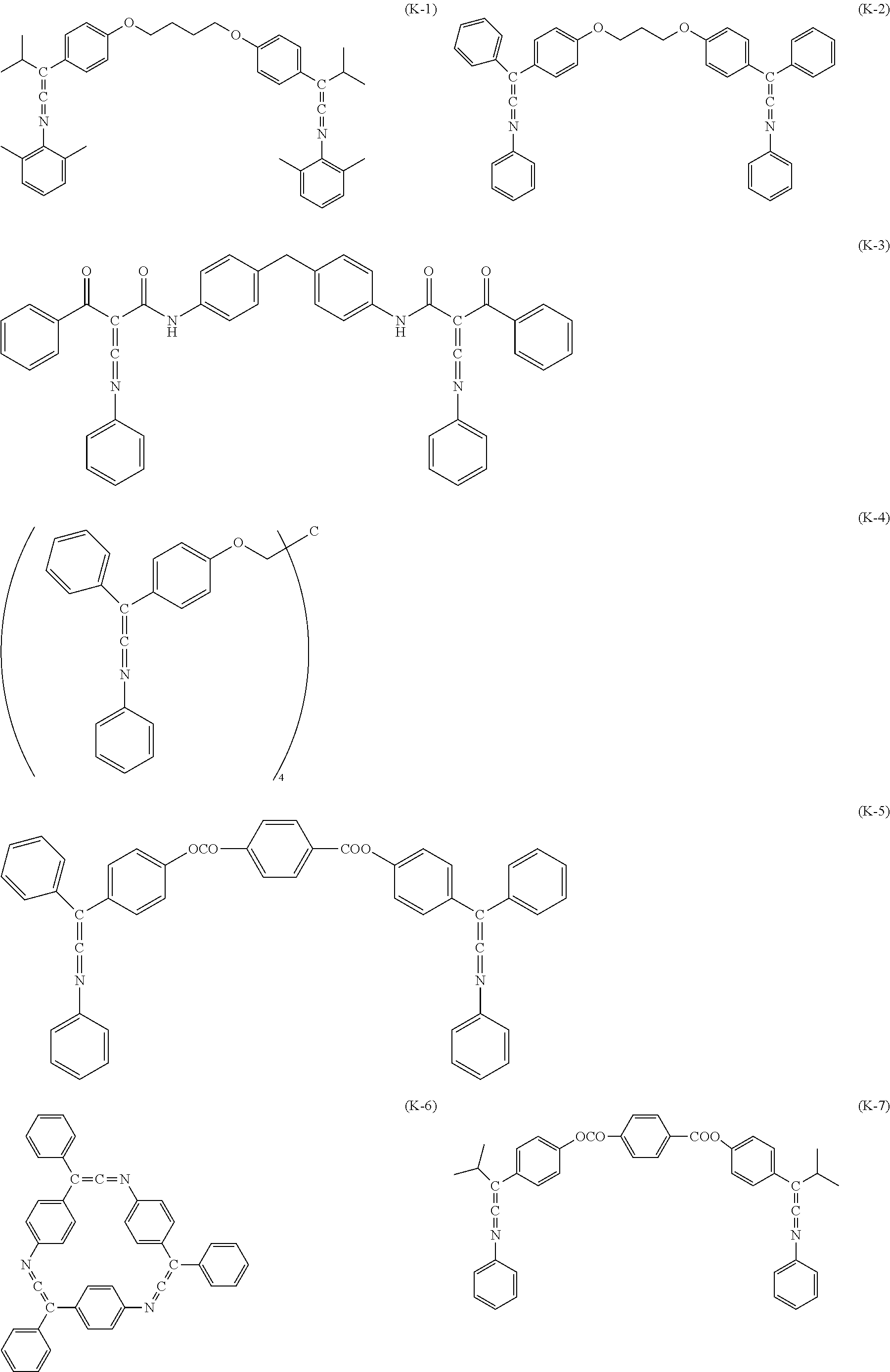

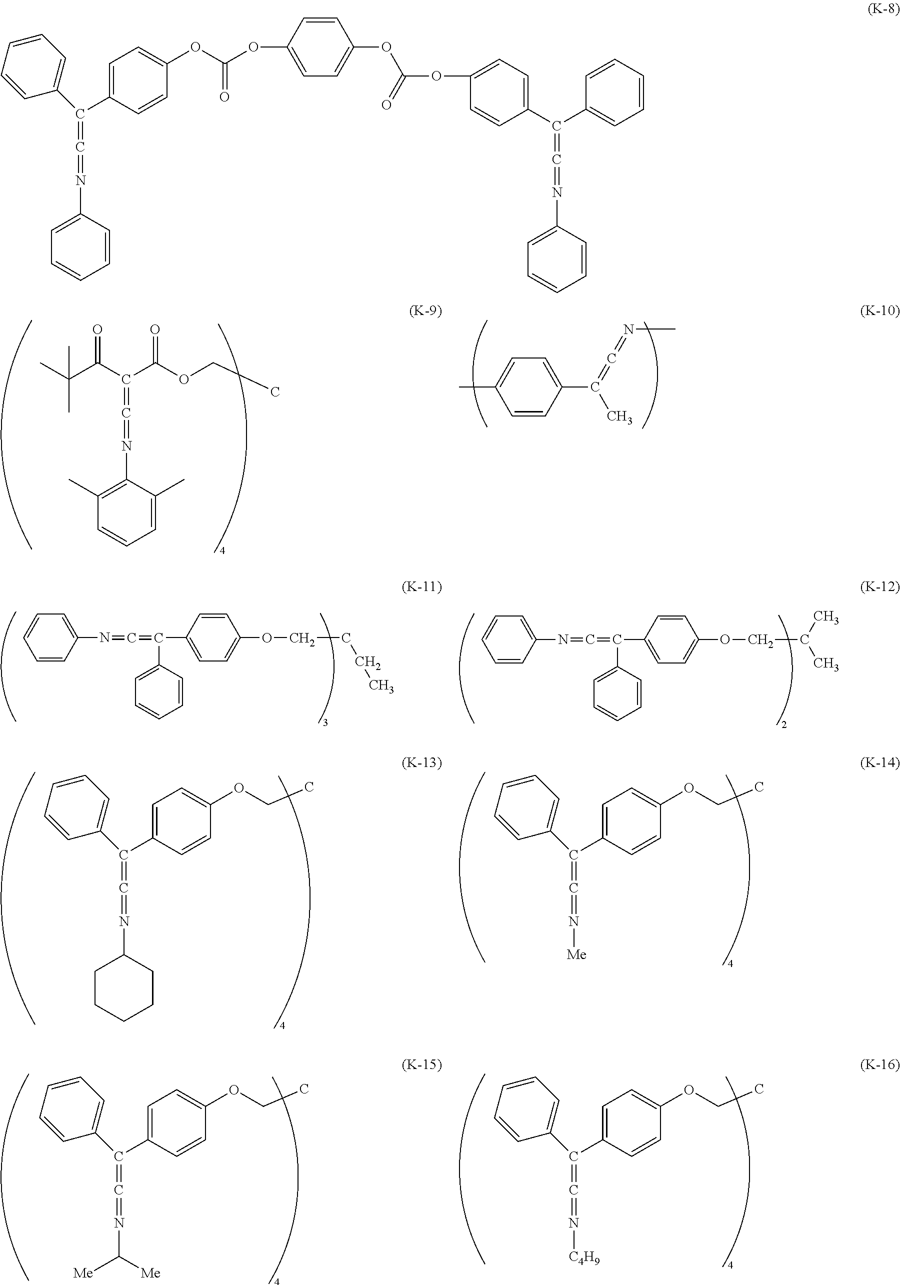

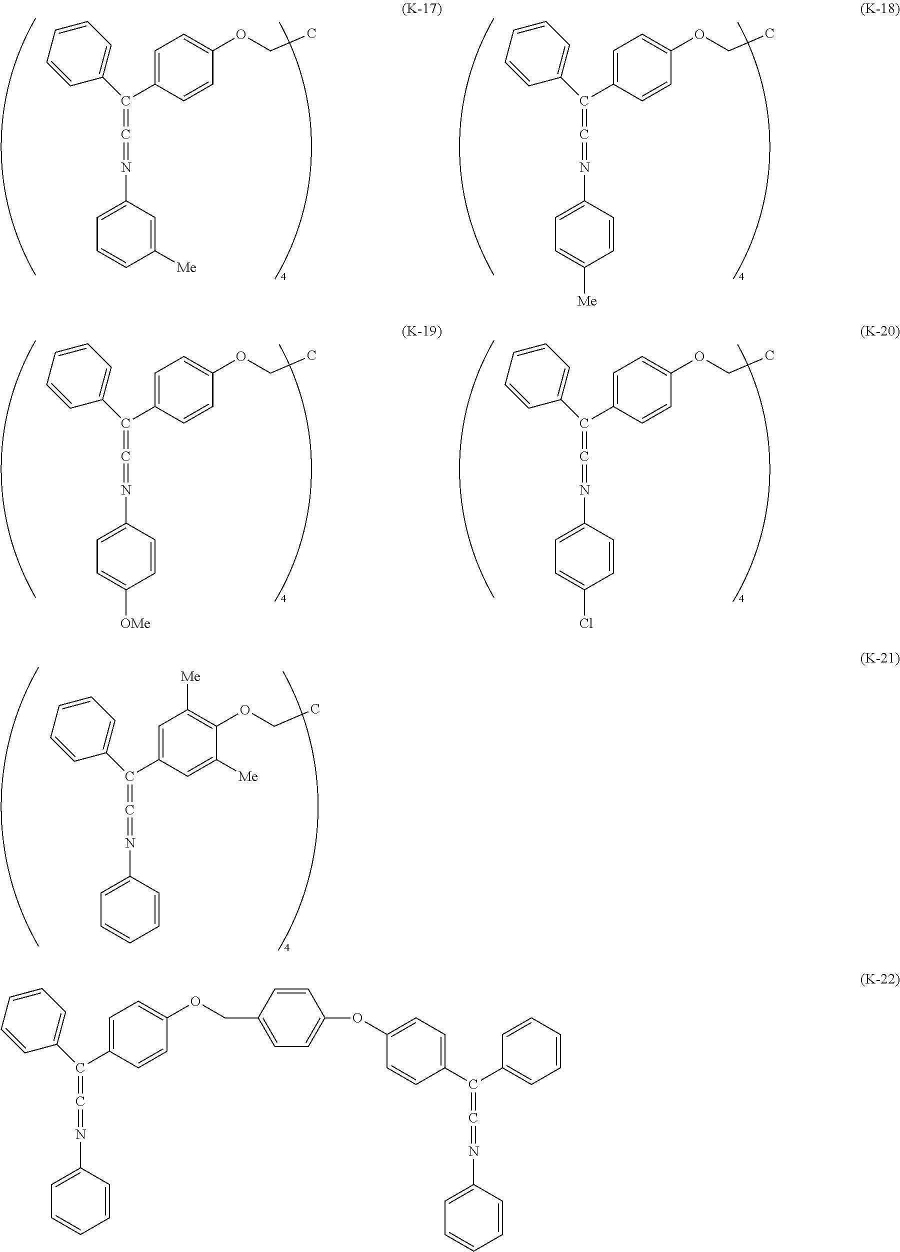

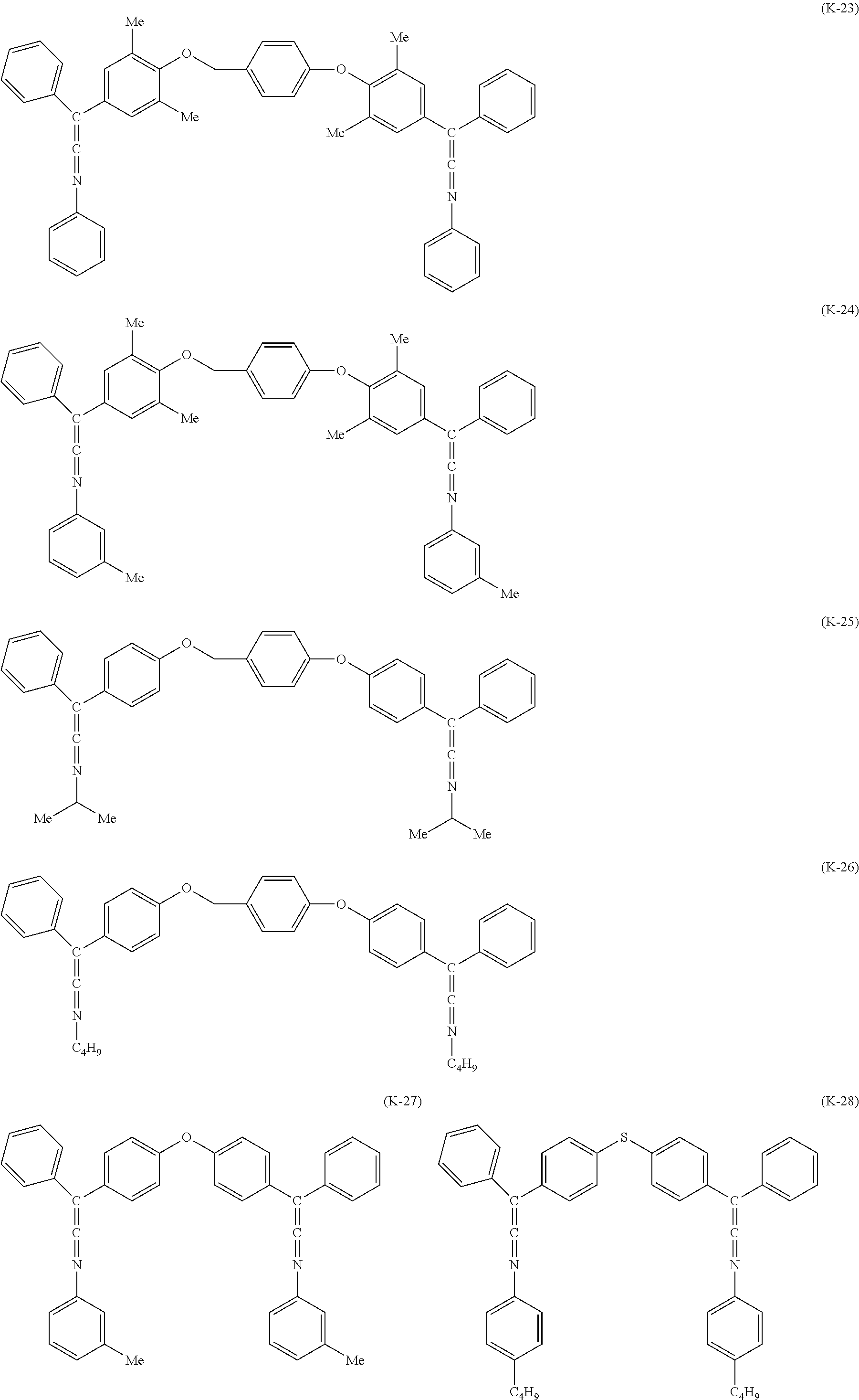

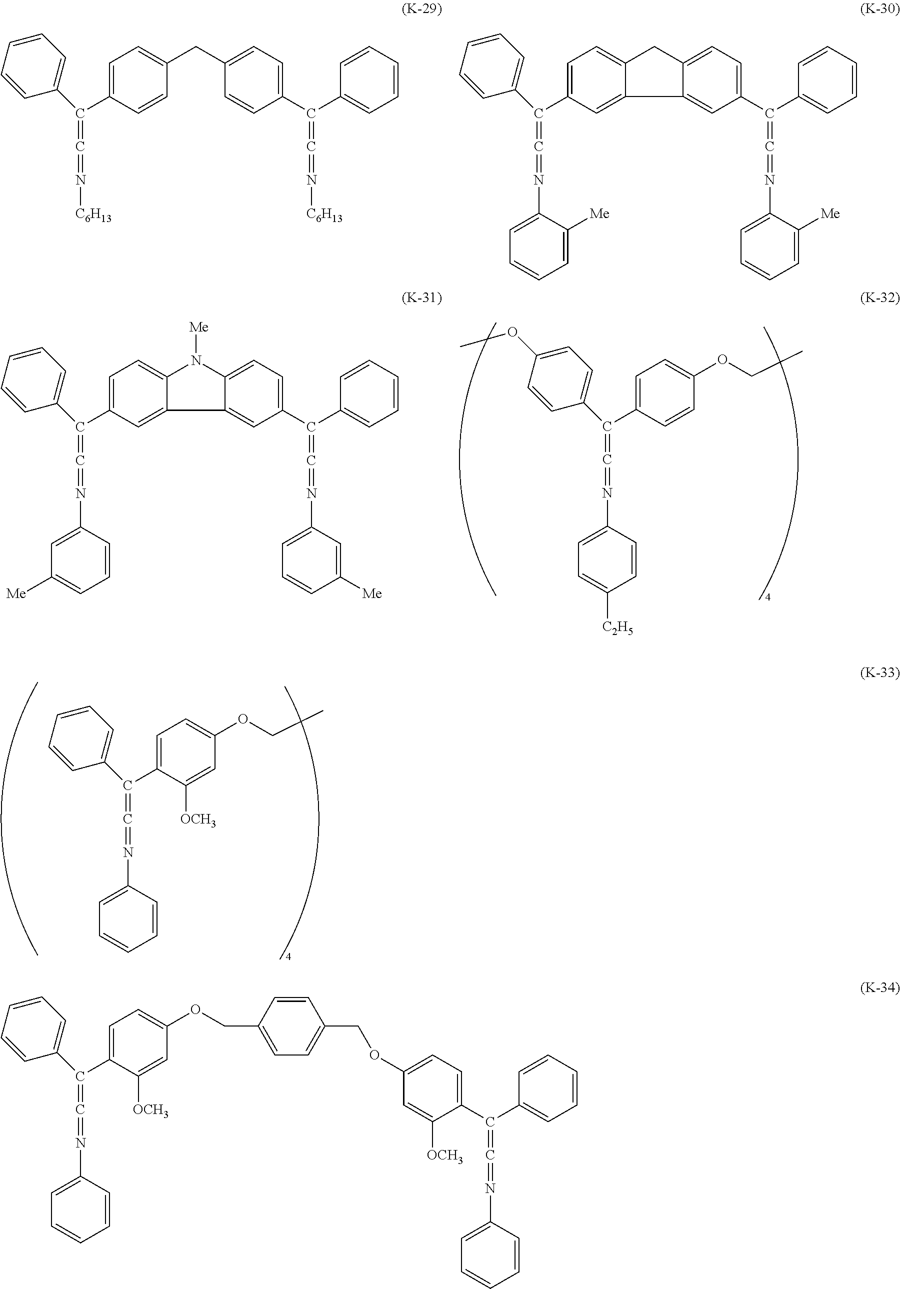

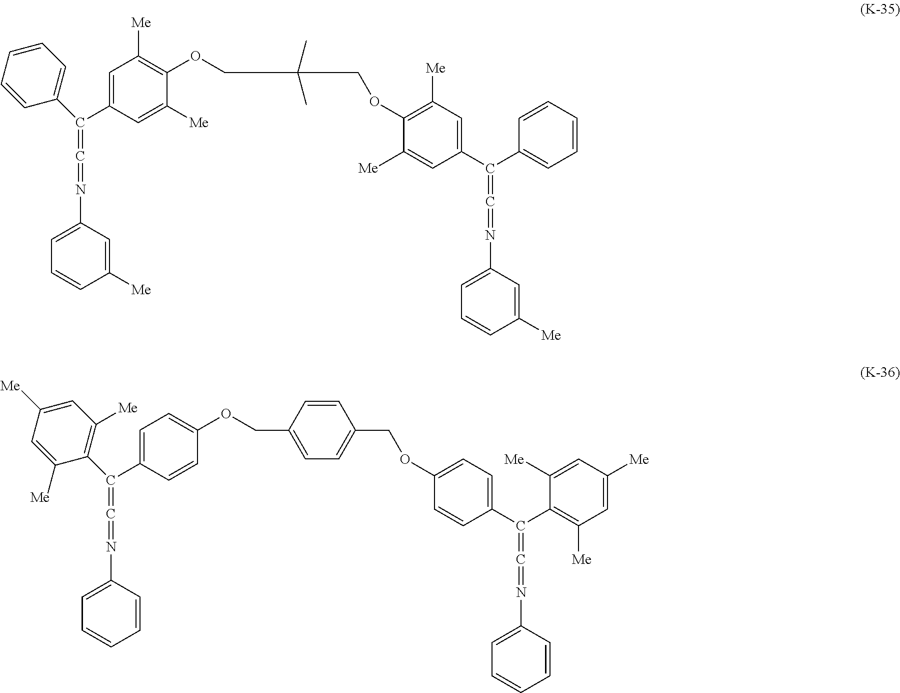

As illustrated in the above-exemplified compounds, the ketenimine compound is more preferably a trifunctional or tetrafunctional compound. In such a case, it is possible to further enhance the terminal-sealing effect of the raw material resin such as polyester and to effectively suppress the sublimation of the ketenimine compound or the ketene compound.

In addition, in a case in which the ketenimine compound has a ring structure in which a cyclic skeleton is formed in the ketenimine portion as illustrated in Exemplary Compound (K-6), in General Formulae (K-A) to (K-C), R¹ and R³ are linked to each other so as to form a ring structure, and R³ is formed of an alkylene group or an arylene group having a cyclic skeleton. In this case, R¹ has a linking group including the ketenimine portion.

Exemplary Compound (K-10) illustrates the repeating unit of which as many as n are included in General Formulae (K-A) to (K-C), and n represents an integer of 3 or more. The left terminal illustrated in Exemplary Compound (K-10) is a hydrogen atom, and the right terminal is a phenyl group.

—Method for Manufacturing Supporter—

Hereinafter, a preferred aspect of a method for manufacturing the supporter will be described using a case in which the supporter is the polyester as an example.

The supporter is preferably a biaxial stretched film obtained by, for example, melt-extruding the polyester in a film form, solidifying the polyester film through cooling using a casting drum so as to produce an un-stretched film, stretching the un-stretched film in the longitudinal direction once or more at a temperature in a range of Tg° C. to (Tg+60)° C. so that the total stretching ratio reaches three times to six times, and then stretching the film in the width direction at a temperature in a range of Tg° C. to (Tg+60)° C. so that the ratio reaches three times to five times.

Furthermore, the polyester film may be subjected to a thermal treatment at a temperature in a range of 180° C. to 230° C. for 1 second to 60 seconds.

Meanwhile, Tg represents the glass transition temperature and can be measured on the basis of JIS K7121, ASTMD3418-82, or the like. For example, In the present invention, Tg is measured using a differential scanning calorimeter (DSC) manufactured by Shimadzu Corporation.

Specifically, 10 mg of a polymer such as a polyester was weighed as a specimen and was set in an aluminum pan. The amount of heat with respect to temperature was measured using DSC while heating the specimen from room temperature to a final temperature of 300° C. at a temperature-increase rate of 10° C./min. At this time, the temperature at which the DSC curve curved was considered as the glass transition temperature.

Hereinafter, as a preferred aspect of the method for manufacturing the supporter, an example of a method for manufacturing a polyester film will be described.

Polyester Film-Forming Step:

In a polyester film-forming step, that is, a step of forming a polyester film, a molten substance obtained by melting the polyester included in a resin composition and at least one of the ketenimine compound, the carbodiimide compound, and the iminoether compound is caused to pass through a gear pump or a filter, then, is extruded through a die into a cooling roll, and is solidified through cooling. Therefore, a (un-stretched) film can be formed. The melting is carried out using an extruder, but a monoaxial extruder may be used or a biaxial extruder may be used.

The carbodiimide compound, the ketenimine compound, or the iminoether compound may be directly added to the extruder, but it is preferable to form a master batch with the polyester in advance and inject the master batch into the extruder from the viewpoint of extrusion stability. In a case in which the master batch is formed, it is preferable to vary the supply amount of the master batch including the ketenimine compound. Meanwhile, regarding the concentration of ketenimine in the master batch, a ketenimine-condensed master batch is preferably used, and the concentration of ketenimine is preferably set in a range of 2 times to 100 times and more preferably set in a range of 5 times to 50 times the concentration of ketenimine in the film after the formation of the film from the viewpoint of the cost.

The extrusion is preferably carried out under evacuation or in an inert gas atmosphere.

In such a case, it is possible to suppress the decomposition of a terminal-sealing material such as ketenimine, the carbodiimide compound, and the iminoether compound, and the like. The temperature of the extruder is preferably in a range of the melting point of the polyester being used to the melting point+80° C., more preferably in a range of the melting point+10° C. to the melting point+70° C., and still more preferably in a range of the melting point+20° C. to the melting point+60° C. When the temperature of the extruder is below the melting point+10° C., the resin does not sufficiently melt. On the other hand, when the temperature of the extruder is above the melting point+80° C., the polyester, the terminal-sealing material such as the ketenimine compound, the carbodiimide compound, or the iminoether compound, and the like are easily decomposed. Meanwhile, it is preferable to dry the polyester or the master batches of the terminal-sealing material such as the ketenimine compound, the carbodiimide compound, or the iminoether compound, and the like before the extrusion, and the moisture content is preferably in a range of 10 ppm to 300 ppm and more preferably in a range of 20 ppm to 150 ppm.

Meanwhile, the extruded molten substance is caused to pass through a gear pump, a filter, and a multilayer die and flow onto a casting drum. As the multilayer die, either of a multi-manifold die and a feedblock die can be preferably used. Regarding the shape of the die, any of a T die, a coat hanger die, and a fish tail may be used. At the front end of the above-described die (die lip), the temperature is preferably changed as described above. On the casting drum, it is possible to closely attach the molten resin (melt) to the cooling roll using an electrostatic application method. At this time, it is preferable to change the driving speed of the casting drum as described above. The surface temperature of the casting drum can be set in a range of approximately 10° C. to 40° C. The diameter of the casting drum is preferably in a range of 0.5 m to 5 m and more preferably in a range of 1 m to 4 m. The driving speed of the casting drum (the linear speed of the outermost circumference) is preferably in a range of 1 m/minute to 50 m/minute and more preferably in a range of 3 m/minute to 30 m/minute.

Stretching Step:

The (un-stretched) film formed through the film-forming step can be subjected to a stretching treatment in a stretching step. The stretching is preferably carried out in at least one direction of the machine direction (MD) and the transverse direction (TD) and more preferably carried out in both directions of the MD and TD since the properties of the film are balanced. The above-described bidirectional stretching may be sequentially carried out in the machine and transverse directions or may be carried out at the same time. In the stretching step, the (un-stretched) film solidified through cooling using the cooling roll is preferably stretched in one or two directions and more preferably stretched in two directions. The stretching in two directions (biaxial stretching) is preferably a combination of stretching in the longitudinal direction (MD: machine direction) (hereinafter, also referred to as “vertical stretching”) and stretching in the width direction (TD: transverse direction) (hereinafter, also referred to as “horizontal stretching”). The vertical stretching and the horizontal stretching may be carried out once respectively or may be carried out a plurality of times, and the stretching may be carried out vertically and horizontally at the same time.

The stretching treatment is preferably carried out at a temperature in a range of (Tg°) C to (Tg+60°) C, more preferably carried out at a temperature in a range of (Tg+3°) C to (Tg+40°) C, and still more preferably carried out at a temperature in a range of (Tg+5°) C to (Tg+30°) C. At this time, it is preferable to impart a temperature distribution as described above.

The preferred stretching ratio is, at least in a single direction, in a range of 280% to 500%, more preferably in a range of 300% to 480%, and still more preferably in a range of 320% to 460%. In the case of biaxial stretching, the polyester film may be equally stretched vertically and horizontally, but it is more preferable to unequally stretch the polyester film by setting the stretching ratio in one direction to be greater than that in the other direction. Either of the stretching ratios in the machine direction (MD) and in the transverse direction (TD) may be set to be greater. The stretching ratio mentioned herein is obtained using the following expression.

Stretching ratio (%)=100×{(length after stretching)/(length before stretching)}

The biaxial stretching treatment can be carried out by, for example, stretching the polyester film once or more in the longitudinal direction at a temperature in a range of the glass transition temperature of the film (Tg₁)° C. to (Tg₁+60)° C. so that the total ratio reaches three times to six times, and then stretching the film in the width direction at a temperature in a range of (Tg₁)° C. to (Tg+60)° C. so that the ratio reaches three times to five times.

In the vertical stretching treatment, the polyester film can be stretched in the longitudinal direction using two or more pairs of nip rollers having an increased outlet-side rotation speed (vertical stretching), or the polyester film may be stretched by gripping the polyester film in the width direction using chucks and then widening the gap between the chucks in the longitudinal direction.

The horizontal stretching can be carried out by gripping both ends of the film using chucks and widening both ends in an orthogonal direction (a direction perpendicular to the longitudinal direction) (horizontal stretching).

The simultaneous stretching can be carried out by combining the gripping of the polyester film using chucks, an operation of widening the gap between the chucks in the longitudinal direction, and an operation of widening the gap between the chucks in the width direction.

A step of coating an undercoat layer (inline coating layer) described below is preferably combined with this stretching step. The undercoat layer is preferably formed on the surface of the polyester film through coating before the above-described stretching step or between the instances of the stretching step. That is, in the present invention, it is preferable to stretch a polyester film base material at least once.

For example, the stretching step and the coating step can be carried out in a combination as described below.
(a) Vertical stretching→coating→horizontal stretching
(b) Coating→vertical stretching→horizontal stretching
(c) Coating→vertical and horizontal stretching at the same time
(d) Vertical stretching→horizontal stretching→coating→vertical stretching
(e) Vertical stretching→horizontal stretching→coating→horizontal stretching

Among these, (a), (b), and (c) are preferred, and (a) is more preferred. This method is preferred since the adhering force is strongest and facilities therefor are also compact.

In the stretching step, it is possible to carry out a thermal treatment on the film before or after the stretching treatment, preferably, after the stretching treatment. When the thermal treatment is carried out, fine crystals are generated, and mechanical characteristics or durability can be improved. The film may be subjected to a thermal treatment at a temperature in a range of 180° C. to 225° C. (more preferably in a range of 185° C. to 210° C.) for 1 second to 60 seconds (more preferably for 2 seconds to 30 seconds).

In the stretching step, it is possible to carry out a thermal relaxation treatment after the thermal treatment. The thermal relaxation treatment refers to a treatment of applying heat to the film in order for the relaxation of stress so as to contract the film. The thermal relaxation treatment is preferably carried out in both directions of the MD and TD of the film. Regarding a variety of conditions for the thermal relaxation treatment, the thermal relaxation treatment is preferably carried out at a temperature lower than the thermal treatment temperature, which is preferably in a range of 130° C. to 220° C. In addition, in the thermal relaxation treatment, the thermal contraction ratio (150° C.) of the film is preferably in a range of 1% to 12% and more preferably in a range of 1% to 10% in both the MD and TD. Furthermore, the thermal contraction ratio (150° C.) can be obtained by cutting out a sample which is 350 mm long in the measurement direction and is 50 mm wide, marking reference points in the vicinities of both edges of the sample in the longitudinal direction at intervals of 300 mm, fixing one edge to an oven having a temperature adjusted to 150° C., leaving the other edge to be free for 30 minutes, then, measuring the distances between the reference points at room temperature, defining this length as L (mm), and obtaining the thermal contraction ratio from the following expression using the measurement values.

Thermal contraction ratio (%) at 150° C.=100×(300−L)/300

In addition, a positive thermal contraction ratio indicates contraction, and a negative thermal contraction ratio indicates elongation.

Through the above-described steps, the polyester film is manufactured as the supporter.

In addition, an example of a method for manufacturing a white polyester film will be described.

The white polyester film includes at least a polyester resin and white particles. The white polyester film can be formed by providing the polyester film-forming step. The polyester film-forming step includes a step in which a polyester resin and white particles are mixed together, and the mixture is melted and kneaded using an extruder so as to be extruded in a sheet shape, and is solidified through cooling. Therefore, an un-stretched film is formed.

In the extrusion, an extrusion pressure in a range of, for example, 0.5 MPa to 30 MPa is imparted. The content of the white particles that can be mixed with the polyester resin is in a range of 0.3% by mass to 5.0% by mass of the polyester resin.

Meanwhile, in the polyester film, a polymer layer (average film thickness in a range of 0.03 μm to 0.5 μm) may be formed on one surface, and a functional layer (average film thickness in a range of 4.0 μm to 8.0 μm) may be formed on the other surface.

In the polyester film-forming step, when manufacturing white polyester, it is preferable to prepare master pellets obtained by mixing the polyester resin and the white particles with other additives as necessary and melting and kneading the mixture using an extruder. As the white particles, white particles selected from the above-described inorganic particles can be used. As the polyester resin used to prepare the master pellets, a polyester resin obtained by polymerization-condensing a diol component and a dicarboxylic acid compound according to an ordinary method and then processing the polymerization condensate in a pellet shape can be used. In addition, particles other than the white particles or a terminal-sealing agent such as a carbodiimide compound, a ketenimine compound, or an iminoether compound, which are included in the polyester film, are also mixed into the master pellets as necessary. The terminal-sealing agent such as a carbodiimide compound, a ketenimine compound, or an iminoether compound may be directly added to an extruder, but it is preferable to form a master batch in advance by mixing the terminal-sealing agent with polyester and melting and kneading the mixture and inject the master batch into the extruder from the viewpoint of extrusion stability.

In a step of preparing the master pellets, a drying step is preferably provided, and a composition of the particles, the terminal-sealing agent, or the polyester resin is dried in a vacuum or in hot air. In a drying step, the moisture content in the composition is set to 100 ppm or lower, more preferably set to 80 ppm or lower, and still more preferably set to 60 ppm or lower. The drying temperature at this time is preferably in a range of 80° C. to 200° C., more preferably in a range of 100° C. to 180° C., and still more preferably in a range of 110° C. to 170° C. The drying time can be appropriately adjusted to be a desired time so that the above-described moisture content is reached.

Next, the dried white particles and polyester are kneaded together, and master pellets in which the white particles are dispersed in a high concentration are produced. A concentration of the additives such as white particles, the terminal-sealing agent and the like in the master pellets is preferably in a range of 1.5 times to 20 times the concentration thereof used in the film, more preferably in a range of 2 times to 15 times, and still more preferably in a range of 3 times to 10 times. The reason for setting the concentration thereof added to be higher than the target concentration is that, in a film-forming step which is the next step, the white particles or the terminal-sealing agent is diluted due to the polyester pellets and thus the target concentration is reached.

For the kneading, a variety of kneaders such as a monoaxial extruder, a biaxial extruder, a Banbury mixer, and a Brabender can be used. Among these, a biaxial extruder is preferably used. The kneading temperature is preferably in a range of the crystal melting temperature (Tm) of the polyester resin to Tm+80° C., more preferably in a range of Tm+10C to Tm+70° C., and still more preferably in a range of Tm+20° C. to Tm+60° C. The kneading atmosphere may be any of in the air, in a vacuum, and in an inert gas flow, but is more preferably in a vacuum or in an inert gas flow. The kneading time is preferably in a range of 1 minute to 20 minutes, more preferably in a range of 2 minutes to 18 minutes, and still more preferably in a range of 3 minutes to 15 minutes. The kneaded resin is extruded in a strand shape, is cooled and solidified in the air or in a vacuum, then, is cut, and is pelletized.

The mater pellets is heated with the polyester resin which is added together with star pellets so that the peak temperature of the resin temperature reaches approximately 300° C. and is melted. After that, the molten resin (melt) is extruded in a film form through a die onto a cooling roll (extrusion step). The molten resin is solidified on the cooling roll, thereby forming a film. A film formed as described above becomes a cast film (un-stretched original fabric). The molten resin is preferably caused to pass through a gear pump and a filter through a melting pipe. In addition, it is also preferable to provide a static mixer in the melting pipe and accelerate the mixing of the resin and an added substance.

Meanwhile, in order to suppress the decomposition of the terminal-sealing agent, the above-described extrusion is preferably carried out under evacuation or in an inert gas atmosphere.

—Other Items—

The thickness of the supporter is preferably in a range of 30 μm to 350 μm; however, from the viewpoint of voltage resistance, the thickness thereof is more preferably in a range of 160 μm to 300 μm, and still more preferably in a range of 180 μm to 280 μm.

After the supporter is stored for 50 hours under conditions of 120° C. and a relative humidity of 100%, the breaking elongation is preferably 50% or more of the breaking elongation before the storage (hereinafter, the retention ratio of the breaking elongation before and after the treatment of the supporter that has been subjected to a heat-and-humidity treatment under the above-described conditions will also be simply referred to as “breaking elongation retention ratio”). When the breaking elongation retention ratio is 50% or higher, a change in response to hydrolysis is suppressed, and, in the case of long-term use, the adhesion state in the adhesion interface between a coating layer and the supporter is stably retained, whereby the peeling or the like of the supporter over time is prevented. Therefore, for example, even in a case in which the back sheet is placed for a long period of time in a high temperature and humidity environment such as outdoors or under the exposure to light, high durability performance is exhibited. More preferably, the time taken for the breaking elongation retention ratio to reach 50% is preferably in a range of 75 hours to 200 hours and more preferably in a range of 100 hours to 180 hours.

It is preferable that, after the supporter is thermally treated for 50 hours at 180° C., the breaking elongation is 50% or more of the breaking elongation before the thermal treatment. It is more preferable that, after the supporter is thermally treated for 80 hours at 180° C., the breaking elongation is 50% or more of the breaking elongation before the thermal treatment. It is still more preferable that, after the supporter is thermally treated for 100 hours at 180° C., the breaking elongation is 50% or more of the breaking elongation before the thermal treatment. In such a case, it is possible to make heat resistance favorable when the supporter is exposed to a high temperature.

When the supporter is thermally treated for 30 minutes at 150° C., the thermal contraction is preferably 1% or less and more preferably 0.5% or less in both the MD and TD. When the thermal contraction is maintained to be 1% or less, it is possible to prevent warping when a solar cell module is formed.

The supporter may be subjected to surface treatments such as a corona discharge treatment, a flame treatment, and a glow discharge treatment as necessary. Among these, the corona discharge treatment can be carried out at a low cost and thus is a preferred surface treatment method.

In the corona discharge treatment, a high frequency and a high voltage are applied between a metallic roll which is generally coated with a dielectric body (dielectric roll) and an insulated electrode so as to cause the insulation breakdown of air between electrodes, whereby the air between the electrodes is ionized and corona discharge is generated between the electrodes. In addition, the supporter is caused to pass through this corona discharge.

Regarding preferred treatment conditions used in the present invention, it is preferable that the gap clearance between the electrode and the dielectric roll is in a range of 1 mm to 3 mm, the frequency is in a range of 1 kHz to 100 kHz, and the applied energy is in a range of approximately 0.2 kV·A·minutes/m² to 5 kV·A·minutes/m².

The glow discharge treatment is a method which is also called a vacuum plasma treatment or a glow discharge treatment and in which plasma is generated through discharging in a gas in a low-pressure atmosphere (plasma gas), thereby treating the surface of a base material. Low-pressure plasma used in the treatment of the present invention is non-equilibrium plasma generated under conditions in which the pressure of the plasma gas is low. The treatment of the present invention is carried out by placing a film to be treated in this low-pressure plasma atmosphere.

As the method for generating plasma in the glow discharge treatment, it is possible to use a method of direct-current glow discharge, high-frequency discharge, microwave discharge, or the like. The power supply used for the discharge may be a direct current or an alternating current. In a case in which an alternating current is used, the frequency is preferably in a range of approximately 30 Hz to 20 MHz.

In a case in which an alternating current is used, a commercial frequency of 50 Hz or 60 Hz may be used or a high frequency in a range of approximately 10 kHz to 50 kHz may be used. In addition, a method of using a high frequency of 13.56 MHz is also preferred.

As the plasma gas used in the glow discharge treatment, it is possible to use an inorganic gas such as oxygen gas, nitrogen gas, water vapor gas, argon gas, or helium gas, and oxygen gas or a gas mixture of oxygen gas and argon gas is particularly preferred. Specifically, the gas mixture of oxygen gas and argon gas is desirably used. In a case in which oxygen gas and argon gas are used, the partial pressure ratio between both gases (oxygen gas and argon gas) is preferably in a range of approximately 100:0 to 30:70 and more preferably in a range of approximately 90:10 to 70:30. In addition, particularly, a method in which gas is not introduced into a treatment container, and a gas such as air entering the treatment container through leaking or water vapor emitted from a substance to be treated is used as the plasma gas is also preferred.

Here, as the pressure of the plasma gas, a low pressure capable of achieving non-equilibrium plasma conditions is required. A specific pressure of the plasma gas is preferably in a range of approximately 0.005 Torr to 10 Torr and more preferably in a range of approximately 0.008 Torr to 3 Torr. In a case in which the pressure of the plasma gas is lower than 0.005 Torr, there are cases in which the adhesiveness-improving effect is insufficient, and conversely, when the pressure of the plasma gas exceeds 10 Torr, there are cases in which an electric current increases and thus discharging becomes unstable.

While it is not possible to name the specific value of the plasma output since the plasma output varies depending on the shape or size of the treatment container, the shape of the electrode, and the like, the plasma output is preferably in a range of approximately 100 W to 2500 W and more preferably in a range of approximately 500 W to 1500 W.

The treatment time of the glow discharge treatment is preferably in a range of approximately 0.05 seconds to 100 seconds and more preferably in a range of approximately 0.5 seconds to 30 seconds. In a case in which the treatment time is shorter than 0.05 seconds, there are cases in which the adhesiveness-improving effect is insufficient, and conversely, when the treatment time exceeds 100 seconds, there are cases in which a problem of the deformation or discoloration of a film to be treated occurs.

The discharge treatment intensity of the glow discharge treatment varies depending on the plasma output and the treatment time, but is preferably in a range of 0.01 kV·A·minutes/m² to 10 kV·A·minutes/m² and more preferably in a range of 0.1 kV·A·minutes/m² to 7 kV·A·minutes/m². When the discharge treatment intensity is set to 0.01 kV·A·minutes/m² or higher, a sufficient adhesiveness-improving effect can be obtained, and, when the discharge treatment intensity is set to 10 kV·A·minutes/m² or lower, it is possible to avoid the problem of the deformation or discoloration of the film to be treated.

In the glow discharge treatment, it is also preferable to heat the film to be treated in advance. In such a case, compared with a case in which the film is not heated, favorable adhesiveness can be obtained within a short period of time. The temperature of the heating is preferably in a range of 40° C. to the softening temperature of the film to be treated+20° C. and more preferably in a range of 70° C. to the softening temperature of the film to be treated. When the temperature of the heating is set to 40° C. or higher, a sufficient adhesiveness-improving effect can be obtained. In addition, when the temperature of the heating is set to the softening temperature or lower of the film to be treated, it is possible to ensure favorable handling properties of the film during the treatment.

Specific examples of a method for increasing the temperature of the film to be treated in a vacuum include heating using an infrared heater and heating by bringing the film into contact with a hot roll.

[Coating Layer (B) Including Polymer Having Yield Point: (B) Layer]

In the back sheet of the present invention, the (B) layer including a polymer having a yield point is provided on at least one surface of the supporter.

Whether or not the polymer included in the (B) layer has a yield point and the yield point of the polymer are measured using the following method.

(Method for Measuring Yield Point of Polymer)

First, a polymer the yield point of which is to be measured is applied to a CERAPEEL (manufactured by Toray Industries, Inc.) so that the film thickness of a dried film reaches 15 m and is dried at 170° C. for two minutes, thereby forming a polymer film on the surface of the CERAPEEL.

The polymer film formed on the surface of the CERAPEEL is stored in a high temperature and humidity environment of 121° C. and 100% for 30 hours, then, is cut into dimensions of 3 cm×5 mm, and is peeled off from the CERAPEEL.

A tensile test for a polymer film is carried out on the obtained polymer using a tensile tester (TENSILON manufactured by A&D Company) in an environment of 23.0° C. and 50.0% at a rate of 50 mm/min, and elongatedness and stress are measured.

In this tensile test, the polymer film elongates as the tensile stress increases; however, when the tensile stress exceeds a certain stress, a phenomenon occurs in which the tensile stress decreases while the polymer film further distorts (elongates). When this phenomenon appears, the polymer film is determined to be “yielded”, and the stress at this point is called a yield point. A polymer exhibiting the above-described behavior is determined to “have a yield point”.

On the other hand, a polymer film which elongates as the tensile stress increases and ruptures at a certain stress is determined to “not have a yield point”.

For the polymer having a yield point which is used in the (B) layer, a polymer serving as the base thereof is not particularly limited and is selected from an acrylic resin, an olefin-based resin, a urethane-based resin, a polyester resin, and the like. However, the polymer film needs to have a yield point according to the above-described measurement method.

For the polymer having a yield point, a polymer film is produced through solvent film formation or latex film formation, and the yield point is measured using the above-described measurement method.

The polymer having a yield point may be used after being dissolved in an organic solvent or may be used in the form of a dispersion obtained by dispersing polymer particles in water. The use of the polymer dispersed in water is preferred in consideration of the enviromnent.

The polymer having a yield point can be procured from commercially available products, and examples thereof include Mitsui Chemicals Inc.'s, BONRON XPS001, BONRON XPS002 (both are trade names: acrylic resin particle dispersions), Toyobo Co., Ltd.'s HARDLEN NZ-1001 (trade name: acid-denatured olefin-based resin particle dispersions), and the like.

Only one polymer having a yield point may be used or a mixture of two or more polymers may be used. However, in a case in which two or more polymers are mixed together, a film formed of a mixture of the polymers needs to have a yield point. Generally, 50% by mass or more of polymers to be mixed preferably have a yield point, 70% by mass or more of polymers to be mixed more preferably have a yield point, and all polymers to be mixed particularly preferably have a yield point.

The (B) layer is formed by dissolving the polymer having a yield point in an appropriate solvent or by applying and drying a substance obtained by dispersing polymer particles in a dispersion medium. A composition for forming the (B) layer may include additional additives as necessary in addition to the polymer having a yield point and the solvent or the dispersion medium. The composition for forming the (B) layer is preferably used in a form of being dispersed in water in consideration of the environment.

—Other Additives—

Examples of other additives include inorganic particles for improving film strength, a crosslinking agent, a surfactant for improving the evenness of a coated film, a colorant, an ultraviolet absorber, an antioxidant, a preservative, and the like depending on a function to be imparted to the (B) layer.

—Inorganic Particles—

The coating layer (B) preferably includes inorganic particles. Examples of the inorganic particles include silica particles such as colloidal silica, particles of a metallic oxide such as titanium oxide, aluminum oxide, zirconium oxide, magnesium oxide, or tin oxide, particles of an inorganic carbonate such as calcium carbonate or magnesium carbonate, particles of a metallic compound such as barium sulfate, and particles of a black pigment such as carbon black. Among these, as a white pigment, colloidal silica, titanium oxide particles, aluminum oxide particles, zirconium oxide, and the like are preferred, and as a black pigment, carbon black and the like are preferred.

In the (B) layer, only one kind of inorganic particles may be included, or two or more kinds of inorganic particles may be jointly used. In a case in which two or more kinds of inorganic particles are jointly used, two or more white pigments may be used, two or more black pigments may be used, or a white pigment and a black pigment may be jointly used.

Here, when a black pigment is used as the inorganic particles, it is possible to provide shielding properties to the solar cell back sheet.

In a solar cell, from the viewpoint of designability, wires connecting power generation elements and the like are preferably invisible to the outside, and a solar cell back sheet provided with high shielding properties is a preferable aspect. In order to improve the shielding properties of the film, a polyester film obtained by directly adding carbon black, which is a black pigment, to a polyester is known. However, when carbon black is directly added to a polyester, there has been a problem in that the carbon black serves as a crystallization nucleus, the crystallization rate of the polyester increases, and thus the molding of a film through stretching becomes difficult, or, in a case in which a film obtained using a polyester is placed in a hot and humid atmosphere, the speed of an increase in the degree of crystallization of the film is fast, the film becomes brittle at an early phase, and the moisture and heat resistance of the film degrades.

In the present invention, when a black pigment such as carbon black is added to the (B) layer, not only an effect of the inorganic particles for improving strength but also an advantage of imparting high shielding properties to the solar cell back sheet while suppressing the degradation of the moisture and heat resistance of the polyester film which serves as the supporter are provided.

Colloidal silica which can be used for the (B) layer refers to a substance in which particles of, mainly, a silicon oxide are present in a colloidal form using water, an alcohol, a diol, or the like, or a mixture thereof as a dispersion medium.

Regarding the particle diameters of colloidal silica particles, the average primary particle diameter is in a range of approximately several nm to 100 nm. The average particle diameter can be measured from an electron micrograph captured using a scanning electron microscope (SEM) or the like or can be measured using a particle size distribution analyzer in which a dynamic light scattering method or a static light scattering method is used. The shape of the colloidal silica particle may be a spherical shape, and the particles may be connected to each other in a beads shape.

Colloidal silica particles are commercially available, and examples thereof include SNOWTEX series manufactured by Nissan Chemical Industries, Ltd., CATALOID S series manufactured by JGC Catalysts and Chemicals Industries Co., Ltd., LEVASIL series manufactured by Bayer Holding Ltd., and the like. Specific examples thereof include SNOWTEX ST-20, ST-30, ST-40, ST-C, ST-N, ST-20L, ST-O, ST-OL, ST-S, ST-XS, ST-XL, ST-YL, ST-ZL, ST-OZL, ST-AK, SNOWTEX-AK-series, SNOWTEX-PS series, and SNOWTEX-UP series manufactured by Nissan Chemical Industries, Ltd.

Carbon black used in the (B) layer is not particularly limited, and carbon black which is known as a black pigment can be appropriately selected and used.

In the present invention, in order to obtain a strong coloration strength with a small amount of carbon black, as the carbon black, carbon black particles are preferably used, carbon black particles having a primary particle diameter of 1 μm or smaller are more preferably used, and carbon black particles having a primary particle diameter in a range of 0.1 μm to 0.8 μm are particularly preferably used. Furthermore, carbon black particles are preferably used after being dispersed in water together with a dispersing agent.

Meanwhile, carbon black which can be procured from commercially available products may be used, and, for example, MF-5630 BLACK (trade name: manufactured by Dainichiseika Color and Chemicals Mfg. Co., Ltd.), the carbon black described in Paragraph “0035” of JP2009-132887A, or the like can be used.

The average particle diameter of the inorganic particles included in the coating layer (B) is not particularly limited; however, from the viewpoint of improving film strength and maintaining favorable adhesiveness, the average primary particle diameter is preferably equal to or smaller than the film thickness of the coating layer (B), more preferably equal to or smaller than half of the film thickness of the coating layer (B), and still more preferably equal to or smaller than a third of the film thickness of the coating layer (B).

In addition, specifically, the average primary particle diameter of the inorganic particles is preferably 1.0 μm or smaller, more preferably in a range of 10 nm to 700 nm, and still more preferably in a range of 15 nm to 300 nm.

In the present specification, as the average primary particle diameter of the inorganic particles, a value measured using a MICROTRACK FRA manufactured by Honeywell Inc. is used.

The percentage content of the inorganic particles in the coating layer (B) is preferably in a range of 10% by volume to 35% by volume and more preferably in a range of 20% by volume to 30% by volume.

[Crosslinking Agent]

The composition for forming the (B) layer preferably includes a crosslinking agent.

When the composition for forming the (B) layer includes a crosslinking agent, a crosslinking structure is formed in a film of a binder (the polymer having a yield point) included in the composition for forming the (B) layer, and a layer having further-improved adhesiveness and strength is formed.

Examples of the crosslinking agent include an epoxy-based crosslinking agent, an isocyanate-based crosslinking agent, a melamine-based crosslinking agent, a carbodiimide-based crosslinking agent, and an oxazoline-based crosslinking agent. From the viewpoint of ensuring adhesiveness between the (B) layer and the inline coating layer and between the (B) layer and the polyester base material after storage of the back sheet in a hot and humid environment, among these, an oxazoline-based crosslinking agent is particularly preferred.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, bis-(2-oxazolinylnorbornane) sulfide, and the like. Furthermore, (co)polymers of these compounds can also be preferably used.

In addition, as the oxazoline-based crosslinking agent, a commercially available product may be used, and, for example, EPOCROS K2010E, K2020E, K2030E, WS500, WS700 (all manufactured by Nippon Shokubai Co., Ltd.), or the like can be used.

—Catalyst for Crosslinking Agent—

In the composition for forming the (B) layer, a catalyst for the crosslinking agent may be jointly used with the crosslinking agent. When the composition includes a catalyst for the crosslinking agent, a crosslinking reaction between the binder (resin) and the crosslinking agent is accelerated, and solvent resistance is improved. In addition, crosslinking favorably proceeds, and thus the strength and dimensional stability of the (B) layer can be further improved.

Particularly, in a case in which a crosslinking agent having an oxazoline group (oxazoline-based crosslinking agent) is used as the crosslinking agent, a catalyst for the crosslinking agent is preferably used.

Examples of the catalyst for the crosslinking agent include onium compounds.

Preferred examples of the onium compounds include ammonium salts, sulfonium salts, oxonium salts, iodonium salts, phosphonium salts, nitronium salts, nitrosonium salts, diazonium salts, and the like.

Specific examples of the onium compounds include ammonium salts such as monoammonium phosphate, diammonium phosphate, ammonium chloride, ammonium sulfate, ammonium nitrate, ammonium p-toluenesulfonate, ammonium sulfamate, ammonium imidodisulfonate, tetrabutylammonium chloride, benzyltrimethylammonium chloride, triethylbenzylammonium—chloride, tetrabutylammonium—tetrafluoroboron, tetrabutylammonium phosphorus hexafluoride, tetrabutylammonium perchlorate, and tetrabutylammonium sulfate;
sulfonium salts such as trimethylsulfonium iodide, trimethylsulfonium tetrafluoroboron, diphenylmethylsulfonium tetrafluoroboron, benzyltetramethylenesulfonium tetrafluoroboron, 2-butenyltetramethylenesulfonium antimony hexafluoride, and 3-methyl-2-butenyltetramethylenesulfonium antimony hexafluoride;
oxonium salts such as trimethyloxonium tetrafluoroboron;
iodonium salts such as diphenyl iodonium chloride and diphenyl iodonium tetrafluoroboron;
phosphonium salts such as cyanomethyltributylphosphonium antimony hexafluoride and ethoxycarbonylmethyltributylphosphonium tetrafluoroboron;
nitronium salts such as nitronium tetrafluoroboron; nitrosonium salts such as nitrosonium tetrafluoroboron;
diazonium salts such as 4-methoxybenzenediazonium chloride; and the like.

Among these, the onium compounds are more preferably the ammonium salts, the sulfonium salts, the iodonium salts, and the phosphonium salts in terms of shortening the curing time; among these, the ammonium salts are more preferred, and, from the viewpoint of safety, pH, and cost, phosphoric acid-based salts and benzyl chloride-based salts are preferred.

The onium compound is more particularly preferably ammonium diphosphate.

One catalyst for the crosslinking agent may be used or two or more catalysts for the crosslinking agent may be jointly used.

The amount of the catalyst for the crosslinking agent added is preferably in a range of 0.1% by mass to 15% by mass, more preferably in a range of 0.5% by mass to 12% by mass, particularly preferably in a range of 1% by mass to 10% by mass, and more particularly preferably in a range of 2% by mass to 7% by mass of the crosslinking agent. An added amount of the catalyst for the crosslinking agent of 0.1% by mass or higher of the crosslinking agent means that the crosslinking agent actively includes the catalyst for the crosslinking agent, and the inclusion of the catalyst for the crosslinking agent causes a crosslinking reaction between the polymer having a yield point, which is the binder, and the crosslinking agent to more favorably proceed, and superior durability is obtained. In addition, the inclusion of 15% by mass or lower of the catalyst for the crosslinking agent is advantageous in terms of solubility, filtering properties of a coating fluid, and adhesiveness between individual layers adjacent to each other.

—Thickness of (B) Layer—

The thickness of the (B) layer is preferably thicker than the thickness of the (C) layer, which is an easy-adhesion layer described below from the viewpoint of improving adhesiveness. That is, when the thickness of the (B) layer is represented by (b), and the thickness of the (C) layer is represented by (c), a relationship of (b)>(c) is preferred, and the ratio of (b) to (c) is more preferably in a range of 2:1 to 15:1.

In addition, the thickness of the (B) layer is preferably 0.5 μm or larger and more preferably 0.7 μm or larger. In addition, the thickness of the (B) layer is preferably 5.0 μm or smaller and more preferably 1.5 μm or smaller. When the thickness of the (B) layer and the balance between the thickness of the (B) layer and the thickness of the (C) layer are in the above-described ranges, the characteristics of the polymer film configuring the (B) layer are favorably developed, and adhesiveness between the supporter and the sealing material and durability are superior.

—Method for Forming (B) Layer—

As a method for forming the (B) layer, there is a method for forming the (B) layer through coating. The method for forming the (B) layer through coating is preferred since a highly even thin film can be easily formed. As a coating method, a well-known method such as gravure coating or bar coating can be used. A solvent (or a dispersion medium) for a coating fluid used for coating may be water or an organic solvent such as toluene or methyl ethyl ketone. The solvent may be singly used, or a mixture of two or more solvents may be used. As the composition for forming the (B) layer, a composition in which the polymer having a yield point is dispersed in water is preferably used in consideration of the environment.

In a case in which the (B) layer is formed through coating, it is preferable to carry out the drying and thermal treatment of a coated film at the same time in a drying zone.

After the composition for forming the (B) layer (coating fluid) is applied, a step for drying the coated film is preferably provided. The drying step is a step of supplying drying air to the coated film. The average speed of the drying air is preferably in a range of 5 m/second to 30 m/second, more preferably in a range of 7 m/second to 25 m/second, and still more preferably in a range of 9 m/second to 20 m/second.

It is also preferable to carry out a surface treatment such as a corona discharge treatment, a glow treatment, an atmospheric-pressure plasma treatment, a flame treatment, or an UV treatment on the surface of the supporter before the application of the (B) layer onto the supporter. In addition, it is also preferable to provide an inline coating layer formed by including an acid-denatured polyolefin.

(Undercoat Layer: Inline Coating Layer)

The inline coating layer is formed on the surface of the polyester film through coating before the stretching step of the polyester film used in the supporter as described above or between the instances of the stretching step.

The inline coating layer includes an acid-denatured polyolefin. When applying a composition for forming the inline coating layer, an aqueous solution or a water-based dispersion liquid (latex) is preferably applied. Since the acid-denatured polyolefin is a non-aqueous solution, a basic compound having a boiling point of 200° C. or lower is mixed into the aqueous solution or the water-based dispersion liquid (latex) as a neutralizing agent for imparting dispersion stability.

An example of the preparation of the composition for forming the inline coating layer will be described in detail.

First, an acid-denatured polyolefin is prepared.

As raw materials, a copolymer resin of ethylene and methacrylic acid, an organic solvent (for example, n-propanol), a basic compound, and distilled water are placed in a glass container equipped with a stirrer and a heater, the container is closed, and the raw materials are stirred and mixed together.

After the stirring and mixing, it is confirmed that a precipitate of a resin granulated substance is not observed at the bottom portion of the container and the resin granulated substance is in a floating state. After that, the glass container is fully covered with a lagging material, the heater is turned on, and the resin granulated substance is further stirred for 30 minutes to 120 minutes while maintaining the system temperature in a range of 50° C. to 250° C. After that, the heater is turned off, and the resin granulated substance is cooled through natural cooling under stirring.

After that, the lagging material covering the glass container is peeled off, and the resin granulated substance is cooled by immersing the lower half of the glass container in water.

Stirring is stopped when the system temperature reaches 35° C. or lower, the contents in the glass container are filtered using a stainless steel filter, whereby an aqueous dispersion body containing the acid-denatured polyolefin can be obtained.

After that, a crosslinking agent and distilled water are added to the obtained water dispersion body of the acid-denatured polyolefin, thereby obtaining a composition for forming the inline coating layer.

To this composition, a surfactant such as a nonionic surfactant or an anionic surfactant and the like may be further added depending on the purpose.

The coating method for coating the polyester film with the composition for forming the inline coating layer is not particularly limited, and a well-known method such as bar coating or slide coating can be used.

[Coating layer (C)]

A coating layer (C) is provided on a surface of the coating layer (B) opposite to the supporter.

The coating layer (C) is a layer which is located at a location at which the coating layer is in direct contact with a sealing material for a solar cell module to which the solar cell back sheet of the present invention is applied, that is, located as the outermost layer and functions as an easy-adhesion layer.

The coating layer (C) includes at least a binder and may include a variety of additives as desired.

—Binder—

Examples of the binder include one or more polymers selected from polyolefin resins, acrylic resins, polyester resins, and polyurethane resins. These resins are preferably used since an adhering force can be easily obtained. Specific examples of the binder include the following resins.

The acrylic resin is preferably, for example, a polymer containing polymethyl methacrylate or polyethyl acrylate, or the like. The acrylic resin is also preferably a composite resin of acryl and silicone. A commercially available acrylic resin on sale may be used, and examples thereof include AS-563A (manufactured by Daicel FineChem Ltd.), and JURYMER ET-410 and JURYMER SEK-301 (both manufactured by Nippon Junyaku K.K.). Examples of the composite resin of acryl and silicone include CERANATE WSA1060, CERANATE WSA1070 (both manufactured by DIC Corporation), and H7620, H7630, and H7650 (all manufactured by Asahi Kasei Chemicals Corporation).

The polyester resin is preferably, for example, polyethylene terephthalate (PET), polyethylene-2,6-naphthalate (PEN), or the like. A commercially available polyester resin on sale may be used, and, for example, VYLONAL MD-1245 (manufactured by Toyobo Co., Ltd.) can be preferably used.

The polyurethane resin is preferably, for example, a carbonate-based urethane resin, and, for example, SUPERFLEX 460 (manufactured by DKS Co., Ltd.) can be preferably used.

The polyolefin resin is preferably, for example, a modified polyolefin copolymer. A commercially available polyolefin resin on sale may be used, and examples thereof include ARROW-BASE SE-1013N, SD-1010, TC-4010, TD-4010 (all manufactured by Unitika Limited), HITECH S3148, HITECH S3121, HITECH S8512 (all manufactured by Toho Chemical Industry Co., Ltd.), CHEMIPAL S-120, CHEMIPAL S-75N, CHEMIPAL V100, CHEMIPAL EV210H (manufactured by Mitsui Chemicals, Inc.), and the like. Among these, ARROW-BASE SE-1013N manufactured by Unitika Limited, which is a ternary copolymer of low-density polyethylene, acrylic acid ester, and maleic acid anhydride, is preferably used since the adhesiveness is improved.

These polyolefin resins may be used singly or two or more polyolefin resins may be jointly used. In a case in which two or more polyolefin resins are jointly used, a combination of an acrylic resin and a polyolefin resin, a combination of a polyester resin and a polyolefin resin, or a combination of a urethane resin and a polyolefin resin is preferred and a combination of an acrylic resin and a polyolefin resin is more preferred.

In a case in which a combination of an acrylic resin and a polyolefin resin is used, the content of the acrylic resin in relation to the total amount of the polyolefin resin and the acrylic resin in the (C) layer is preferably in a range of 3% by mass to 50% by mass, more preferably in a range of 5% by mass to 40% by mass, and particularly preferably in a range of 7% by mass to 25% by mass.

It is possible to preferably combine a polyester resin (for example, VYLONAL MD-1245 (manufactured by Toyobo Co., Ltd.)) and the polyolefin resin and use the combination.

In addition, it is also preferable to add a polyurethane resin to the polyolefin resin, and the polyurethane resin is preferably, for example, a carbonate-based urethane resin, and, for example, SUPERFLEX 460 (manufactured by DKS Co., Ltd.) can be preferably used.

—Crosslinking Agent—

The binder (resin) included in the (C) layer may be crosslinked using a crosslinking agent. It is preferable to form a crosslinked structure in the (C) layer since, then, it is possible to further improve the adhesiveness. Examples of the crosslinking agent include the same crosslinking agents as exemplified for the (B) layer such as epoxy-based, isocyanate-based, melamine-based, carbodiimide-based, and oxazoline-based crosslinking agents. Among these, in the (C) layer, the crosslinking agent is preferably an oxazoline-based crosslinking agent. As a crosslinking agent having an oxazoline group, it is possible to use EPOCROS K2010E, EPOCROS K2020E, EPOCROS K2030E, EPOCROS WS-500, EPOCROS WS-700 (all manufactured by Nippon Shokubai Co., Ltd.), or the like.

The amount of the crosslinking agent added is preferably in a range of 0.5% by mass to 50% by mass, more preferably in a range of 3% by mass to 40% by mass, and particularly preferably in a range of 5% by mass or higher and lower than 30% by mass of the binder included in the (C) layer. Particularly, when the amount of the crosslinking agent added is 0.5% by mass or higher, a sufficient crosslinking effect is obtained while maintaining the intensity and adhesiveness of the (C) layer; when the amount thereof is 50% by mass or lower, the pot life of a coating fluid is maintained for a long period of time; when the amount thereof is lower than 40% by mass, the coating surface properties can be improved.

—Catalyst for Crosslinking Agent—

In a case in which a crosslinking agent is used for the (C) layer, a catalyst for the crosslinking agent may be jointly used with the crosslinking agent. When a catalyst for the crosslinking agent is included, a crosslinking reaction between the binder (resin) and the crosslinking agent is accelerated, and the solvent resistance is improved. In addition, the favorable progress of crosslinking may lead to an improvement of the adhesiveness between the (C) layer and a sealing material.

Particularly, in a case in which a crosslinking agent having an oxazoline group (an oxazoline-based crosslinking agent) is used as the crosslinking agent, the catalyst for the crosslinking agent is preferably used.

Examples of the catalyst for the crosslinking agent include onium compounds.

Preferred examples of the onium compounds include ammonium salts, sulfonium salts, oxonium salts, iodonium salts, phosphonium salts, nitronium salts, nitrosonium salts, diazonium salts, and the like.

As the catalyst for the crosslinking agent, the compounds exemplified for the (B) layer can be used in the same manner, and the preferred range thereof is also identical.

One catalyst for the crosslinking agent included in the (C) layer may be used or two or more catalysts for the crosslinking agent may be jointly used.

The amount of the catalyst for the crosslinking agent added is preferably in a range of 0.1% by mass to 15% by mass, more preferably in a range of 0.5% by mass to 12% by mass, particularly preferably in a range of 1% by mass to 10% by mass, and more particularly preferably in a range of 2% by mass to 7% by mass of the crosslinking agent. An added amount of the catalyst for the crosslinking agent of 0.1% by mass or higher of the crosslinking agent means that the crosslinking agent actively includes the catalyst for the crosslinking agent, and the inclusion of the catalyst for the crosslinking agent causes a crosslinking reaction between the binder and the crosslinking agent to favorably proceed, and superior solvent resistance is obtained. In addition, the inclusion of 15% by mass or lower of the catalyst for the crosslinking agent is advantageous in terms of solubility, the filtering properties of the coating fluid, and adhesion to the sealing material.

The (C) layer may include a variety of additives in addition to the binder as long as the effect of the present invention is not impaired.

Examples of the additives include an antistatic agent, an ultraviolet absorber, a colorant, a preservative, and the like.

Examples of the antistatic agent include a surfactant such as a nonionic surfactant, an organic conductive material, an inorganic conductive material, an organic/inorganic composite conductive material, and the like.

A surfactant used as the antistatic agent which can be included in the (C) layer is preferably a nonionic surfactant, an anionic surfactant, or the like. Among these, a nonionic surfactant is preferred, and a nonionic surfactant which has an ethylene glycol chain (polyoxyethylene chain; —(CH₂—CH₂—O)ₙ—) but does not have a carbon-carbon triple bond (alkyne bond) is preferred. Furthermore, a nonionic surfactant having 7 to 30 ethylene glycol chains is particularly preferred.

More specific examples thereof include hexaethylene glycol monododecyl ether, 3,6,9,12,15-pentaoxahexadecan-1-ol, polyoxyethylene phenyl ether, polyoxyethylene methyl phenyl ether, polyoxyethylene naphthyl ether, polyoxyethylene methyl naphthyl ether, and the like, but the nonionic surfactant is not limited thereto.

In a case in which the surfactant is used as the antistatic agent, the content of the surfactant is preferably in a range of 2.5% by mass to 40% by mass, more preferably in a range of 5.0% by mass to 35% by mass, and still more preferably in a range of 10% by mass to 30% by mass in terms of the weight of solid contents.

With the content of the surfactant in the above-described range, the dropping of the partial discharge voltage is suppressed, and adhesiveness between the sealing material for sealing a solar cell element and a sealing material (for example, EVA: ethylene vinyl acetate copolymer) is favorably maintained.

Examples of the organic conductive materials include cationic conductive compounds having a cationic substituent such as an ammonium group, an amine base, or a quaternary ammonium group in the molecule; anionic conductive compounds having anionic groups such as a sulfonate group, a phosphate group, or a carboxylate group; ionic conductive materials such as amphoteric conductive compounds having both an anionic substituent and a cationic substituent; and conductive macromolecular compounds having a conjugated polyene-based skeleton such as polyacetylene, polyparaphenylene, polyaniline, polythiophene, polyparaphenylene vinylene, and polypyrrole.

Examples of the inorganic conductive materials include substances obtained by oxidizing, sub-oxidizing, or hyper-oxidizing a substance mainly containing an inorganic substance such as gold, silver, copper, platinum silicon, boron, palladium, rhenium, vanadium, osmium, cobalt, iron, zinc, ruthenium, praseodymium, chromium, nickel, aluminum, tin, zinc, titanium, tantalum, zirconium, antimony, indium, yttrium, lanthanum, magnesium, calcium, cerium, hafnium, or barium; mixtures of the above-described inorganic substance and a substance obtained by oxidizing, sub-oxidizing, or hyper-oxidizing the above-described inorganic substance (hereinafter, referred to as inorganic oxides); substances obtained by nitriding, sub-nitriding, or hyper-nitriding a substance mainly containing the above-described inorganic substance; mixtures of the above-described inorganic substance and a substance obtained by nitriding, sub-nitriding, or hyper-nitriding the above-described inorganic substance (hereinafter, referred to as inorganic nitrides); substances obtained by oxynitriding, sub-oxynitriding, or hyper-oxynitriding a substance mainly containing the above-described inorganic substance; mixtures of the above-described inorganic substance and a substance obtained by oxynitriding, sub-oxynitriding, or hyper-oxynitriding the above-described inorganic substance (hereinafter, referred to as inorganic oxynitrides); substances obtained by carbonizing, sub-carbonizing, or hyper-carbonizing a substance mainly containing the above-described inorganic substance; mixtures of the above-described inorganic substance and a substance obtained by carbonizing, sub-carbonizing, or hyper-carbonizing the above-described inorganic substance (hereinafter, referred to as inorganic carbides); substances obtained by halogenating, sub-halogenating, or hyper-halogenating at least one of a fluoride, a chloride, a bromide, and an iodide of a substance mainly containing the above-described inorganic substance; mixtures of the above-described inorganic substance and a substance obtained by halogenating, sub-halogenating, or hyper-halogenating the above-described inorganic substance (hereinafter, referred to as inorganic halides); substances obtained by sulfurizing, sub-sulfurizing, or hyper-sulfurizing a substance mainly containing the above-described inorganic substance; mixtures of the above-described inorganic substance and a substance obtained by sulfurizing, sub-sulfurizing, or hyper-sulfurizing the above-described inorganic substance (hereinafter, referred to as inorganic sulfides); substances obtained by doping a different element into the inorganic substance; carbon-based compounds such as graphite-form carbon, diamond-like carbon, carbon fibers, carbon nanotubes, and fullerenes (hereinafter, referred to as carbon-based compounds); and mixtures thereof.

The solar cell back sheet of the present invention includes at least the coating layer (B) and the coating layer (C) on the supporter in this order. When this configuration is provided, the back sheet of the present invention becomes excellent in terms of adhesiveness to the sealing material, durability, and weather resistance.

Meanwhile, the back sheet may have at least one weather-resistant layer described below in detail on the rear surface side of the supporter. When the weather-resistant layer is provided, the influence of the enviromnent on the supporter is suppressed, and weather resistance and durability are further improved.

Hereinafter, as the weather-resistant layer that is preferably used in the present invention, a coating layer (D) and a coating layer (E) will be described in detail using examples.

[Weather-Resistant Layer Including Binder, Colorant, and Scattering Particles: Coating Layer (D)]

Examples of the weather-resistant layer include a layer including a binder, a colorant, and scattering particles [coating layer (D)]. The above-described weather-resistant layer will be appropriately referred to as (D) layer.

In a solar cell having a laminate structure of a cell-side substrate [=a transparent base material on a side on which sunlight is incident (glass substrate or the like)/an element structure portion including a solar cell element]/a solar cell back sheet, the (D) layer is a rear surface protective layer disposed on a side of the supporter opposite to a side on which the supporter is in contact with the cell-side substrate in the solar cell back sheet.

The (D) layer may have a single-layer structure or a laminate structure made up of a plurality of layers. In the case of a single layer, an aspect in which a layer including a binder, a colorant, and scattering particles is disposed on a polymer supporter is preferred.

Meanwhile, in the case of the laminate structure, an aspect in which two layers including the binder, the colorant, and the scattering particles are laminated on a polymer supporter or an aspect in which a layer including the binder, the colorant, and the scattering particles is formed on a polymer supporter, and furthermore, a weather-resistant layer including an arbitrary fluorine-based polymer and including neither a colorant nor scattering particles (for example, a layer of another composition such as a coating layer (E) described below in detail) is laminated thereon can also be employed.

—Binder—

The binder used in the (D) layer may be a binder formed of any one of an organic polymer, an inorganic polymer, and an organic and inorganic complex polymer. When the polymer is included, adhesion to the supporter or adhesion between layers in a case in which a laminate structure made up of two or more weather-resistant layers is employed is improved, and degradation resistance in a hot and humid environment is obtained.

The inorganic polymer is not particularly limited, and a well-known inorganic polymer can be used. The organic polymer or the organic and inorganic complex polymer is not particularly limited, but a binder including either or both a fluorine-based polymer and a silicone-based polymer is preferred, a binder including either or both a fluorine-based organic polymer and a silicone-acryl organic and inorganic complex resin is more preferred, and a binder including a silicone-acryl organic and inorganic complex resin is particularly preferred.

<<Silicone-Based Polymer>>

The silicone-based polymer is a polymer having a (poly)siloxane structure in a molecular chain, and, when including the silicone-based polymer, the (D) layer becomes superior in terms of adhesiveness to an adjacent material such as the supporter in the solar cell back sheet or the coating layer (E) described below and durability in a hot and humid environment.

The silicone-based polymer is not particularly limited as long as the silicone-based polymer has a (poly)siloxane structure in a molecular chain and may be a homopolymer of a compound having a (poly)siloxane structure or a copolymer including a (poly)siloxane structural unit and another structural unit. The structural unit that copolymerizes with the siloxane structural unit is a non-siloxane-based structural unit.

The silicone-based polymer preferably has a siloxane structure represented by General Formula (1) below as the (poly)siloxane structure.

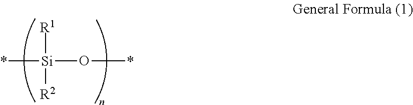

In General Formula (1), each of R¹ and R² independently represents a hydrogen atom, a halogen atom, or a monovalent organic group. Here, R¹ and R² may be identical to or different from each other, and a plurality of R¹'s or R²'s may be identical to or different from each other. n represents an integer of 1 or higher.

The partial structure of “—(Si(R′)(R²)—O)n-”, which is the siloxane structural unit in the silicone-based polymer is a siloxane segment capable of forming a variety of (poly)siloxane structures having a linear, branched, or ring structure.

In a case in which each of R¹ and R² represents a halogen atom, examples of the halogen atom include a fluorine atom, a chlorine atom, an iodine atom, and the like.

In a case in which each of R¹ and R² represents a monovalent organic group, the monovalent organic group may be any group capable of forming a covalent bonding with a Si atom, and examples thereof include an alkyl group (for example, a methyl group or an ethyl group), an aryl group (for example, a phenyl group), an aralkyl group (for example, a benzyl group, phenyl ethyl, or the like), an alkoxy group (for example, a methoxy group, an ethoxy group, or a propoxy group), an aryloxy group (for example, a phenoxy group), a mercapto group, an amino group (for example, an amino group or a diethylamino group), an amide group, and the like. These organic groups may be unsubstituted groups or may further have a substituent. In a case in which the organic group further has a substituent, examples of the substituent include an alkyl group having 1 to 20 carbon atoms, an aryl group having 6 to 15 carbon atoms, a halogen atom, a nitro group, an amide group, a hydroxyl group, an ester group, an ether group, an aldehyde group, and the like.

Among these, in terms of adhesiveness to an adjacent material such as the polymer base material and durability in a hot and humid enviromnent, each of R¹ and R² is preferably, independently, a hydrogen atom, a chlorine atom, a bromine atom, an unsubstituted or substituted alkyl group having 1 to 4 carbon atoms (particularly, a methyl group or an ethyl group), an unsubstituted or substituted phenyl group, an unsubstituted or substituted alkoxy group, a mercapto group, an unsubstituted amino group, or an amide group. In terms of durability in a hot and humid environment, each of R¹ and R² is more preferably an unsubstituted or substituted alkoxy group (preferably an alkoxy group having 1 to 4 carbon atoms).

n is preferably in a range of 1 to 5000 and more preferably in a range of 1 to 1000.

The proportion of the “—(Si(R′)(R²)—O)ₙ—” portion (the (poly)siloxane structural unit represented by General Formula (1)) in the polymer is preferably in a range of 15% by mass to 85% by mass of the total mass of the polymer and, particularly, more preferably in a range of 20% by mass to 80% by mass from the viewpoint of improving the strength of the surface of the polymer layer, preventing damage from being generated due to scratching, abrasion, or the like, and making adhesiveness to an adjacent material such as the polymer base material and durability in a hot and humid environment superior. When the proportion of the (poly)siloxane structural unit is 15% by mass or higher, the strength of the surface of the polymer layer is improved, the generation of damage generated by scratching, abrasion, or a small stone flying toward and striking the surface of the polymer layer is prevented, and adhesiveness to an adjacent material such as the polymer base material forming the supporter is excellent. The prevention of the generation of damage improves weather resistance, and peeling resistance and shape stability, which are easily deteriorated due to heat or moisture, and adhesion durability exhibited when the back sheet is exposed to a hot and humid environment are effectively enhanced. In addition, when the proportion of the (poly)siloxane structural unit is 85% by mass or lower, it is possible to stably hold a liquid.

In a case in which the polymer in the present invention is a copolymerized polymer having the (poly)siloxane structural unit and another structural unit, the polymer preferably includes 15% by mass to 85% by mass of the (poly)siloxane structural unit represented by General Formula (1) and 85% by mass to 15% by mass of a non-siloxane-based structural unit in the molecular chain in terms of percentage by mass. When the above-described copolymerized polymer is included, the film strength of the polymer layer is improved, the generation of damage due to scratching, abrasion, or the like is prevented, adhesiveness to the polymer base material forming the supporter, that is, peeling resistance and shape stability, which are easily deteriorated due to heat or moisture, and durability in a hot and humid environment can be significantly improved compared with in the related art.

The copolymerized polymer is preferably a block copolymer in which a siloxane compound (including polysiloxane) and a non-siloxane-based monomer or a compound selected from non-siloxane-based polymers are copolymerized together and which has the (poly)siloxane structural unit represented by General Formula (1) and a non-siloxane-based structural unit. In this case, the number of kinds of the siloxane compound and the non-siloxane-based monomer or the non-siloxane-based polymer to be copolymerized may be one or more.

The non-siloxane-based structural unit copolymerizing with the (poly)siloxane structural unit (derived from a non-siloxane-based monomer or a non-siloxane-based polymer) is not particularly limited except for the fact that the non-siloxane-based structural unit needs to not have a siloxane structure and may be any polymer segment derived from an arbitrary polymer. Examples of a polymer which is a precursor of the polymer segment (precursor polymer) include a variety of polymers such as a vinyl-based polymer, a polyester-based polymer, and a polyurethane-based polymer.

Among these, a vinyl-based polymer and a polyurethane-based polymer are preferred, and a vinyl-based polymer is particularly preferred since the preparation of these polymers is easy and the hydrolytic resistance is excellent.

Typical examples of the vinyl-based polymer include a variety of polymers such as an acrylic polymer, a vinyl carboxylate ester-based polymer, an aromatic vinyl-based polymer, and a fluoroolefin-based polymer. Among these, from the viewpoint of the degree of freedom of design, an acrylic polymer is particularly preferred.

Meanwhile, a polymer constituting the non-siloxane-based structural unit may be one or two or more in combination.

In addition, the precursor polymer capable of forming the non-siloxane-based structural unit preferably includes at least one of acid groups and neutralized acid groups and/or a hydrolyzable silyl group. Among these precursor polymers, the vinyl-based polymer can be prepared using a variety of methods such as (1) a method in which a vinyl-based monomer having an acid group and a vinyl-based monomer having a hydrolysable silyl group and/or a silanol group are copolymerized with a monomer capable of copolymerizing with the above-described monomers, (2) a method in which polycarboxylic anhydride is reacted with a vinyl-based polymer having a previously-prepared hydroxyl group and a hydrolyzable silyl group and/or a silanol group, and (3) a method in which a compound having active hydrogen (water, an alcohol, an amine, or the like) is reacted with a vinyl-based polymer having a previously-prepared acid anhydride group and a hydrolyzable silyl group and/or a silanol group.

The precursor polymer can be manufactured using, for example, the method described in Paragraphs “0021” to “0078” of JP2009-52011A or procured.

In the polymer layer in the present invention, as the binder, the polymer may be used singly or jointly used with another polymer. In a case in which the polymer is jointly used with another polymer, the percentage content of the polymer having the (poly)siloxane structure in the present invention is preferably 30% by mass or higher and more preferably 60% by mass or higher of the total amount of the binder. When the percentage content of the polymer having the (poly)siloxane structure is 30% by mass or higher, the strength of the layer surface is improved, the generation of damage due to scratching, abrasion, or the like is prevented, and adhesiveness to the polymer base material and durability in a hot and humid environment are superior.

The molecular weight of the polymer is preferably in a range of 5,000 to 100,000 and more preferably in a range of 10,000 to 50,000.

For the preparation of the polymer, it is possible to use a method such as (i) a method in which the precursor polymer and polysiloxane having the structural unit represented by General Formula (1) are reacted with each other or (ii) a method in which a silane compound having the structural unit represented by General Formula (1) in which R¹ and/or R² are hydrolysable groups is hydrolytically condensed in the presence of the precursor polymer.

A variety of silane compounds can be used as the silane compound used in the (ii) method, and an alkoxysilane compound is particularly preferred.

In a case in which the polymer is prepared using the (i) method, the polymer can be prepared by, for example, adding water and a catalyst as necessary to a mixture of the precursor polymer and polysiloxane and reacting the mixture at a temperature in a range of approximately 20° C. to 150° C. for approximately 30 minutes to 30 hours (preferably at 50° C. to 130° C. for 1 hour to 20 hours). As the catalyst, it is possible to add a variety of silanol condensation catalysts such as an acidic compound, a basic compound, and a metal-containing compound.

In addition, in a case in which the polymer is prepared using the (ii) method, the polymer can be prepared by, for example, adding water and a silanol condensation catalyst to a mixture of the precursor polymer and an alkoxysilane compound and performing hydrolytic condensation at a temperature in a range of approximately 20° C. to 150° C. for approximately 30 minutes to 30 hours (preferably at 50° C. to 130° C. for 1 hour to 20 hours).

In addition, as the polymer having the (poly)siloxane structure, a commercially available product on the market may be used, and, for example, CERANATE series manufactured by DIC Corporation (for example, CERANATE WSA1070, CERANATE WSA1060, and the like), H7600 series manufactured by Asahi Kasei Chemicals Corporation (H7650, H7630, H7620, and the like), and an inorganic acryl complex emulsion manufactured by JSR Corporation can be used.

The amount of the polymer having the (poly)siloxane structure applied to the (D) layer is preferably in a range of higher than 0.2 g/m² to 15 g/m². When the amount of the polymer applied in the above-described range, the generation of damage generated due to an external force is suppressed, and the (D) layer is sufficiently cured.

Even in the above-described range, from the viewpoint of the surface strength of the (D) layer, the amount of the polymer applied is preferably in a range of 0.5 g/m² to 10.0 g/m², and more preferably in a range of 1.0 g/m² to 5.0 g/m².

Among the above-described commercially available polymers, the (D) layer in the present invention is preferably configured using CERANATE series manufactured by DIC Corporation or an inorganic acryl complex emulsion manufactured by JSR Corporation as the polymer.

—Fluorine-Based Polymer—

The (D) layer may be configured using a fluorine-based polymer (fluorine-containing polymer) as a main binder. The main binder refers to a binder having the largest content in the layer.

The fluorine-based polymer that can be used here is not particularly limited as long as the polymer has a repeating unit represented by —(CFX¹—CX²X³)—(here, each of X¹, X², and X³ independently represents a hydrogen atom, a fluorine atom, a chlorine atom, or a fluoroalkyl group having 1 to 3 carbon atoms).

Specific examples of the polymer include polytetrafluoroethylene (hereinafter, in some cases, referred to as PTFE), polyvinyl fluoride (hereinafter, in some cases, referred to as PVF), polyvinylidene fluoride (hereinafter, in some cases, referred to as PVDF), polychlorotrifluoroethylene (hereinafter, in some cases, referred to as PCTFE), polytetrafluoropropylene (hereinafter, in some cases, referred to as HFP), and the like.

The fluorine-based polymer may be a homopolymer obtained by polymerizing identical monomers or a copolymer obtained by copolymerizing two or more monomers. Examples thereof include a copolymer obtained by copolymerizing tetrafluoroethylene and tetrafluoropropylene (abbreviated as P(TFE/HFP)), a copolymer obtained by copolymerizing tetrafluoroethylene and vinylidene fluoride (abbreviated as P(TFE/VDF)), and the like.

Furthermore, the polymer used in the (D) layer including the fluorine-based polymer may be a polymer obtained by copolymerizing a fluorine-based structural unit represented by —(CFX¹—CX²X³)—and another structural unit. Examples thereof include a copolymer of tetrafluoroethylene and ethylene (hereinafter, abbreviated as P(TFE/E)), a copolymer of tetrafluoroethylene and propylene (abbreviated as P(TFE/P)), a copolymer of tetrafluoroethylene and vinyl ether (abbreviated as P(TFE/VE)), a copolymer of tetrafluoroethylene and perfluorovinyl ether (abbreviated as P(TFE/FVE)), a copolymer of chlorotrifluoroethylene and vinyl ether (abbreviated as P(CTFE/VE)), a copolymer of chlorotrifluoroethylene and perfluorovinyl ether (abbreviated as P(CTFE/FVE)), and the like.

The fluorine-based polymer may be used in a state of being dissolved in an organic solvent or after the polymer fine particles are dispersed in water. The latter way is preferred in consideration of small environmental load. A water dispersion of the fluorine-based polymer is described in, for example, JP2003-231722A, JP2002-20409A, JP1997-194538A (JP-H09-194538A), and the like, and the polymers described therein can be applied to the present invention.

As the binder for the (D) layer including the fluorine-based polymer, the above-described fluorine-based polymer may be used singly, or two or more fluorine-based polymers may be jointly used. In addition, a resin other than the fluorine-based polymer such as an acrylic resin, a polyester resin, a polyurethane resin, a polyolefin resin, or a silicone resin may be jointly used in a range of no larger than 50% by mass of the entire binder. However, when the content of the resin other than the fluorine-based polymer exceeds 50% by mass, there are cases in which the intended effect of improving weather resistance cannot be obtained.

In a case in which the (D) layer is provided, the thickness of the layer is preferably in a range of 0.8 μm to 12 μm. When the thickness thereof is in the above-described range, an effect of improving durability and weather resistance is sufficiently obtained, the deterioration of the surface state is suppressed, and the adhering force to an adjacent layer becomes sufficient. The film thickness is more preferably in a range of approximately 1.0 μm to 10 μm.

—Colorant—

The colorant that can be used in the (D) layer is not particularly limited, and a well-known dye or a well-known pigment can be used. In the present specification, scattering particles are not considered as the colorant. In the present invention, the colorant is preferably a black colorant, a green-based colorant, a blue-based colorant, or a red-based colorant.

A coloring pigment used for the (D) layer is not particularly limited except for the fact that the coloring pigment preferably includes at least one substance selected from carbon black, titanium black, a black complex metallic oxide, a cyanine-based color, and a quinacridone-based color and may be selected depending on required optical density.

Here, the black complex metallic oxide is preferably a complex metallic oxide containing at least one element of iron, manganese, cobalt, chromium, copper, and nickel, more preferably a complex metallic oxide containing two or more elements of cobalt, chromium, iron, manganese, copper, and nickel, and more particularly preferably at least one pigment selected from pigments having color indexes of PBk26, PBk27, PBk28, and PBk34. Meanwhile, a pigment of PBk26 is a complex oxide of iron, manganese, and copper, a pigment of PBk27 is a complex oxide of iron, cobalt, and chromium, a pigment of PBk-28 is a complex oxide of copper, chromium, and manganese, and a pigment of PBk34 is a complex oxide of nickel and iron. Examples of the cyanine-based color and the quinacridone-based color include cyanine green, cyanine blue, quinacridone red, phthalocyanine blue, phthalocyanine green, and the like.

Among these, carbon black is preferably used as the colorant from the viewpoint of easily controlling the optical density such that the optical density is in the above-described preferred range or the viewpoint of controlling the optical density such that the optical density has a desired value with a small amount of the colorant.

The carbon black is preferably carbon black fine particles having a particle diameter in a range of 0.1 t to 0.8 μm. Furthermore, the carbon black fine particles are preferably used after being dispersed in water together with a dispersing agent. Meanwhile, as the carbon black, it is possible to use carbon black that can be commercially procured, and examples thereof include MF-5630 BLACK, manufactured by Dainichiseika Color & Chemicals Mfg. Co., Ltd. and the carbon black described in Paragraph “0035” of JP2009-132887A.

—Scattering Particles—

The scattering particles that can be included in the (D) layer are not particularly limited, and well-known scattering particles can be used. In the present specification, the scattering particles refer to particles that barely absorb light and do not include the colorant. In the present invention, a white pigment is preferably used as the scattering particles.

Examples of the white pigment that can be used as the scattering particles include inorganic pigments such as titanium dioxide, barium sulfate, silicon oxide, aluminum oxide, magnesium oxide, calcium carbonate, kaolin, talc, and colloidal silica, organic pigments such as hollow particles, and the like, and, among these, titanium dioxide is preferred.

As the crystalline form of titanium dioxide, there are a rutile system, an anatase form, and a brookite form, and titanium dioxide used in the present invention preferably has a rutile crystalline form. Titanium dioxide used in the present invention may be subjected to a surface treatment as necessary using aluminum oxide (Al₂O₃), silicon dioxide (SiO₂), an alkanolamine compound, a silicon compound, or the like.

Particularly, when titanium dioxide having a bulk specific gravity of 0.50 g/cm³ or higher is used, titanium oxide is densely packed, and the weather-resistant layer becomes robust. On the other hand, when titanium dioxide having a bulk specific gravity of higher than 0.85 g/cm³, the dispersibility of titanium dioxide deteriorates and thus the surface state of the coating layer becomes poor. When the bulk specific gravity is set in a range of 0.50 g/cm³ to 0.85 g/cm³ is used, titanium oxide is densely packed, and the coated film becomes robust, and thus adhesiveness can be maintained at a high level even when the mass proportion of titanium dioxide is set to be high. The bulk specific gravity of titanium dioxide used for the weather-resistant layer is particularly preferably in a range of 0.60 g/cm³ to 0.80 g/cm³.

The bulk specific gravity of the white pigment in the present specification is a value measured using the following method. (1) A pigment is caused to pass through a sieve with a mesh of 1.0 mm. (2) Approximately 100 g of the pigment is weighed (m) and is gently put into a 250 mL measuring cylinder. If necessary, the top surface of a pigment layer is carefully leveled without consolidating the pigment layer, and the volume (V) is measured. (3) The bulk specific gravity is obtained according to the following expression. Bulk specific gravity=m/V (unit: g/cm³)

When the (D) layer further includes a white pigment as the scattering particles in addition to the base polymer such as a silicone-based polymer or a fluorine-based polymer, it is possible to increase the reflectivity of the (D) layer and to decrease yellow discoloration in a long-term high-temperature and humidity test (2000 hours to 3000 hours at 85° C. and a relative humidity of 85%) and a UV irradiation test (according to the UV test of IEC61215, a total irradiation amount: 45 Kwh/m²). Furthermore, the addition of the white pigment such as the scattering particles to the (D) layer further improves adhesiveness to an adjacent layer.

In a case in which the scattering particles are used in the (D) layer, the amount of the scattering particles applied to the (D) layer is preferably in a range of 1.0 g/m² to 15 g/m² per layer. When the content of the scattering particles, preferably the white pigment, is 1.0 g/m² or higher, it is possible to effectively impart reflectivity and UV resistance (light resistance). In addition, when the amount of the white pigment applied to the weather-resistant layer is 15 g/m² or lower, the surface state of the colored layer is easily maintained to be favorable, and the film strength is superior. Particularly, the amount of the scattering particles applied to the (D) layer is more preferably in a range of 2.5 g/m² to 10 g/m², and particularly preferably in a range of 4.5 g/m² to 8.5 g/m².

Regarding the average particle diameter of the white pigment as the scattering particles, the volume-average particle diameter is preferably in a range of 0.03 μm to 0.8 μm and more preferably in a range of approximately 0.15 μm to 0.5 μm. When the average particle diameter is within the above-described range, the light reflection efficiency is high. The average particle diameter is a value measured using a laser diffraction particle size distribution analyzer LA950 [manufactured by Horiba, Ltd.].

In the (D) layer, the content of the binder component (including the silicone-based polymer) is preferably in a range of 15 parts by mass to 200 parts by mass and more preferably in a range of 17 parts by mass to 100 parts by mass with respect to 100 parts by mass of the white pigment which is the scattering particles. When the content of the binder is 15 parts by mass or higher, the strength of the colored layer is sufficiently obtained, and, when the content of the binder is 200 parts by mass or lower, reflectivity or designability can be favorably maintained.

—Other Components—

In a case in which a polymer sheet of the present invention includes the (D) layer including the binder such as a silicone-based polymer, the colorant, and the scattering particles, the polymer sheet may further include, as necessary, other components such as a variety of additives, for example, a crosslinking agent, a surfactant, and a filler.

Among these, it is preferable to add a crosslinking agent to the binder (binding resin) so as to form a crosslinking structure derived from the crosslinking agent in the (D) layer from the viewpoint of further improving the strength and durability of the (D) layer.

Examples of the crosslinking agent that can be included in the (D) layer include an epoxy-based crosslinking agent, an isocyanate-based crosslinking agent, a melamine-based crosslinking agent, a carbodiimide-based crosslinking agent, and an oxazoline-based crosslinking agent. Among these, the crosslinking agent is preferably at least one crosslinking agent selected from a carbodiimide-based crosslinking agent, an oxazoline-based crosslinking agent, and an isocyanate-based crosslinking agent.

As the crosslinking agent, the crosslinking agent previously described in the section of the (B) layer can be also similarly applied to the (D) layer, and preferred examples thereof are also identical.

In a case in which the crosslinking agent is used in the (D) layer, the amount of the crosslinking agent added is preferably in a range of 0.5 parts by mass to 30 parts by mass and more preferably in a range of 3 parts by mass to 15 parts by mass with respect to 100 parts by mass of the binder included in the (D) layer. When the amount of the crosslinking agent added is 0.5 parts by mass or higher, a sufficient crosslinking effect can be obtained while maintaining the strength and adhesiveness of the weather-resistant layer; when the amount of the crosslinking agent added is 30 parts by mass or lower, the pot life of a coating fluid is maintained for long period of time; when the amount of the crosslinking agent added is lower than 15 parts by mass, the coating surface state can be improved.

Examples of the surfactant that can be used in the (D) layer include a well-known anionic surfactant and a well-known nonionic surfactant. In a case in which the surfactant is added to the (D) layer, the amount of the surfactant applied is preferably in a range of 0.1 mg/m² to 10 mg/m² and more preferably in a range of 0.5 mg/m² to 3 mg/m². When the amount of the surfactant applied is 0.1 mg/m² or higher, the generation of cissing is suppressed, and thus a favorable layer can be formed, and, when the amount of the surfactant applied is 10 mg/m² or lower, it is possible to favorably adhere the (D) layer to a polymer supporter or the like.

A filler may be added to the (D) layer. As the filler, it is possible to use a well-known filler such as colloidal silica.

The (D) layer can be formed by applying and drying a coating fluid including the binder and the like on the rear surface-side surface of the supporter.

In the polymer sheet of the present invention, the (D) layer is preferably a coating layer formed by applying the composition for forming the (D) layer including either or both the fluorine-based polymer and the silicone-based polymer.

In a method for manufacturing the polymer sheet of the present invention, it is preferable to prepare an aqueous dispersion liquid in which the silicone-based or fluorine-based resin or other components that are jointly used with the resin as desired are included and dispersed and apply this aqueous dispersion liquid as a water-based coating fluid onto a desired polymer supporter.

A coating method or a solvent for the coating fluid are not particularly limited. As the coating method, for example, gravure coating or bar coating can be used. The solvent used for the coating fluid may be water or an organic solvent such as toluene or methyl ethyl ketone.

From the viewpoint of environmental load, a water-based coating fluid for which water is used as a coating solvent is preferably prepared.

Only one coating solvent may be used, or a mixture of two or more coating solvents may be used. A method in which a water-based coating fluid in which the binder is dispersed in water is formed and applied is preferred. In this case, the proportion of water in the solvent is preferably 60% by mass or higher and more preferably 80% by mass or higher.

After the coating, a drying step for drying a coated film under desired conditions may be provided. The drying temperature during drying may be appropriately selected depending on the composition or applied amount of the coating fluid and the like. In addition, in a case in which the polymer supporter is a biaxial stretched film, it is possible to apply a coating fluid for forming the weather-resistant layer to the biaxial stretched polymer supporter and then dry a coated film or to apply a coating fluid to a monoaxial stretched polymer supporter, dry a coated film, and then stretch the film in a direction different from the first stretching direction.

Furthermore, it is also possible to apply a coating fluid to the polymer supporter that has yet to be stretched, dry a coated film, and then stretch the film in two directions.

—Thickness—

The thickness of the coating layer (D) [the (D) layer] is, generally, preferably in a range of 0.3 μm to 22 μm, more preferably in a range of 0.5 μm to 15 μm, still more preferably in a range of 0.8 μm to 12 μm, particularly preferably in a range of 1.0 μm to 8 μm, and most preferably in a range of 2 μm to 6 μm. When the thickness thereof is within the above-described range, when the polymer sheet is exposed to a hot and humid environment, moisture is not allowed to easily intrude into the interior of the (D) layer from the surface, additionally, moisture is not allowed to easily reach the interface between the (D) layer and the supporter, and thus the deterioration of adhesiveness is significantly suppressed, the film strength of the (D) layer is also maintained to be favorable, and the weather-resistant layer does not easily break when the polymer sheet is exposed to a hot and humid environment and thus the maintenance of adhesiveness is further improved.

[Weather-Resistant Layer Including Fluorine-Based Polymer: Coating Layer (E)]

The polymer sheet of the present invention may further include a coating layer (E) including a fluorine-based polymer (hereinafter, appropriately referred to as (E) layer) on the surface of the (D) layer including the silicone-based or fluorine-based binder resin, the colorant, and the scattering particles.

In a case in which the polymer sheet of the present invention includes the (E) layer including a fluorine-based polymer, the (E) layer is preferably provided directly on the surface of the (D) layer that is arbitrarily provided on the supporter. The (E) layer is preferably located as the outermost layer of the polymer sheet of the present invention.

The coating layer (E) including a fluorine-based polymer is configured using a fluorine-based polymer (fluorine-containing polymer) as a main binder. The main binder refers to a binder having the largest content in the (E) layer.

Hereinafter, the (E) layer and the fluorine-based polymer included therein will be specifically described.

—Fluorine-Based Polymer—

The fluorine-based polymer used for the weather-resistant layer including the fluorine-based polymer is not particularly limited as long as the polymer has a repeating unit represented by —(CFX¹—CX²X³)— (here, each of X¹, X², and X³ independently represents a hydrogen atom, a fluorine atom, a chlorine atom, or a fluoroalkyl group having 1 to 3 carbon atoms).

Examples of the fluorine-based polymer used for the (E) layer include the same polymers as the fluorine-based polymer used for the coating layer (D), and specific examples and preferred examples thereof are also identical.

When forming the coating layer (E), the fluorine-based polymer may be used in a state of being dissolved in an organic solvent or after the fluorine-based polymer particles are dispersed in an appropriate dispersion medium such as water. A polymer particle dispersion for which water or a water-based solvent is used as a dispersion medium is preferably used from the viewpoint of small environmental load. Water dispersions of the fluorine-based polymer are described in, for example, JP2003-231722A, JP2002-20409A, JP1997-194538A (JP-H09-194538A), and the like, and these may be used for the formation of the coating layer (E).

For the coating layer (E), the fluorine-based polymer may be used singly or two or more fluorine-based polymers may be jointly used. In addition, a resin other than the fluorine-based polymer such as an acrylic resin, a polyester resin, a polyurethane resin, a polyolefin resin, or a silicone resin may be jointly used in a range of no larger than 50% by mass of the entire binder. However, when the content of the fluorine-based polymer exceeds 50% by mass, in a case in which the resin is used for the back sheet, the weather resistance-improving effect is more favorably developed.

—Lubricant—

The coating layer (E) preferably includes at least one lubricant.

When the coating layer includes a lubricant, the degradation of sliding properties, which is easily caused in a case in which a fluorine-containing polymer is used, (that is, an increase in the coefficient of dynamic friction) is suppressed, and thus susceptibleness to damage caused by an external force such as scratching, abrasion, or a small stone striking the surface of the layer is significantly alleviated. In addition, it is possible to improve the cissing of a coating fluid on the surface, which is easily caused in a case in which the fluorine-based polymer is used, and it is possible to form a weather-resistant layer including the fluorine-based polymer with a favorable surface state.

The content of the lubricant in the coating layer (E) is in a range of 0.2 mg/m² to 200 mg/m². When the amount of the lubricant applied is lower than 0.2 mg/m², the amount of the lubricant is too small, and the effect of reducing the coefficient of dynamic friction, which is generated by the inclusion of the lubricant, is weak. In addition, when the amount of the lubricant applied exceeds 200 mg/m², and thus the amount of the lubricant is too large, when a polymer layer is formed through coating, it is likely that coating unevenness or aggregates may be generated and cissing-induced failure may be caused.

Even in the above-described range, from the viewpoint of the effect of reducing the coefficient of dynamic friction and coating suitability, the amount of the lubricant applied is preferably in a range of 1.0 mg/m² to 1150 mg/m² and more preferably in a range of 5.0 mg/m² to 100 mg/m².

Examples of the lubricant include a synthetic wax-based compound, a natural wax-based compound, a surfactant-based compound, an inorganic compound, an organic compound, and the like. Among these, in terms of the surface strength of the polymer layer, a compound selected from a synthetic wax-based compound, a natural wax-based compound, and a surfactant-based compound is preferred.

Examples of the synthetic wax-based compound include an olefin-based wax such as a polyethylene wax or a polypropylene wax, an ester, an amide, a bisamide, a ketone, a metallic salt of stearic acid, oleic acid, erucic acid, lauric acid, behenic acid, palmitic acid, adipic acid, or the like, derivatives thereof, a synthetic hydrocarbon wax such as a Fischer Tropsch wax, a hydrogenated wax such as phosphoric acid ester, cured castor oil, or a cured castor oil derivative, and the like.

Examples of the natural wax-based compound include a plant-based wax such as a carnauba wax, a candelilla wax, or a Japan wax, a petroleum-based wax such as a paraffin wax or a microcrystalline wax, a mineral-based wax such as a montan wax, an animal-based wax such as a beeswax or lanolin.

Examples of the surfactant-based compound include a cationic surfactant such as an alkyl amine salt, an anionic surfactant such as an alkylsulfuric acid ester salt, a nonionic surfactant such as polyoxyethylene alkyl ether, an amphoteric surfactant such as an alkylbetaine, a fluorine-based surfactant, and the like.

As the lubricant, a commercially available lubricant on the market may be used, and specific examples of a synthetic wax-based lubricant include CHEMIPAL series manufactured by Mitsui Chemicals, Inc. (for example, CHEMIPAL W700, CHEMIPAL W900, CHEMIPAL W950, and the like), POLYRON P-502, HYMICRON L-271, HIDORIN L-536 manufactured by Chukyo Yushi Co., Ltd., and the like;

specific examples of a natural wax-based lubricant include HIDORIN L-703-35, SELOSOL 524, SELOSOL R-586 manufactured by Chukyo Yushi Co., Ltd., and the like;

specific examples of a surfactant-based lubricant include NIKKOL series manufactured by Nikko Chemicals Co., Ltd. (for example, NIKKOL SCS and the like), EMAL series manufactured by Kao Corporation (for example, EMAL 40 and the like).

Among these, the coating layer (E) in the present invention is preferably configured using CERANATE series manufactured by DIC Corporation or an inorganic acryl complex emulsion manufactured by JSR Corporation as the polymer and CHEMIPAL series manufactured by Mitsui Chemicals, Inc. as the lubricant.

—Other Additives—

To the (E) layer, colloidal silica, a silane coupling agent, a crosslinking agent, a surfactant, and the like may be added as necessary.

As the colloidal silica, the same colloidal silica as described in the section of the coating layer (B) can be used in the same manner.

In a case in which the (E) layer includes colloidal silica in order to improve the surface state, the content thereof is preferably in a range of 0.3% by mass to 1.0% by mass and more preferably in a range of 0.5% by mass to 0.8% by mass of the total solid contents in the (E) layer. When the amount of the colloidal silica added is set to 0.3% by mass or higher, a surface state-improving effect can be obtained, and, when the amount thereof is set to 1.0% by mass or lower, the aggregation of a coating fluid is more effectively prevented.

In a case in which the (E) layer includes colloidal silica, a silane coupling agent is preferably added to the (E) layer from the viewpoint of improving the surface state.

The silane coupling agent is preferably an alkoxysilane compound, and examples thereof include tetraalkoxysilanes and trialkoxysilanes. Among these, a trialkoxysilane is preferred, and an alkoxysilane compound having an amino group is particularly preferred.

In a case in which a silane coupling agent is added to the (E) layer, the amount of the silane coupling agent added is preferably in a range of 0.3% by mass to 1.0% by mass and particularly preferably in a range of 0.5% by mass to 0.8% by mass of the (E) layer. When the amount of the silane coupling agent added is set to 0.3% by mass or higher, a surface state-improving effect can be obtained, and, when the amount thereof is set to 1.0% by mass or lower, the aggregation of a coating fluid is more effectively prevented.

From the viewpoint of improving weather resistance, it is preferable to add a crosslinking agent to the (E) layer so as to form a crosslinking structure. Examples of the crosslinking agent that can be used for the (E) layer include the same crosslinking agent as used for the (D) layer.

As the surfactant used for the (E) layer, a well-known surfactant such as an anionic or nonionic surfactant can be used. In a case in which the surfactant is added to the (E) layer, the amount of the surfactant applied is preferably in a range of 0 mg/m² to 15 mg/m² and more preferably in a range of 0.5 mg/m² to 5 mg/m². When the amount of the surfactant applied is 0.1 mg/m² or higher, the generation of cissing is suppressed, and thus a favorable layer can be formed, and, when the amount thereof is 15 mg/m² or lower, adhesion can be favorably carried out.

—Thickness—

The thickness of the (E) layer is, generally, preferably in a range of 0.8 μm to 12 μm, more preferably in a range of 0.5 μm to 15 μm, and still more preferably in a range of 1.0 μm to 10 μm.

When the thickness thereof is within the above-described range, weather resistance and durability are further improved, and the deterioration of the coated surface state is suppressed.

The polymer sheet of the present invention may have another layer laminated on (the outer layer on) the (E) layer; however, from the viewpoint of improving durability of the polymer sheet for a back sheet, reducing the weight, reducing the thickness, and reducing the cost, the (E) layer is preferably an outermost layer of the solar cell back sheet.

—Other Layers—

(Gas-Barrier Layer)

A gas-barrier layer may be provided on a surface opposite to the (B) layer in the supporter. The gas-barrier layer is a layer for imparting a moisture-proof function with which the intrusion of water or gas past the polyester is prevented.

The amount of water vapor penetrating through the gas-barrier layer (moisture permeability) is preferably in a range of 10² g/m²·d to 10⁻⁶ g/m²·d, more preferably in a range of 10¹ g/m²·d to 10⁻⁵ g/m²·d, and still more preferably in a range of 10⁰ g/m²·d to 10⁻⁴ g/m²·d.

Furthermore, the moisture permeability can be measured on the basis of JIS Z0208 or the like.

In order to form the gas-barrier layer having the above-described moisture permeability, a dry method is preferred. Examples of a method for forming the gas-barrier layer that blocks gas using the dry method include a vacuum vapor deposition method such as resistance heating vapor deposition, electron beam vapor deposition, induced heating vapor deposition, or an assist method in which plasma or ion beams are used for the above-described methods, a sputtering method such as a reactive sputtering method, an ion beam sputtering method, or an electron cyclotron resonance (ECR) sputtering method, a physical vapor deposition method (PVD method) such as an ion plating method, and a chemical vapor deposition method (CVD method) in which heat, light, plasma, or the like is used. Among these, a vacuum vapor deposition method in which a film is formed using a vapor deposition method in a vacuum is preferred.

Examples of a material for forming the gas-barrier layer include an inorganic oxide, an inorganic nitride, an inorganic oxynitride, an inorganic halide, an inorganic sulfide, and the like.

Meanwhile, an aluminum foil may be attached to the supporter and be used as the gas-barrier layer.

The thickness of the gas-barrier layer is preferably in a range of 1 μm to 30 μm.

When the thickness thereof is 1 μm or larger, the gas-barrier layer does not easily allow water to intrude past the supporter over time (thermo) and the hydrolysis resistance is excellent, and when the thickness thereof is 30 μm or smaller, an inorganic layer does not become excessively thick, and there is no case in which accretion is generated in the supporter due to stresses in the inorganic layer.

[Solar Cell Module]

In the solar cell module of the present invention, a solar cell element for converting the optical energy of sunlight to electrical energy is disposed between a transparent substrate on which sunlight is incident and a solar cell back sheet, and a space between the substrate and the back sheet is sealed with a sealing material such as an ethylene-vinyl acetate copolymer or the like.

Specifically, the solar cell protective sheet of the present invention includes a transparent base material on which sunlight is incident, an element structure portion which is provided on the base material and has a solar cell element and a sealing material that seals the solar cell element, and a solar cell back sheet disposed on a side opposite to a side on which the base material of the element structure portion is located. In addition, as the solar cell back sheet, the solar cell back sheet of the present invention is applied.

Regarding members other than the solar cell module, the solar cell, and the back sheet, for example, “The Constituent Materials of Photovoltaic Power Generation Systems” (edited by Eiichi Sugimoto and published by Kogyo Chosakai Publishing Co., Ltd. in 2008) describes them in detail.

The transparent front substrate needs to have a light-transmitting property so as to be capable of transmitting sunlight and can be appropriately selected from base materials transmitting light. From the viewpoint of power generation efficiency, the light transmittance is preferably higher, and, as the above-described substrate, for example, a glass substrate, a transparent resin such as an acrylic resin, or the like can be preferably used.

As the solar cell element, it is possible to apply a variety of well-known solar cell elements such as a solar cell element based on silicon such as monocrystalline silicon, polycrystalline silicon, or amorphous silicon or a solar cell element based on a III-V group or II-VI group compound semiconductor such as copper-indium-gallium-selenium, copper-indium-selenium, cadmium-tellurium, or gallium-arsenic.

### EXAMPLES

Hereinafter, the present invention will be more specifically described using examples, but the present invention is not limited to the following examples within the scope of the gist of the present invention. Meanwhile, unless particularly otherwise described, “parts” is on the basis of mass.

(Production of Transparent PET Supporter)

—Synthesis of Polyester—

High-purity terephthalic acid (100 kg, manufactured by Mitsui Chemicals, Inc.) and a slurry of ethylene glycol (45 kg, manufactured by Nippon Shokubai Co., Ltd.) were sequentially supplied over four hours to an esterification reaction vessel in which bis(hydroxyethyl)terephthalate (approximately 123 kg) had been previously placed and the temperature and the pressure were respectively maintained at 250° C. and 1.2×10⁵ Pa. After the completion of the supply, an esterification reaction was further caused for one hour, and then, the obtained esterification reaction product (123 kg) was moved to a condensation polymerization reaction vessel.

Subsequently, 0.3% by mass of ethylene glycol in relation to the obtained polymer was added to the condensation polymerization reaction vessel to which the esterification reaction product had been moved. After five minutes of stirring, cobalt acetate and an ethylene glycol solution of manganese acetate were added thereto so that the contents thereof respectively reached 30 ppm and 15 ppm of the obtained polymer. Furthermore, after five minutes of stirring, a 2% by mass ethylene glycol solution of a titanium alkoxide compound was added thereto so that the content thereof reached 5 ppm of the obtained polymer. After five minutes, a 10% by mass ethylene glycol solution of triethyl phosphonoacetate was added thereto so that the content thereof reached 5 ppm of the obtained polymer. After that, while stirring a lower polymer at 30 rpm, the reaction system was gradually heated from 250° C. to 285° C., and the pressure was lowered to 40 Pa. The time periods necessary to reach the final temperature and the final pressure were both set to 60 minutes. When a predetermined stirring torque was reached, the reaction system was purged with nitrogen, the pressure was returned to normal pressure, and the condensation polymerization reaction was stopped. In addition, the reaction product was ejected into cold water in a strand shape and was, immediately, cut into polymer pellets (with a diameter of approximately 3 mm and a length of approximately 7 mm).

Meanwhile, it took three hours from the initiation of depressurization to reach the predetermined stirring torque.

Meanwhile, as the titanium alkoxide compound, the titanium alkoxide compound (with a content of Ti of 4.44% by mass) synthesized in Example 1 of Paragraph “0083” of JP2005-340616A was used.

—Solid-Phase Polymerization—

The pellets obtained above were held at a temperature of 220° C. for 30 hours in a vacuum container held at 40 Pa, thereby causing solid-phase polymerization.

—Formation of Base—

The pellets which had been subjected to solid-phase polymerization as described above were melted at 280° C. and were cast on a metallic drum, thereby producing an un-stretched base having a thickness of approximately 3 mm. After that, the base was stretched 3.4 times in the machine direction at 90° C., a corona discharge treatment was carried out under the following conditions, and then a composition for forming an inline coating layer having the following formulation was applied using an inline coating method onto the corona-treated surface of a polyethylene terephthalate supporter after stretching in the MD but before stretching in the TD so that the amount of the coating fluid applied reached 5.1 ml/m², thereby forming a 0.1 μm-thick inline coating layer. Meanwhile, the pellets were stretched 4.5 times in the TD direction at a TD stretching temperature of 105° C., a thermal treatment was carried out on a film surface at 200° C. for 15 seconds, and thermal relaxation was carried out at 190° C. in the MD and TD directions at an MD relaxation ratio of 5% and a TD relaxation ratio of 11%, thereby obtaining a 250 μm-thick biaxial stretched polyethylene terephthalate supporter on which the inline coating layer was formed (hereinafter, referred to as “inline coating layer-attached transparent PET supporter”).

(Corona Discharge Treatment)

The conditions for the corona discharge treatment carried out on one surface of the PET supporter are as described below.
Gap clearance between an electrode and a dielectric roll: 1.6 mm
Treatment frequency: 9.6 kHz
Treatment rate: 20 m/minute
Treatment intensity: 0.375 kV·A·minute/m²

(Formulation of Coating Fluid for Forming Inline Coating Layer)

| | | |
|---|---|---|
| Water dispersion liquid of polyolefin resin | 3.74 | parts by mass |
| [ARROW-BASE SE-1013N, manufactured by | | |
| Unitika Limited, solid content: 20.2% by mass] | | |
| Water dispersion liquid of acrylic resin | 0.3 | parts by mass |
| [AS-563A, manufactured by Daicel FineChem Ltd., | | |
| solid content: 28% by mass of latex] | | |
| Water-soluble oxazoline-based crosslinking agent | 0.85 | parts by mass |
| [EPOCROS WS-700, manufactured by Nippon | | |
| Shokubai Co., Ltd., solid content: 25% by mass] | | |
| Distilled water | 100 | parts by mass |

Coating layers (B) to (E) were formed in the following manner using the inline coating layer-attached transparent PET supporter obtained in the above-described manner and were used as solar cell back sheets.

### Examples 1 to 91 and Comparative Examples 1 to 8

A composition for forming a (B) layer was prepared using raw materials shown in Table 1 so as to obtain the percentage content of solid contents described below. There are other cases in which inorganic particles are added to the above-described formulation according to the kind and the amount (% by capacity in a dried-film state) as shown in Tables 7 to 11, thereby producing a composition for forming a (B) layer.

Meanwhile, sodium-1,2-{bis(3,3,4,4,5,5,6,6,6-nanofluorohexyl carbonyl)}ethanesulfonate in Table 1 was used after being diluted with a solvent mixture of water and ethanol (at a ratio of 2:1) so that the content thereof reached 2% by mass. Individual components shown in Table 1 were mixed together in a ratio of solid contents described below, and furthermore, distilled water was added thereto so as to make the concentration of solid contents reach 7.0% by mass, thereby preparing a composition for forming a (B) layer.

In addition, in Examples 88 to 91, the following inline coating layer-attached white PET supporter was used instead of the inline coating layer-attached transparent PET supporter used in Examples 1 to 87.

(Production of White PET Supporter)

—Production of Master Pellets—

Titanium oxide was added to the pellets which were produced in the “production of the transparent PET supporter” and was not subjected to solid-phase polymerization so that the percentage content thereof reached 50% by mass of all the pellets, and the components were kneaded together, thereby producing master pellets.

Here, as the titanium oxide, PF-739 (trade name; average primary particle diameter=0.25 jam, inorganic particles subjected to a polyol treatment after an alumina treatment as a surface treatment) manufactured by Ishihara Sangyo Kaisha, Ltd. was used.

—Formation of Base—

Pellets which had been subjected to solid-phase polymerization in the same manner as in the “production of the transparent PET supporter” and the master pellets were mixed together so that the amount of titanium oxide reached a concentration shown in Table 11 below, were melted at 280° C., and were cast on a metallic drum, thereby producing an un-stretched base having a thickness of approximately 3 mm. After that, the base was stretched (MD-stretched) 3.0 times in the machine direction (MD) at 90° C., and a corona discharge treatment was carried out under the same conditions as in the “production of the transparent PET supporter”. Next, the same composition for forming an inline coating layer as in the “production of the transparent PET supporter” was applied to this corona-treated surface using an inline coating method so that the amount of the composition applied reached 5.1 ml/m², thereby forming a 0.1 μm-thick inline coating layer. The application was carried out after the MD stretching and before the base was stretched in a transverse direction (TD) orthogonal to the MD (before TD stretching). In addition, after the formation of the inline coating layer, the base was TD-stretched 4.5 times at 105° C., and the surface of the inline coating layer was thermally treated at 200° C. for 15 seconds. After that, thermal relaxation was carried out at 190° C. in the MD and TD at an MD relaxation ratio of 5% and a TD relaxation ratio of 11%.

Therefore, a 250 μm-thick biaxial stretched polyethylene terephthalate supporter (inline coating layer-attached white PET) was obtained.

TABLE 1

| | Concentration | |
|---|---|---|
| | of raw | Concentration |
| | materials | used |
| Polymer having yield point or comparative | 45 | 45 |
| polymer (shown in Tables 6 to 10) | | |
| Crosslinking agent EPOCROS WS700 | 25 | 25 |
| (manufactured by Nippon Shokubai | | |
| Co., Ltd.) | | |
| Sodium-1,2-{bis(3,3,4,4,5,5,6,6,6- | 100 | 2 |
| nanofluorohexyl carbonyl)}ethanesulfonate | | |
| Inorganic particles | | |
| (shown in Tables 7 to 10) | | |

—Proportion of Solid Contents in Composition for Forming (B) Layer—

| | | |
|---|---|---|
| Polymer having a yield point | 90 | parts by mass |
| Crosslinking agent | 10 | parts by mass |
| Sodium-1,2-{bis(3,3,4,4,5,5,6,6,6- | 1 | part by mass |
| nanofluorohexyl carbonyl)}ethanesulfonate | | |

For reference, the formulation of the composition for forming a (B) layer used in Example 2 is specifically described. In Examples 4 to 87, inorganic particles were further added to this composition.

—Composition for Forming (B) Layer of Example 2—

TABLE 1

| | | |
|---|---|---|
| Water-soluble oxazoline-based crosslinking agent | 29.0 | parts by mass |
| [EPOCROS WS-700, manufactured by Nippon | | |
| Shokubai Co., Ltd., solid content: 25% by mass] | | |
| Polymer having a yield point [XPS002 | 144.7 | parts by mass |
| (concentration of solid contents: 45%)] | | |
| Sodium-1.2-{bis(3,3,4,4,5,5,6,6,6-nanofluorohexyl | 3.6 | parts by mass |
| carbonyl)}ethanesulfonate (2%) | | |
| Distilled water | 822.6 | parts by mass |

The obtained composition for forming a (B) layer was applied to the surface of the inline coating layer-attached transparent PET supporter on which the inline coating layer was formed so that the film thickness after drying reached 1.0 μm and was dried at 170° C. for two minutes, thereby forming a coating layer (B). The kinds and the added amounts of the inorganic particles in the coating layer (B) are as shown in Tables 7 to 10.

Polymers used for the formation of the (B) layer are shown in Table 2 below in detail. The yield points of the polymer films shown in Table 2 are the measurement results of the above-described method.

TABLE 2

| | Polymer for coating layer (B) | | | | |
|---|---|---|---|---|---|
| | | | Concentration | Yield point of polymer | |
| | | | used % | (at degree of elongation | Stress |
| | Type | Trade name | by mass | of up to 15%) | MPa |
| Present | Acrylic | BONRON XPS001 | 45 | Present | 14 |
| invention | | (Mitsui Chemicals, Inc.) | | | |
| product | | | | | |
| Present | Acrylic | BONRON XPS002 | 45 | Present | 11 |
| invention | | (Mitsui Chemicals, Inc.) | | | |
| product | | | | | |
| Present | Olefin- | HARDLEN NZ-1001 | 30 | Present | 13 |
| invention | based | (Toyobo Co., Ltd.) | | | |
| product | | | | | |
| Comparative | Acrylic | AS-563A | 28 | Absent | — |
| product | | (Daicel FineChem Ltd.) | | | |
| Comparative | Acrylic | JONCRYL PDX-7341 | 49 | Absent | — |
| product | | (BASF) | | | |
| Comparative | Olefin- | HITECH S3148 | 28 | Absent | — |
| product | based | (Toho Chemical Industry | | | |
| | | Co., Ltd.) | | | |
| Comparative | Olefin- | ARROW-BASE SE1013N | 20.2 | Absent | — |
| product | based | (Unitika Limited.) | | | |
| Comparative | Olefin- | ARROW-BASE SE1010N | 25 | Absent | — |
| product | based | (Unitika Limited.) | | | |
| Comparative | Urethane- | SUPERFLEX 500M | 46 | Absent | — |
| product | based | (DKS Co., Ltd.) | | | |
| Comparative | Urethane- | SUPERFLEX 460S | 37.6 | Absent | — |
| product | based | (DKS Co., Ltd.) | | | |
| Comparative | Polyester- | FINETEX ES2200 | 30 | Absent | — |
| product | based | (DIC Corporation) | | | |

After that, each of compositions for forming a coating layer (C) (in Tables 6 to 10, denoted as “(C) layer”) [C-1 to C-9] was applied to the surface of the (B) layer so that the dried film thickness reached 0.3 μm and was dried, thereby forming a (C) layer.

The formulations of the compositions for forming a coating layer (C) [C-1 to C-9] are shown in Table 3 below. EMALEX110 was used after being diluted with a solvent mixture of water and ethanol (at a ratio of 2:1) so that the content thereof reached 2% by mass.

TABLE 3

| | Concentration | | | | | | | | | | |
|---|---|---|---|---|---|---|---|---|---|---|---|
| | of raw | Concentration | | | | | | | | | |
| Materials | material | used | C-1 | C-2 | C-3 | C-4 | C-5 | C-6 | C-7 | C-8 | C-9 |
| ARROW-BASE SE- | 20.2 | 20.2 | 122.2 | 114.4 | 107.3 | 99.1 | 108.8 | 94.2 | 86.4 | 94.2 | 86.4 |
| 1013N | | | | | | | | | | | |
| (Unitika Limited.) | | | | | | | | | | | |
| AS-563A | 28 | 28 | | | | | 19.6 | 17.0 | 15.6 | 17.0 | 15.6 |
| (Daicel FineChem Ltd.) | | | | | | | | | | | |
| EPOCROS WS700 | 25 | 25 | 25.1 | 23.5 | 22.0 | 20.4 | 14.0 | 12.1 | 11.1 | 12.1 | 11.1 |
| (Nippon Shokubai Co., | | | | | | | | | | | |
| Ltd.) | | | | | | | | | | | |
| Sodium = 1,2- | 100 | 2 | 1.4 | 1.3 | 1.2 | 1.1 | 1.6 | | | | |
| {bis(3,3,4,4,5,5,6,6,6- | | | | | | | | | | | |
| nanofluorohexyl | | | | | | | | | | | |
| carbonyl)}ethanesulfonate | | | | | | | | | | | |
| NAROACTY CL-95 | 100 | 1 | 5.6 | 205.6 | 385.6 | 593.5 | 6.2 | | | | |
| (Sanyo Chemical | | | | | | | | | | | |
| Industries, ltd.) | | | | | | | | | | | |
| Compound SI-3 shown | 100 | 10 | | | | | | | | 42.3 | 64.7 |
| below | | | | | | | | | | | |
| EMALEX110 | 100 | 10 | | | | | | 42.3 | 64.7 | | |
| (Nihon emulsion Co., | | | | | | | | | | | |
| Ltd.) | | | | | | | | | | | |
| Distilled water | | | 845.7 | 655.3 | 483.9 | 285.9 | 849.8 | 834.3 | 822.2 | 834.3 | 822.2 |

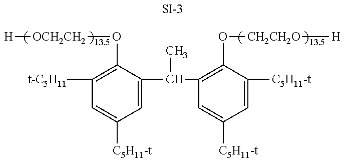

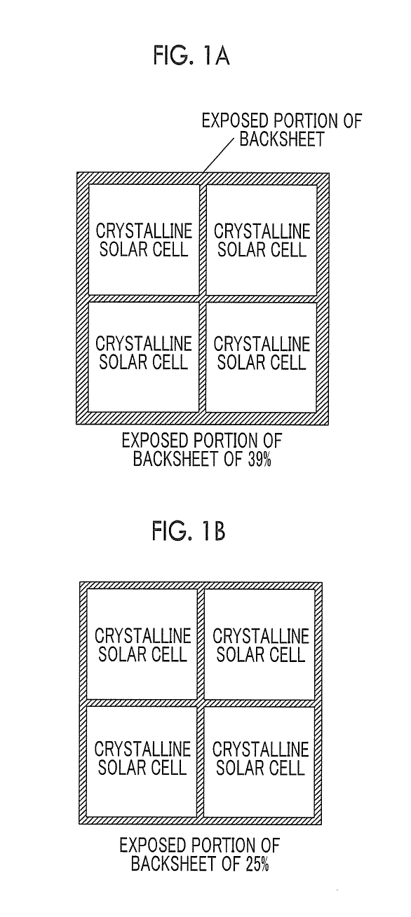

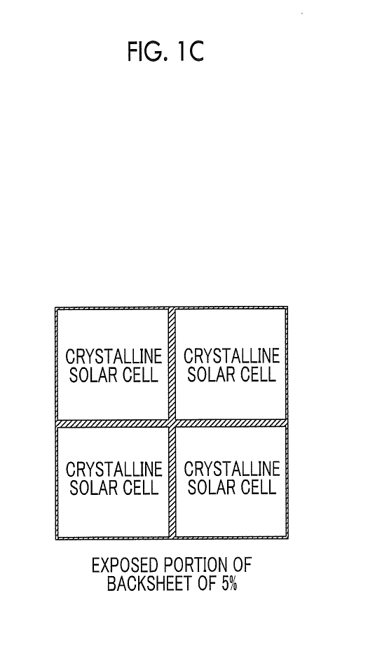

Furthermore, as weather-resistant layers, a (D) layer and an (E) layer were formed in an order illustrated in FIG. 1 on the side of the supporter on which the inline coating layer was not formed using a composition for forming a (D) layer and a composition for forming an (E) layer each having a formulation shown in Tables 4 and 5, thereby obtaining a back sheet.

—Formation of (D) Layer—

1. Preparation of Titanium Dioxide Dispersion

Titanium dioxide was dispersed using a Dyno-Mill disperser so that the average particle diameter of titanium dioxide reached 0.42 μm, thereby preparing a titanium dioxide dispersion. Meanwhile, the average particle diameter of titanium dioxide was measured using a MICROTRACK FRA manufactured by Honeywell Inc.
(Formulation of the Dispersion of Titanium Dioxide)
   Titanium dioxide . . . 455.8 parts by mass (TIPAQUE CR-95, manufactured by Ishihara Sangyo Kaisha, Ltd., powder)
   PVA aqueous solution . . . 227.9 parts by mass (PVA-105, manufactured by Kuraray Co., Ltd., concentration of 10% by mass)
   Dispersing agent . . . 5.5 parts by mass (DEMOL EP, manufactured by Kao Corporation, concentration of 25% by mass)
   Distilled water . . . 310.8 parts by mass

2. Preparation of composition for forming (D) layer

Individual components shown in Table 4 below were mixed together, thereby preparing compositions for forming a (D) layer [D-1 to D-4]. As the “titanium dioxide dispersion liquid *” in Table 4 below, the titanium dioxide dispersion liquid prepared above was used.

3. Formation of (D) Layer

The obtained composition for forming a (D) layer was applied onto the rear surface (surface on which the (B) layer was not formed) of the polymer supporter so that the amount of the binder applied reached 4.7 g/m² and the amount of titanium dioxide applied reached 5.6 g/m² and was dried at 170° C. for two minutes, thereby forming a 5 μm-thick (D) layer (white layer).

TABLE 4

| | Concentration of | Concentration | | | | |
|---|---|---|---|---|---|---|
| Materials | raw material | used | D-1 | D-2 | D-3 | D-4 |
| CERANATE WSA1070 | 38 | 38 | 381.7 | 381.7 | 381.7 | 381.7 |
| (DIC Corporation) | | | | | | |
| NAROACTY CL-95 | 100 | 1 | 13.1 | 13.1 | 13.1 | 13.1 |
| (Sanyo Chemical Industries, ltd.) | | | | | | |
| EPOCROS WS700 | 25 | 25 | 105.1 | 105.1 | 105.1 | 105.1 |
| (Nippon Shokubai Co., Ltd.) | | | | | | |
| MF-5630 BLACK | 31.5 | 31.5 | | 1.4 | 0.7 | 35 |
| (Dainichiseika Color & Chemicals | | | | | | |
| Mfg. Co., Ltd.) | | | | | | |
| Distilled water | 0 | 0 | 14.3 | 15.3 | 15.5 | 15.5 |
| Titanium dioxide dispersion liquid* | 48 | 48 | 483.4 | 483.4 | 483.4 | 483.4 |

—Formation of (E) Layer—

Coating fluids for the composition for forming an (E) layer of the compositions for forming an (E) layer [E-1 to E-3] shown in Table 5 below were applied to the surface of the (D) layer so that the amount of the binder applied reached 1.3 g/m² and were dried at 175° C. for two minutes, thereby forming (E) layers.

The thicknesses of the (E) layers were all 0.3 μm. In addition, Tables 6 to 10 below show which compositions were used to form the (C) to (E) layers forming on the supporters.

TABLE 5

| | Concen- | | | | |
|---|---|---|---|---|---|
| | tration | Concen- | | | |
| | of raw | tration | | | |
| Materials | material | used | E-1 | E-2 | E-3 |
| OBBLIGATO | 36 | 36 | 345.0 | | 172.5 |
| SW0011F | | | | | |
| (AGC Coat-Tech | | | | | |
| Co., Ltd.) | | | | | |
| CERANATE | 38 | 38 | | 326.8 | 163.4 |
| WSA1070 | | | | | |
| (DIC Corporation) | | | | | |
| SNOWTEX UP | 20 | 20 | 3.9 | 3.9 | 3.9 |
| (Nissan Chemical | | | | | |
| Industries, Ltd.) | | | | | |
| TSL8340 | 1 | 1 | 78.5 | 78.5 | 78.5 |
| (Momentive | | | | | |
| Performance | | | | | |
| Materials Inc.) | | | | | |
| CHEMIPAL W950 | 5 | 5 | 207.0 | 207.0 | 207.0 |
| (Mitsui Chemicals, | | | | | |
| Inc.) | | | | | |
| NAROACTY CL-95 | 100 | 1 | 60.0 | 60.0 | 60.0 |
| (Sanyo Chemical | | | | | |
| Industries, ltd.) | | | | | |
| CARBODILITE | 20 | 20 | 62.3 | 62.3 | 62.3 |
| V-02-L2 | | | | | |
| (Nisshinbo | | | | | |
| Holdings Inc.) | | | | | |
| Distilled water | | | 242.8 | 261.0 | 251.8 |

[Evaluation]

On the solar cell back sheets obtained in the respective examples, the following evaluations were carried out. The results thereof are shown in Tables 6 to 10 below.

(Adhering Force to Sealing Material (EVA))

The solar cell back sheet obtained in each of the examples was cut into 2.5 cm (TD direction)×15 cm (MD direction) pieces. Next, a back sheet for evaluation was placed on an EVA film (HANGZHOU F806) laminated on a 2.5 cm×7.5 cm×0.5 cm-thick glass plate so that the (C) layer came into contact with the EVA, and was laminated using a vacuum laminator (LAMINATOR 0505S) manufactured by Nisshinbo Mechatronics Inc. under conditions of 145° C., four minutes of evacuation, and 10 minutes of pressurization.

After the moisture content of the back sheet adhered to the EVA was adjusted to be a desired value for 24 hours or longer under conditions of 23° C. and 50%, two notches were made in the MD direction of the back sheet using a cutter so as to obtain a portion with a width of 10 mm, and a laminate of the notched back sheet, the EVA, and the glass plate was stored for 30 hours in an environment of 121° C. and 100%.

The 10 mm-wide portion of the above-produced sample was pulled at 180 degrees using a TENSILON at a rate of 100 mm/min. In addition, the failure stress of the (B) layer was evaluated according to the following evaluation standards. As the stress increased, an adhering force under conditions of a high temperature and a high humidity increased, and the weather resistance was evaluated to be excellent.

In addition, a peeled portion was visually observed, and the presence or absence of aggregation failure on the surface of PET which was the supporter was determined. When aggregation failure occurs, the PET supporter does transition.

The above-described test was carried out ten times, and the aggregation failure ratio (transition probability) of the surface of PET was determined according to the following standards.
Failure stress in (B) layer (in Tables 6 to 10, denoted as “adhering force”)
5: A back sheet with a failure stress of 5 N/mm or higher
4: A back sheet with a failure stress in a range of 4 N/mm or higher and lower than 5 N/mm
3: A back sheet with a failure stress in a range of 3 N/mm or higher and lower than 4 N/mm
2: A back sheet with a failure stress in a range of 2 N/mm or higher and lower than 3 N/mm
1: A back sheet in which the failure stress of the B coating layer cannot be measured using the aggregation failure of the entire PET
Aggregation failure probability of PET (in Tables 6 to 10, denoted as “transition probability”)
3: No aggregation failure occurs in PET
2: Aggregation failure occurs in half or less of PET
1: Aggregation failure occurs in entire PET

TABLE 6

| | (B) layer | | | | | | | Evaluation results | |
|---|---|---|---|---|---|---|---|---|---|
| | Polymer | | | | | | | PCT | |
| | | Concentration | Inorganic particles | | | | | (121° C./100%/30 h) | |
| | | used | | Added amount | (C) layer | (D) layer | (E) layer | Transition | Adhering |
| | Trade name | % by mass | Type | % by capacity | Formulation | Formulation | Formulation | probability | force |
| Example 1 | BONRON XPS001 | 45 | None | 0 | C-1 | D-1 | E-2 | 2 | 4 |
| Example 2 | BONRON XPS002 | 45 | None | 0 | C-1 | D-1 | E-2 | 2 | 5 |
| | (Mitsui Chemicals, Inc.) | | | | | | | | |
| Comparative | AS-563A | 28 | None | 0 | C-1 | D-1 | E-2 | 1 | 1 |
| Example 1 | (Daicel FineChem Ltd.) | | | | | | | | |
| Comparative | JONCRYL PDX-7341 | 49 | None | 0 | C-1 | D-1 | E-2 | 1 | 1 |
| Example 2 | (BASF) | | | | | | | | |
| Example 3 | HARDLEN NZ-1001 | 30 | None | 0 | C-1 | D-1 | E-2 | 2 | 4 |
| | (Toyobo Co., Ltd.) | | | | | | | | |
| Comparative | HITECH S3148 | 28 | None | 0 | C-1 | D-1 | E-2 | 1 | 1 |
| Example 3 | (Toho Chemical Industry | | | | | | | | |
| | Co., Ltd.) | | | | | | | | |
| Comparative | ARROW-BASE SE1013N | 20.2 | None | 0 | C-1 | D-1 | E-2 | 1 | 1 |
| Example 4 | (Unitika Limited.) | | | | | | | | |
| Comparative | ARROW-BASE SE1010N | 25 | None | 0 | C-1 | D-1 | E-2 | 1 | 1 |
| Example 5 | (Unitika Limited.) | | | | | | | | |
| Comparative | SUPERFLEX 500M | 46 | None | 0 | C-1 | D-1 | E-2 | 1 | 1 |
| Example 6 | (DKS Co., Ltd.) | | | | | | | | |
| Comparative | SUPERFLEX 460S | 37.6 | None | 0 | C-1 | D-1 | E-2 | 1 | 1 |
| Example 7 | (DKS Co., Ltd.) | | | | | | | | |
| Comparative | FINETEX ES2200 | 30 | None | 0 | C-1 | D-1 | E-2 | 1 | 1 |
| Example 8 | (DIC Corporation) | | | | | | | | |

TABLE 7

| | (B) layer | | | | | |
|---|---|---|---|---|---|---|
| | Polymer | | Inorganic particles | | | |
| | | Concentration | | | Particle | |
| | | used | | | diameter | Added amount |
| | Trade name | % by mass | Type | Trade name | μm | % by capacity |
| Example 4 | BONRON XPS002 | 45 | Titanium | TTO-51 | 0.02 | 20 |
| | (Mitsui Chemicals, | | oxide | (Ishihara Sangyo Kaisha, | | |
| | Inc.) | | | Ltd.) | | |
| Example 5 | BONRON XPS002 | 45 | Titanium | CR-95 | 0.25 | 20 |
| | (Mitsui Chemicals, | | oxide | (Ishihara Sangyo Kaisha, | | |
| | Inc.) | | | Ltd.) | | |
| Example 6 | BONRON XPS002 | 45 | Titanium | CR-95 | 0.25 | 20 |
| | (Mitsui Chemicals, | | oxide | (Ishihara Sangyo Kaisha, | | |
| | Inc.) | | | Ltd.) | | |
| Example 7 | BONRON XPS002 | 45 | Titanium | CR-95 | 0.25 | 20 |
| | (Mitsui Chemicals, | | oxide | (Ishihara Sangyo Kaisha, | | |
| | Inc.) | | | Ltd.) | | |
| Example 8 | BONRON XPS002 | 45 | Titanium | CR-95 | 0.25 | 20 |
| | (Mitsui Chemicals, | | oxide | (Ishihara Sangyo Kaisha, | | |
| | Inc.) | | | Ltd.) | | |
| Example 9 | BONRON XPS002 | 45 | Titanium | CR-95 | 0.25 | 20 |
| | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 10 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 11 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 12 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 13 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 14 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 15 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 16 | (Mitsui Chemicals, | | oxide | (Ishihara Sangyo Kaisha, | | |
| | Inc.) | | | Ltd.) | | |
| Example | BONRON XPS002 | 45 | Titanium | CR-95 | 0.25 | 20 |
| 17 | (Mitsui Chemicals, | | oxide | (Ishihara Sangyo Kaisha, | | |
| | Inc.) | | | Ltd.) | | |
| Example | BONRON XPS002 | 45 | Colloidal | SNOWTEX C | 0.02 | 20 |
| 18 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 19 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 20 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 21 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 22 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 23 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 24 | (Mitsui Chemicals, | | silica | (Nissan Chemical | | |
| | Inc.) | | | Industries, Ltd.) | | |
| Example | BONRON XPS002 | 45 | Colloidal | SNOWTEX MP-2040 | 0.2 | 20 |
| 25 | (Mitsui Chemicals, | | silica | | | |
| | Inc.) | | | | | |
| Example | BONRON XPS002 | 45 | Colloidal | SNOWTEX MP-2040 | 0.45 | 20 |
| 26 | (Mitsui Chemicals, | | silica | | | |
| | Inc.) | | | | | |
| Example | BONRON XPS002 | 45 | Aluminum | TM-5D | 0.2 | 20 |
| 27 | (Mitsui Chemicals, | | oxide | (Taimei Chemicals Co., | | |
| | Inc.) | | | Ltd.) | | |
| Example | BONRON XPS002 | 45 | Zirconium | SZR-CW | 0.05 | 20 |
| 28 | (Mitsui Chemicals, | | oxide | (Sakai Chemical Industry | | |
| | Inc.) | | | Co. Ltd.) | | |
| Example | BONRON XPS002 | 45 | Titanium | JR-1000 | 1.0 | 20 |
| 29 | (Mitsui Chemicals, | | oxide | (TAYCA Corporation) | | |
| | Inc.) | | | | | |
| Example | BONRON XPS002 | 45 | Silica | ADMAFINE SO-C3 | 0.9 | 20 |
| 30 | (Mitsui Chemicals, | | particles | (Admatechs) | | |
| | Inc.) | | | | | |

| | | | | Evaluation results | |
|---|---|---|---|---|---|
| | | | | PCT | |
| | | | | (121° C./100%/30 h) | |
| | (C) layer | (D) layer | (E) layer | Transition | Adhering |
| | Formulation | Formulation | Formulation | probability | force |
| Example 4 | C-1 | D-1 | E-2 | 3 | 5 |
| Example 5 | C-1 | D-1 | E-2 | 3 | 5 |
| Example 6 | C-1 | D-2 | E-2 | 3 | 5 |
| Example 7 | C-2 | D-2 | E-2 | 3 | 5 |
| Example 8 | C-2 | D-2 | E-1 | 3 | 5 |
| Example 9 | C-2 | D-2 | E-3 | 3 | 5 |
| Example | C-2 | D-3 | E-3 | 3 | 5 |
| 10 | | | | | |
| Example | C-3 | D-2 | E-2 | 3 | 5 |
| 11 | | | | | |
| Example | C-4 | D-2 | E-2 | 3 | 5 |
| 12 | | | | | |
| Example | C-5 | D-2 | E-2 | 3 | 5 |
| 13 | | | | | |
| Example | C-6 | D-2 | E-2 | 3 | 5 |
| 14 | | | | | |
| Example | C-7 | D-2 | E-2 | 3 | 5 |
| 15 | | | | | |
| Example | C-8 | D-2 | E-2 | 3 | 5 |
| 16 | | | | | |
| Example | C-9 | D-2 | E-2 | 3 | 5 |
| 17 | | | | | |
| Example | C-1 | D-1 | E-2 | 3 | 5 |
| 18 | | | | | |
| Example | C-1 | D-1 | E-2 | 3 | 4 |
| 19 | | | | | |
| Example | C-1 | D-1 | E-2 | 3 | 5 |
| 20 | | | | | |
| Example | C-1 | D-1 | E-2 | 3 | 5 |
| 21 | | | | | |
| Example | C-1 | D-1 | E-2 | 3 | 5 |
| 22 | | | | | |
| Example | C-1 | D-1 | E-2 | 3 | 5 |
| 23 | | | | | |
| Example | C-1 | D-1 | E-2 | 3 | 4 |
| 24 | | | | | |
| Example | C-1 | D-1 | E-2 | 3 | 5 |
| 25 | | | | | |
| Example | C-1 | D-1 | E-2 | 2 | 5 |
| 26 | | | | | |
| Example | C-1 | D-1 | E-2 | 3 | 5 |
| 27 | | | | | |
| Example | C-1 | D-1 | E-2 | 3 | 5 |
| 28 | | | | | |
| Example | C-1 | D-1 | E-2 | 2 | 2 |
| 29 | | | | | |
| Example | C-1 | D-1 | E-2 | 2 | 2 |
| 30 | | | | | |

TABLE 8

| | (B) layer | | | | | |
|---|---|---|---|---|---|---|
| | | | Inorganic particles | | | |
| | Polymer | | | | | Added |
| | | Concentration | | | Particle | amount |
| | | used | | | diameter | % by |
| | Trade name | % by mass | Type | Trade name | μm | capacity |
| Example | BONRON XPS002 | 45 | Aluminum | ADMAFINE AO- | 0.7 | 20 |
| 31 | (Mitsui Chemicals, | | oxide | C502 | | |
| | Inc.) | | | (Admatechs) | | |
| Example | BONRON XPS002 | 45 | Colloidal | SNOWTEX C | 0.02 | 5 |
| 32 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 10 |
| 33 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 15 |
| 34 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 25 |
| 35 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 20 |
| 36 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 37 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 38 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 39 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 40 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 41 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 42 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 43 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 44 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 45 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 46 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 47 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 48 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 49 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | BONRON XPS002 | 45 | Colloidal | SNOWTEX C | 0.02 | 20 |
| 50 | (Mitsui Chemicals, | | silica | (Nissan Chemical | | |
| | Inc.) | | | Industries, Ltd.) | | |
| | | | Titanium | CR-95 | 0.25 | 5 |
| | | | oxide | (Ishihara Sangyo | | |
| | | | | Kaisha, Ltd.) | | |

| | | | | Evaluation results | |
|---|---|---|---|---|---|
| | | | | PCT | |
| | | | | (121° C./100%/30 h) | |
| | (C) layer | (D) layer | (E) layer | Transition | Adhering |
| | Formulation | Formulation | Formulation | probability | force |
| Example | C-1 | D-1 | E-2 | 2 | 2 |
| 31 | | | | | |
| Example | C-1 | D-1 | E-2 | 2 | 5 |
| 32 | | | | | |
| Example | C-1 | D-1 | E-2 | 2 | 5 |
| 33 | | | | | |
| Example | C-1 | D-1 | E-2 | 3 | 5 |
| 34 | | | | | |
| Example | C-1 | D-1 | E-2 | 3 | 5 |
| 35 | | | | | |
| Example | C-1 | D-1 | E-2 | 3 | 5 |
| 36 | | | | | |
| Example | C-1 | D-2 | E-2 | 3 | 5 |
| 37 | | | | | |
| Example | C-1 | D-2 | E-1 | 3 | 5 |
| 38 | | | | | |
| Example | C-1 | D-2 | E-3 | 3 | 5 |
| 39 | | | | | |
| Example | C-1 | D-3 | E-2 | 3 | 5 |
| 40 | | | | | |
| Example | C-2 | D-1 | E-2 | 3 | 5 |
| 41 | | | | | |
| Example | C-3 | D-1 | E-2 | 3 | 5 |
| 42 | | | | | |
| Example | C-4 | D-1 | E-2 | 3 | 5 |
| 43 | | | | | |
| Example | C-5 | D-1 | E-2 | 3 | 5 |
| 44 | | | | | |
| Example | C-6 | D-1 | E-2 | 3 | 5 |
| 45 | | | | | |
| Example | C-6 | D-1 | E-1 | 3 | 5 |
| 46 | | | | | |
| Example | C-7 | D-1 | E-2 | 3 | 5 |
| 47 | | | | | |
| Example | C-8 | D-1 | E-2 | 3 | 5 |
| 48 | | | | | |
| Example | C-8 | D-1 | E-1 | 3 | 5 |
| 49 | | | | | |
| Example | C-9 | D-1 | E-2 | 3 | 5 |
| 50 | | | | | |

TABLE 9

| | (B) layer | | | | | |
|---|---|---|---|---|---|---|
| | | | Inorganic particles | | | |
| | Polymer | | | | | Added |
| | | Concentration | | | Particle | mount |
| | | used | | | diameter | % by |
| | Trade name | % by mass | Type | Trade name | μm | capacity |
| Example | BONRON XPS002 | 45 | Colloidal | SNOWTEX C | 0.02 | 20 |
| 51 | (Mitsui Chemicals, | | silica | (Nissan Chemical | | |
| | Inc.) | | | Industries, Ltd.) | | |
| | | | Aluminum | TM-5D | 0.2 | 5 |
| | | | oxide | (Taimei Chemicals | | |
| | | | | Co., Ltd.) | | |
| Example | BONRON XPS002 | 45 | Colloidal | SNOWTEX C | 0.02 | 20 |
| 52 | (Mitsui Chemicals, | | silica | (Nissan Chemical | | |
| | Inc.) | | | Industries, Ltd.) | | |
| | | | Zirconium | SZR-CW | 0.05 | 5 |
| | | | oxide | (Sakai Chemical | | |
| | | | | Industry Co. Ltd.) | | |
| Example | BONRON XPS002 | 45 | Colloidal | SNOWTEX C | 0.02 | 30 |
| 53 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 35 |
| 54 | (Mitsui Chemicals, | | silica | (Nissan Chemical | | |
| | Inc.) | | | Industries, Ltd.) | | |
| Example | BONRON XPS002 | 45 | Colloidal | SNOWTEX C | 0.02 | 40 |
| 55 | (Mitsui Chemicals, | | silica | (Nissan Chemical | | |
| | Inc.) | | | Industries, Ltd.) | | |
| Example | BONRON XPS002 | 45 | Titanium | CR-95 | 0.25 | 40 |
| 56 | (Mitsui Chemicals, | | oxide | (Ishihara Sangyo | | |
| | Inc.) | | | Kaisha, Ltd.) | | |
| Example | HARDLEN NZ1001 | 30 | Colloidal | SNOWTEX C | 0.02 | 5 |
| 57 | (Toyobo Co., Ltd.) | | silica | (Nissan Chemical | | |
| | | | | Industries, Ltd.) | | |
| Example | HARDLEN NZ1001 | 30 | Colloidal | SNOWTEX C | 0.02 | 10 |
| 58 | (Toyobo Co., Ltd.) | | silica | (Nissan Chemical | | |
| | | | | Industries, Ltd.) | | |
| Example | HARDLEN NZ1001 | 30 | Colloidal | SNOWTEX C | 0.02 | 15 |
| 59 | (Toyobo Co., Ltd.) | | silica | (Nissan Chemical | | |
| | | | | Industries, Ltd.) | | |
| Example | HARDLEN NZ1001 | 30 | Colloidal | SNOWTEX C | 0.02 | 25 |
| 60 | (Toyobo Co., Ltd.) | | silica | (Nissan Chemical | | |
| | | | | Industries, Ltd.) | | |
| Example | HARDLEN NZ1001 | 30 | Colloidal | SNOWTEX C | 0.02 | 20 |
| 61 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 62 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 63 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 64 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 65 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 66 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 67 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 68 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 69 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 70 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |

| | | | | Evaluation results | |
|---|---|---|---|---|---|
| | | | | PCT | |
| | | | | (121° C./100%/30 h) | |
| | (C) layer | (D) layer | (E) layer | Transition | Adhering |
| | Formulation | Formulation | Formulation | probability | force |
| Example | C-1 | D-1 | E-2 | 3 | 5 |
| 51 | | | | | |
| Example | C-1 | D-1 | E-2 | 3 | 5 |
| 52 | | | | | |
| Example | C-1 | D-1 | E-2 | 3 | 4 |
| 53 | | | | | |
| Example | C-1 | D-1 | E-2 | 3 | 3 |
| 54 | | | | | |
| Example | C-1 | D-1 | E-2 | 2 | 2 |
| 55 | | | | | |
| Example | C-1 | D-1 | E-2 | 2 | 2 |
| 56 | | | | | |
| Example | C-1 | D-1 | E-2 | 2 | 3 |
| 57 | | | | | |
| Example | C-1 | D-1 | E-2 | 2 | 4 |
| 58 | | | | | |
| Example | C-1 | D-1 | E-2 | 3 | 4 |
| 59 | | | | | |
| Example | C-1 | D-1 | E-2 | 3 | 5 |
| 60 | | | | | |
| Example | C-1 | D-1 | E-2 | 3 | 5 |
| 61 | | | | | |
| Example | C-1 | D-2 | E-2 | 3 | 5 |
| 62 | | | | | |
| Example | C-1 | D-3 | E-2 | 3 | 5 |
| 63 | | | | | |
| Example | C-1 | D-3 | E-1 | 3 | 5 |
| 64 | | | | | |
| Example | C-1 | D-3 | E-3 | 3 | 5 |
| 65 | | | | | |
| Example | C-2 | D-1 | E-2 | 3 | 5 |
| 66 | | | | | |
| Example | C-3 | D-1 | E-2 | 3 | 5 |
| 67 | | | | | |
| Example | C-4 | D-1 | E-2 | 3 | 5 |
| 68 | | | | | |
| Example | C-5 | D-1 | E-2 | 3 | 5 |
| 69 | | | | | |
| Example | C-6 | D-1 | E-2 | 3 | 5 |
| 70 | | | | | |

TABLE 10

| | (B) layer | | | | | |
|---|---|---|---|---|---|---|
| | | | Inorganic particles | | | |
| | Polymer | | | | | Added |
| | | Concentration | | | Particle | amount |
| | | used | | | diameter | % by |
| | Trade name | % by mass | Type | Trade name | μm | capacity |
| Example | HARDLEN NZ1001 | 30 | Colloidal | SNOWTEX C | 0.02 | 20 |
| 71 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 72 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 73 | (Toyobo Co., Ltd.) | | silica | (Nissan Chemical | | |
| | | | | Industries, Ltd.) | | |
| | | | Titanium | CR-95 | 0.25 | 5 |
| | | | oxide | (Ishihara Sangyo | | |
| | | | | Kaisha, Ltd.) | | |
| Example | HARDLEN NZ1001 | 30 | Colloidal | SNOWTEX C | 0.02 | 20 |
| 74 | (Toyobo Co., Ltd.) | | silica | (Nissan Chemical | | |
| | | | | Industries, Ltd.) | | |
| | | | Aluminum | TM-5D | 0.2 | 5 |
| | | | oxide | (Taimei Chemicals | | |
| | | | | Co., Ltd.) | | |
| Example | HARDLEN NZ1001 | 30 | Colloidal | SNOWTEX C | 0.02 | 20 |
| 75 | (Toyobo Co., Ltd.) | | silica | (Nissan Chemical | | |
| | | | | Industries, Ltd.) | | |
| | | | Zirconium | SZR-CW | 0.05 | 5 |
| | | | oxide | (Sakai Chemical | | |
| | | | | Industry Co. Ltd.) | | |
| Example | HARDLEN NZ1001 | 30 | Colloidal | SNOWTEX C | 0.02 | 30 |
| 76 | (Toyobo Co., Ltd.) | | silica | (Nissan Chemical | | |
| | | | | Industries, Ltd.) | | |
| Example | HARDLEN NZ1001 | 30 | Colloidal | SNOWTEX C | 0.02 | 35 |
| 77 | (Toyobo Co., Ltd.) | | silica | (Nissan Chemical | | |
| | | | | Industries, Ltd.) | | |
| Example | HARDLEN NZ1001 | 30 | Colloidal | SNOWTEX C | 0.02 | 40 |
| 78 | (Toyobo Co., Ltd.) | | silica | (Nissan Chemical | | |
| | | | | Industries, Ltd.) | | |
| Example | HARDLEN NZ1001 | 30 | Titanium | CR-95 | 0.25 | 40 |
| 79 | (Toyobo Co., Ltd.) | | oxide | (Ishihara Sangyo | | |
| | | | | Kaisha, Ltd.) | | |
| Example | BONRON XPS001 | 45 | Colloidal | SNOWTEX C | 0.02 | 20 |
| 80 | (50%) | | silica | (Nissan Chemical | | |
| | (Mitsui Chemicals, | | | Industries, Ltd.) | | |
| | Inc.) | | | | | |
| | BONRON XPS002 | 45 | Titanium | CR-95 | 0.25 | 5 |
| | (50%) | | oxide | (Ishihara Sangyo | | |
| | (Mitsui Chemicals, | | | Kaisha, Ltd.) | | |
| | Inc.) | | | | | |
| Example | BONRON XPS001 | 45 | Colloidal | SNOWTEX C | 0.02 | 20 |
| 81 | (50%) | | silica | (Nissan Chemical | | |
| | (Mitsui Chemicals, | | | Industries, Ltd.) | | |
| | Inc.) | | | | | |
| | HARDLEN NZ1001 | 30 | Titanium | CR-95 | 0.25 | 5 |
| | (50%) | | oxide | (Ishihara Sangyo | | |
| | (Toyobo Co., Ltd.) | | | Kaisha, Ltd.) | | |
| Example | BONRON XPS002 | 45 | Colloidal | SNOWTEX C | 0.02 | 20 |
| 82 | (50%) | | silica | (Nissan Chemical | | |
| | (Mitsui Chemicals, | | | Industries, Ltd.) | | |
| | Inc.) | | | | | |
| | HARDLEN NZ1001 | 30 | Titanium | CR-95 | 0.25 | 5 |
| | (50%) | | oxide | (Ishihara Sangyo | | |
| | (Toyobo Co., Ltd.) | | | Kaisha, Ltd.) | | |
| Example | BONRON XPS001 | 45 | Colloidal | SNOWTEX C | 0.02 | 20 |
| 83 | (30%) | | silica | (Nissan Chemical | | |
| | (Mitsui Chemicals, | | | Industries, Ltd.) | | |
| | Inc.) | | | | | |
| | BONRON XPS002 | 45 | Titanium | CR-95 | 0.25 | 5 |
| | (50%) | | oxide | (Ishihara Sangyo | | |
| | (Mitsui Chemicals, | | | Kaisha, Ltd.) | | |
| | Inc.) | | | | | |
| | HARDLEN NZ1001 | 30 | | | | |
| | (20%) | | | | | |
| | (Toyobo Co., Ltd.) | | | | | |
| Example | BONRON XPS002 | 45 | Colloidal | SNOWTEX C | 0.02 | 20 |
| 84 | (Mitsui Chemicals, | | silica | (Nissan Chemical | | |
| | Inc.) | | | Industries, Ltd.) | | |
| | | | Carbon | MF BLACK 5630 | 0.16 | 0.8 |
| | | | black | (Dainichiseika Color | | |
| | | | | and Chemicals Mfg. | | |
| | | | | Co., Ltd.) | | |
| Example | BONRON XPS002 | 45 | Colloidal | SNOWTEX C | 0.02 | 20 |
| 85 | (Mitsui Chemicals, | | silica | (Nissan Chemical | | |
| | Inc.) | | | Industries, Ltd.) | | |
| | | | Carbon | MF BLACK 5630 | 0.16 | 0.8 |
| | | | black | (Dainichiseika Color | | |
| | | | | and Chemicals Mfg. | | |
| | | | | Co., Ltd.) | | |
| Example | BONRON XPS002 | 45 | Colloidal | SNOWTEX C | 0.02 | 20 |
| 86 | (Mitsui Chemicals, | | silica | (Nissan Chemical | | |
| | Inc.) | | | Industries, Ltd.) | | |
| | | | Carbon | MF BLACK 5630 | 0.16 | 0.8 |
| | | | black | (Dainichiseika Color | | |
| | | | | and Chemicals Mfg. | | |
| | | | | Co., Ltd.) | | |
| Example | BONRON XPS002 | 45 | Colloidal | SNOWTEX C | 0.02 | 20 |
| 87 | (Mitsui Chemicals, | | silica | (Nissan Chemical | | |
| | Inc.) | | | Industries, Ltd.) | | |
| | | | Carbon | MF BLACK 5630 | 0.16 | 0.8 |
| | | | black | (Dainichiseika Color | | |
| | | | | and Chemicals Mfg. | | |
| | | | | Co., Ltd.) | | |

| | | | | Evaluation results | |
|---|---|---|---|---|---|
| | | | | PCT | |
| | | | | (121° C./100%/30 h) | |
| | (C) layer | (D) layer | (E) layer | Transition | Adhering |
| | Formulation | Formulation | Formulation | probability | force |
| Example | C-7 | D-1 | E-2 | 3 | 5 |
| 71 | | | | | |
| Example | C-8 | D-1 | E-2 | 3 | 5 |
| 72 | | | | | |
| Example | C-9 | D-1 | E-2 | 3 | 5 |
| 73 | | | | | |
| Example | C-1 | D-1 | E-2 | 3 | 5 |
| 74 | | | | | |
| Example | C-1 | D-1 | E-2 | 3 | 5 |
| 75 | | | | | |
| Example | C-1 | D-1 | E-2 | 3 | 3 |
| 76 | | | | | |
| Example | C-1 | D-1 | E-2 | 3 | 3 |
| 77 | | | | | |
| Example | C-1 | D-1 | E-2 | 2 | 2 |
| 78 | | | | | |
| Example | C-1 | D-1 | E-2 | 2 | 2 |
| 79 | | | | | |
| Example | C-1 | D-1 | E-2 | 3 | 5 |
| 80 | | | | | |
| Example | C-1 | D-1 | E-2 | 3 | 4 |
| 81 | | | | | |
| Example | C-1 | D-1 | E-2 | 3 | 4 |
| 82 | | | | | |
| Example | C-1 | D-1 | E-2 | 3 | 4 |
| 83 | | | | | |
| Example | C-7 | D-4 | E-1 | 3 | 5 |
| 84 | | | | | |
| Example | C-9 | D-4 | E-1 | 3 | 5 |
| 85 | | | | | |
| Example | C-9 | D-2 | E-1 | 3 | 5 |
| 86 | | | | | |
| Example | C-9 | D-3 | E-1 | 3 | 5 |
| 87 | | | | | |

TABLE 11

| | (B) layer | | | | | |
|---|---|---|---|---|---|---|
| | | | Inorganic particles | | | |
| | Polymer | | | | | Added |
| | | Concentration | | | Particle | amount |
| | | used | | | diameter | % by |
| | Trade name | % by mass | Type | Trade name | μm | capacity |
| Example | BONRON | 45 | Colloidal | SNOWTEX C | 0.02 | 20 |
| 88 | XPS002 | | silica | (Nissan Chemical | | |
| | (Mitsui | | | Industries, Ltd.) | | |
| | Chemicals, | | | CR-95 | 0.25 | 5 |
| | Inc.) | | | (Ishihara Sangyo | | |
| | | | | Kaisha, Ltd.) | | |
| Example | BONRON | 45 | Colloidal | SNOWTEX C | 0.02 | 20 |
| 89 | XPS002 | | silica | (Nissan Chemical | | |
| | (Mitsui | | | Industries, Ltd.) | | |
| | Chemicals, | | | CR-95 | 0.25 | 5 |
| | Inc.) | | | (Ishihara Sangyo | | |
| | | | | Kaisha, Ltd.) | | |
| Example | BONRON | 45 | Colloidal | SNOWTEX C | 0.02 | 20 |
| 90 | XPS002 | | silica | (Nissan Chemical | | |
| | (Mitsui | | | Industries, Ltd.) | | |
| | Chemicals, | | | CR-95 | 0.25 | 5 |
| | Inc.) | | | (Ishihara Sangyo | | |
| | | | | Kaisha, Ltd.) | | |
| Example | BONRON | 45 | Colloidal | SNOWTEX C | 0.02 | 20 |
| 91 | XPS002 | | silica | (Nissan Chemical | | |
| | (Mitsui | | | Industries, Ltd.) | | |
| | Chemicals, | | | CR-95 | 0.25 | 5 |
| | Inc.) | | | (Ishihara Sangyo | | |
| | | | | Kaisha, Ltd.) | | |

| | | | | | Evaluation results | |
|---|---|---|---|---|---|---|
| | | | | | PCT | |
| | | | | | (121° C./100%/30 h) | |
| | (C) layer | (D) layer | (E) layer | Base | Transition | Adhering |
| | Formulation | Formulation | Formulation | material | probability | force |
| Example | C-7 | D-1 | E-1 | White PET | 3 | 5 |
| 88 | | | | 1.5% by | | |
| | | | | mass of | | |
| | | | | titanium | | |
| | | | | oxide | | |
| Example | C-9 | D-1 | E-1 | White PET | 3 | 5 |
| 89 | | | | 2.5% by | | |
| | | | | mass of | | |
| | | | | titanium | | |
| | | | | oxide | | |
| Example | C-9 | D-1 | E-1 | White PET | 3 | 5 |
| 90 | | | | 4.5% by | | |
| | | | | mass of | | |
| | | | | titanium | | |
| | | | | oxide | | |
| Example | C-9 | D-1 | E-1 | White PET | 2 | 5 |
| 91 | | | | 7.5% by | | |
| | | | | mass of | | |
| | | | | titanium | | |
| | | | | oxide | | |

From the above-described results, it is found that, in the present examples, the adhering force to the sealing material (EVA) after long-term storage in an environment of a high temperature and a high humidity was maintained at a favorable level and peeling between layers was also suppressed.

Therefore, it is found that, the solar cell back sheet of the present invention is capable of maintaining adhesiveness to a sealing material for sealing a solar cell element for a long period of time even under harsh conditions of a high temperature and a high humidity.

In addition, from the results of Examples 84 to 87, it is found that, when carbon black is added to the (B) layer, it is possible to impart a desirable light-shielding property to the solar cell back sheet with no degradation of adhering force and an effect of suppressing peeling between layers.

### Example 92

### Production of Solar Cell Power Generation Module

A 3 mm-thick reinforced glass plate, an EVA sheet (SC50B manufactured by Mitsui Chemicals, Inc.), a crystalline solar cell, an EVA sheet (SC50B manufactured by Mitsui Chemicals, Inc.), and the solar cell back sheet of Example 36 were superimposed in this order so that the (C) layer in the solar cell back sheet came into direct contact with the EVA sheet which was a sealing material for a solar cell element, and were hot-pressed using a vacuum laminator (manufactured by Nisshinbo Mechatronics Inc., vacuum lamination device), thereby adhering the (C) layer to the EVA. The adhering method is as described below.

After evacuation was carried out using the vacuum laminator at 128° C. for three minutes, the (C) layer and the EVA sheet were pressurized for two minutes and were temporarily adhered to each other. After that, a main adhesion treatment was carried out in a dry oven at 150° C. for 30 minutes.

A solar cell power generation module (hereinafter, in some cases, appropriately referred to as “solar cell module”) of Example 88 was produced in the above-described manner using the crystalline solar cell.

After the produced solar cell module was left to stand for 70 hours under environmental conditions of 120° C. and a relative humidity of 100%, the solar cell module was operated to generate power. Consequently, the solar cell back sheet of Example 36 had excellent weather resistance, and thus the solar cell power generation module of Example 36 could stably provide power generation performance for a long period of time.

### Examples 93 to 95

### Production of Solar Cell Power Generation Modules

A solar cell power generation module of Example 93 was produced in the same manner as in Example 92 except for the fact that the crystalline solar cell used in Example 92 and the solar cell back sheet of Example 36 were used and the crystalline solar cell was disposed so that the area of an exposed portion of the solar cell back sheet in a planar view reached 39% as illustrated in FIG. 1(A).

A solar cell power generation module of Example 94 was produced in the same manner as in Example 93 except for the fact that the crystalline solar cell was disposed so that the area of an exposed portion of the solar cell back sheet reached 25%.

A solar cell power generation module of Example 95 was produced in the same manner as in Example 93 except for the fact that the crystalline solar cell was disposed so that the area of an exposed portion of the solar cell back sheet reached 5%.

FIG. 1(A) is a plan view illustrating the solar cell module in which the area of the exposed portion of the solar cell back sheet is 39%, FIG. 1(B) is a plan view illustrating the solar cell module in which the area of the exposed portion of the solar cell back sheet is 25%, and FIG. 1(C) is a plan view illustrating the solar cell module in which the area of the exposed portion of the solar cell back sheet is 5%. In FIGS. 1(A) to 1(C), the hatched regions indicate the exposed portions of the solar cell back sheets.

The produced solar cell modules were operated to generate power in the same manner as in Example 92. Consequently, the solar cell back sheet of Example 36 had excellent weather resistance, and thus the solar cell power generation modules of Examples 93 to 95 could stably obtain power generation performance for a long period of time.

### Examples 96 to 98

### Production of Solar Cell Power Generation Modules

Solar cell power generation modules of Examples 96 to 98 were produced in the same manner as in Examples 93 to 95 except for the fact that the solar cell back sheet of Example 37 was used instead of the solar cell back sheet of Example 36. In the solar cell module of Example 96, the area of the exposed portion of the solar cell back sheet is 39% (refer to FIG. 1(A)); in Example 97, the area of the exposed portion of the solar cell back sheet is 25% (refer to FIG. 1(B)); in Example 98, the area of the exposed portion of the solar cell back sheet is 5% (refer to FIG. 1(C)).

The produced solar cell modules were operated to generate power in the same manner as in Example 92. Consequently, the solar cell back sheet of Example 37 had excellent weather resistance, and thus the solar cell power generation modules of Examples 96 to 98 could stably obtain power generation performance for a long period of time.

### Examples 99 to 101

### Production of Solar Cell Power Generation Modules

Solar cell power generation modules of Examples 99 to 101 were produced in the same manner as in Examples 93 to 95 except for the fact that the solar cell back sheet of Example 85 was used instead of the solar cell back sheet of Example 36. In the solar cell module of Example 99, the area of the exposed portion of the solar cell back sheet is 39% (refer to FIG. 1(A)); in Example 100, the area of the exposed portion of the solar cell back sheet is 25% (refer to FIG. 1(B)); in Example 101, the area of the exposed portion of the solar cell back sheet is 5% (refer to FIG. 1(C)).

The produced solar cell modules were operated to generate power in the same manner as in Example 92. As a result, since the solar cell back sheet of Example 37 had excellent weather resistance, the solar cell power generation modules of Examples 99 to 101 could stably obtain power generation performance for a long period of time.

The above description of the specific aspects of the present invention is provided for the purpose of description and explanation. There is no intention of limiting the present invention to the disclosed aspects or making the present invention exhaustive. Clearly, it is evident that a person skilled in the art can modify or transform the present invention to a significant extent. The aspects are simply selected in order to most appropriately describe the concept and actual applications of the present invention and aim to let other persons skilled in the art understand the present invention so that those persons can carry out a variety of aspects or transformations in order to make the present invention suitable for a specific use they have in their mind.

The descriptions disclosed in Japanese Patent Application No. 2013-116439, filed on May 31, 2013, Japanese Patent Application No. 2013-169243, filed on Aug. 16, 2013, and Japanese Patent Application No. 2014-108183, filed on May 26, 2014, are all incorporated herein by reference. Publications, patent applications, and technical standards described in the present specification are, in a case in which those publications, patent applications, and technical standards are respectively designated as references or to be incorporated, all considered to be incorporated herein within the same restrictive ranges as the references. It is intended that the scope of the present invention is determined on the basis of the scope of the claims and their equivalents.

What is claimed is:

1. A solar cell back sheet comprising:
a supporter;
a coating layer (B), which includes a polymer having a yield point, on at least one surface side of the supporter; and
a coating layer (C), in this order,
wherein the coating layer (C) is in direct contact with a sealing material for a solar cell module to which the solar cell back sheet is applied.

2. The solar cell back sheet according to claim 1,
wherein the film thickness of the coating layer (B) is greater than the film thickness of the coating layer (C).

3. The solar cell back sheet according to claim 1,
wherein the film thickness of the coating layer (B) is in a range of 0.3 μm to 5 μm.

4. The solar cell back sheet according to claim 1,
wherein the coating layer (B) further includes inorganic particles.

5. The solar cell back sheet according to claim 4,
wherein the percentage content of the inorganic particles in the coating layer (B) is in a range of 10% by volume to 35% by volume.

6. The solar cell back sheet according to claim 3, wherein:
the coating layer (B) further includes inorganic particles; and
the percentage content of the inorganic particles in the coating layer (B) is in a range of 10% by volume to 35% by volume.

7. The solar cell back sheet according to claim 4,
wherein the average particle diameter of the inorganic particles included in the coating layer (B) is equal to or smaller than the film thickness of the coating layer (B).

8. The solar cell back sheet according to claim 4,
wherein the average particle diameter of the inorganic particles included in the coating layer (B) is equal to or smaller than half of the film thickness of the coating layer (B).

9. The solar cell back sheet according to claim 4,
wherein the average particle diameter of the inorganic particles included in the coating layer (B) is 1.0 μm or smaller.

10. The solar cell back sheet according to claim 6,
wherein the average particle diameter of the inorganic particles included in the coating layer (B) is 1.0 μm or smaller.

11. The solar cell back sheet according to claim 4,
wherein inorganic particles included in the coating layer (B) are at least one kind of particles selected from colloidal silica, titanium oxide, aluminum oxide, and zirconium oxide.

12. The solar cell back sheet according to claim 10,
wherein inorganic particles included in the coating layer (B) are at least one kind of particles selected from colloidal silica, titanium oxide, aluminum oxide, and zirconium oxide.

13. The solar cell back sheet according to claim 4,
wherein the inorganic particles included in the coating layer (B) contain at least a black pigment.

14. The solar cell back sheet according to claim 13,
wherein the black pigment contains at least carbon black.

15. The solar cell back sheet according to claim 12, wherein:
the inorganic particles included in the coating layer (B) contain at least a black pigment; and
the black pigment contains at least carbon black.

16. The solar cell back sheet according to claim 1, wherein:
the coating layer (C) further includes an antistatic agent; and
the coating layer (B) further includes a component of a crosslinking agent that crosslinks with the polymer in the coating layer (B).

17. The solar cell back sheet according to claim 16,
wherein the crosslinking agent is an oxazoline-based crosslinking agent.

18. The solar cell back sheet according to claim 15, wherein:
the coating layer (C) further includes an antistatic agent; and
the coating layer (B) further includes a component of a crosslinking agent that crosslinks with the polymer in the coating layer (B), the crosslinking agent being an oxazoline-based crosslinking agent.

19. The solar cell back sheet according to claim 16, further comprising, on a surface of the supporter opposite to the coating layer (B), a coating layer (D), the coating layer (D) including:
a silicone resin or a fluorine-based polymer; and
inorganic particles.

20. The solar cell back sheet according to claim 19 formed by further including a black pigment and a nonionic surfactant in the coating layer (D).

21. The solar cell back sheet according to claim 18, further comprising, on a surface of the supporter opposite to the coating layer (B), a coating layer (D), the coating layer (D) including:
a silicone resin or a fluorine-based polymer;
inorganic particles;
a black pigment; and
a nonionic surfactant.

22. The solar cell back sheet according to claim 19, further comprising, on a surface of the coating layer (D) opposite to the supporter, a coating layer (E), the coating layer (E) including:
a silicone resin or a fluorine-based polymer; and
inorganic particles.

23. The solar cell back sheet according to claim 22, further comprising:
a nonionic surfactant; and
a component of a crosslinking agent that crosslinks with the silicone resin or the fluorine-based polymer in the coating layer (E).

24. The solar cell back sheet according to claim 20, further comprising, on a surface of the coating layer (D) opposite to the supporter, a coating layer (E), the coating layer (E) including:
a silicone resin or a fluorine-based polymer,
inorganic particles,
a nonionic surfactant and
a component of a crosslinking agent that crosslinks with the silicone resin or the fluorine-based polymer.

25. The solar cell back sheet according to claim 18, further comprising, on a surface of the coating layer (D) opposite to the supporter, a coating layer (E), the coating layer (E) including:
a silicone resin or a fluorine-based polymer,
inorganic particles,
a nonionic surfactant and
a component of a crosslinking agent that crosslinks with the silicone resin or the fluorine-based polymer.

26. A solar cell module comprising:
a transparent base material on which sunlight is incident;
an element structure portion which is provided on the base material and has a solar cell element and a sealing material that seals the solar cell element; and
the solar cell back sheet according to claim 16 disposed on a side opposite to a side on which the base material of the element structure portion is located.

27. A solar cell module comprising:
a transparent base material on which sunlight is incident;
an element structure portion which is provided on the base material and has a solar cell element and a sealing material that seals the solar cell element; and
the solar cell back sheet according to claim 20 disposed on a side opposite to a side on which the base material of the element structure portion is located.

28. A solar cell module comprising:
a transparent base material on which sunlight is incident;
an element structure portion which is provided on the base material and has a solar cell element and a sealing material that seals the solar cell element; and
the solar cell back sheet according to claim 24 disposed on a side opposite to a side on which the base material of the element structure portion is located.

29. A solar cell module comprising:
a transparent base material on which sunlight is incident;
an element structure portion which is provided on the base material and has a solar cell element and a sealing material that seals the solar cell element; and
the solar cell back sheet according to claim 25 disposed on a side opposite to a side on which the base material of the element structure portion is located.
